(19) United States
(12) Patent Application Publication
(10) Pub. No.: US 2026/0198091 A1
(43) Pub. Date: Jul. 9, 2026

(54) SEMICONDUCTOR DEVICE, DISPLAY DEVICE, DISPLAY MODULE, AND ELECTRONIC DEVICE

(71) Applicant: SEMICONDUCTOR ENERGY LABORATORY CO., LTD., Atsugi-shi, Kanagawa-ken (JP)

(72) Inventors: Motomu KURATA, Isehara, Kanagawa (JP); Sachiaki TEZUKA, Atsugi, Kanagawa (JP); Tsutomu MURAKAWA, Isehara, Kanagawa (JP)

(21) Appl. No.: 19/133,773

(22) PCT Filed: Dec. 4, 2023
(86) PCT No.: PCT/IB2023/062165

§ 371 Date: May 29, 2025

(30) Foreign Application Priority Data
Dec. 9, 2022 (JP) 2022-197318
Dec. 9, 2022 (JP) 2022-197320

(51) Int. Cl. H10D 86/40; H10D 30/01; H10D 30/67; H10D 86/01; H10D 86/60; H10K 59/12; H10K 59/121

(52) U.S. Cl. CPC H10D 86/471; H10D 30/6728; H10D 86/60; H10K 59/1213; H10D 30/0318; H10D 30/6755; H10D 86/0221; H10D 86/423; H10K 59/1201

(57) ABSTRACT

To provide a semiconductor device that occupies a small area. The semiconductor device includes transistors having at least two types of structures and formed on the same plane by the steps some of which are shared. A vertical transistor with an extremely short channel length is used as a transistor required to have a high on-state current. Meanwhile, a planar transistor with a long channel length and a back gate is used as a transistor required to have high saturation characteristics.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device, a display module, and an electronic device each including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. Moreover, a memory device, a display device, a light-emitting apparatus, a lighting device, and an electronic device themselves are semiconductor devices and each of them includes a semiconductor device in some cases.

### BACKGROUND ART

Semiconductor devices that include transistors are applied to a wide range of electronic devices. In a display device, for example, when transistors occupy smaller areas, the pixel size can be smaller and higher definition can be achieved. Therefore, miniaturization of transistors has been required.

As devices requiring high-definition display devices, for example, devices for virtual reality (VR), augmented reality (AR), substitutional reality (SR), and mixed reality (MR) have been actively developed.

As display devices, for example, light-emitting apparatuses that include organic electroluminescence (EL) elements or light-emitting diodes (LEDs) have been developed.

Patent Document 1 discloses a high-definition display device using an organic EL element.

### [Reference]

### [Patent Document]

[Patent Document 1] PCT International Publication No. 2016/038508

### SUMMARY OF THE INVENTION

### Problems to be Solved by the Invention

An object of one embodiment of the present invention is to provide a transistor having a minute size. Another object is to provide a transistor having a small channel length. Another object is to provide a transistor having a high on-state current. Another object is to provide a transistor having favorable electrical characteristics. Another object is to provide a semiconductor device that occupies a small area. Another object is to provide a semiconductor device having small wiring resistance. Another object is to provide a semiconductor device or a display device having low power consumption. Another object is to provide a transistor, a semiconductor device, or a display device having high reliability. Another object is to provide a display device that can easily achieve higher definition. Another object is to provide a display device capable of performing high-luminance display. Another object is to provide a method for manufacturing a semiconductor device or a display device having high productivity. Another object is to provide a novel transistor, a novel semiconductor device, a novel display device, and manufacturing methods thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device which includes a first transistor and a second transistor and in which the first transistor includes a first conductive layer, a second conductive layer, a third conductive layer, a first oxide layer, a second oxide layer, a first insulating layer, a second insulating layer, and a third insulating layer; the second transistor includes a fourth conductive layer, a fifth conductive layer, a sixth conductive layer, a seventh conductive layer, a third oxide layer, the first insulating layer, a fourth insulating layer, and a fifth insulating layer; the first insulating layer is positioned over the first conductive layer and over the fourth conductive layer; the second insulating layer is positioned over the first insulating layer; the first oxide layer is positioned over the second insulating layer; the second conductive layer is positioned over the first oxide layer; the first insulating layer, the second insulating layer, the first oxide layer, and the second conductive layer include an opening reaching the first conductive layer; in the opening, the second oxide layer is in contact with at least a top surface of the first conductive layer, a side surface of the first insulating layer, a side surface of the second insulating layer, a side surface of the first oxide layer, and a side surface of the second conductive layer; in the opening, the third insulating layer is positioned over the second oxide layer; in the opening, the third conductive layer overlaps with the second oxide layer with the third insulating layer therebetween; the fourth insulating layer is positioned over the first insulating layer; the third oxide layer is positioned over the fourth insulating layer; the fifth conductive layer and the sixth conductive layer are positioned over the third oxide layer to be separated from each other; the fifth insulating layer is positioned over the third oxide layer and is positioned between the fifth conductive layer and the sixth conductive layer; and the seventh conductive layer includes a portion positioned over the fifth insulating layer and overlapping with the fourth conductive layer with the third oxide layer therebetween.

It is preferable that a size of the opening provided in the second conductive layer in a plan view be larger than a size of the opening provided in the first oxide layer in the plan view, and the second oxide layer be in contact with part of a top surface of the first oxide layer. Alternatively, the size of the opening provided in the second conductive layer in the plan view may be the same or substantially the same as the size of the opening provided in the first oxide layer in the plan view.

It is preferable that the first conductive layer include a depressed portion, the opening overlap with the depressed portion, and the second oxide layer be further in contact with an inner wall of the depressed portion of the first conductive layer.

It is preferable that the third conductive layer overlap with the side surface of the first insulating layer and the side surface of the second insulating layer with the third insulating layer and the second oxide layer therebetween.

One embodiment of the present invention is a display device which includes the semiconductor device with any of the above structures and a light-emitting element and in which the light-emitting element includes a first electrode, a light-emitting layer, and a second electrode stacked in this order; and the first electrode is electrically connected to the first conductive layer, the second conductive layer, the fifth conductive layer, or the sixth conductive layer.

It is preferable that a first layer, a second layer, and a third layer be stacked in this order, the first layer include a third transistor including silicon in a channel formation region, the second layer include the first transistor and the second transistor, and the third layer include the light-emitting element.

One embodiment of the present invention is a display module that includes the display device having any of the above structures. For example, the display module is a display module provided with a connector such as a flexible printed circuit board (hereinafter referred to as an FPC) or a TCP (Tape Carrier Package) or a display module mounted with an integrated circuit (IC) by a COG (Chip On Glass) method, a COF (Chip On Film) method, or the like.

Another embodiment of the present invention is an electronic device including the above display module and at least one of a housing, a battery, a camera, a speaker, and a microphone.

### Effect of the Invention

One embodiment of the present invention can provide a transistor having a minute size. Alternatively, a transistor having a small channel length can be provided. Alternatively, a transistor having a high on-state current can be provided. Alternatively, a transistor having favorable electrical characteristics can be provided. Alternatively, a semiconductor device that occupies a small area can be provided. Alternatively, a semiconductor device having small wiring resistance can be provided. Alternatively, a semiconductor device or a display device having low power consumption can be provided. Alternatively, a transistor, a semiconductor device, or a display device having high reliability can be provided. Alternatively, a display device that can easily achieve higher definition can be provided. Alternatively, a display device capable of performing high-luminance display can be provided. Alternatively, a method for manufacturing a semiconductor device or a display device having high productivity can be provided. Alternatively, a novel transistor, a novel semiconductor device, a novel display device, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A and FIG. 1B are top views illustrating an example of a semiconductor device. FIG. 1C is a cross-sectional view illustrating the example of the semiconductor device.

FIG. 2A and FIG. 2B are cross-sectional views illustrating an example of a semiconductor device.

FIG. 3A to FIG. 3D are cross-sectional views illustrating examples of a semiconductor device.

FIG. 4A and FIG. 4B are top views illustrating an example of a semiconductor device. FIG. 4C is a cross-sectional view illustrating the example of the semiconductor device.

FIG. 5A to FIG. 5D are cross-sectional views illustrating examples of a semiconductor device.

FIG. 6A and FIG. 6B are cross-sectional views illustrating an example of a method for manufacturing a semiconductor device.

FIG. 7A and FIG. 7B are cross-sectional views illustrating an example of a method for manufacturing a semiconductor device.

FIG. 8 is a cross-sectional view illustrating an example of a method for manufacturing a semiconductor device.

FIG. 9A and FIG. 9B are cross-sectional views illustrating an example of a method for manufacturing a semiconductor device.

FIG. 10A and FIG. 10B are cross-sectional views illustrating an example of a method for manufacturing a semiconductor device.

FIG. 11A and FIG. 11B are cross-sectional views illustrating an example of a method for manufacturing a semiconductor device.

FIG. 12A and FIG. 12B are cross-sectional views illustrating an example of a method for manufacturing a semiconductor device.

FIG. 13A and FIG. 13B are cross-sectional views illustrating an example of a method for manufacturing a semiconductor device.

FIG. 14A and FIG. 14B are perspective views illustrating an example of a display device.

FIG. 15 is a cross-sectional view illustrating an example of a display device.

FIG. 16 is a cross-sectional view illustrating an example of a display device.

FIG. 17 is a cross-sectional view illustrating an example of a display device.

FIG. 18 is a cross-sectional view illustrating an example of a display device.

FIG. 19 is a cross-sectional view illustrating an example of a display device.

FIG. 20A to FIG. 20G are diagrams illustrating examples of pixels.

FIG. 21A to FIG. 21K are diagrams illustrating examples of pixels.

FIG. 22A to FIG. 22F are diagrams illustrating structure examples of light-emitting devices.

FIG. 23A to FIG. 23C are diagrams illustrating structure examples of light-emitting devices.

FIG. 24A to FIG. 24D are diagrams illustrating examples of electronic devices.

FIG. 25A to FIG. 25F are diagrams illustrating examples of electronic devices.

FIG. 26A to FIG. 26G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”.

A transistor is a kind of semiconductor element and can achieve a function of amplifying a current or a voltage, switching operation for controlling conduction or non-conduction, and the like. An IGFET (Insulated Gate Field Effect Transistor) and a thin film transistor (TFT) are in the category of a transistor in this specification.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

In this specification and the like, the expression “electrically connected” includes the case where components are connected to each other through an “object having any electric action”. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode or a wiring.

Unless otherwise specified, an off-state current in this specification and the like refers to a leakage current between a source and a drain generated when a transistor is in an off state (also referred to as a non-conducting state or a cutoff state). Unless otherwise specified, an off state in an n-channel transistor refers to a state where a voltage V_{gs} between its gate and source is lower than a threshold voltage Vₜₕ (in a p-channel transistor, higher than Vₜₕ).

In this specification and the like, “normally-on characteristics” mean a state where a channel exists and a current flows through a transistor even when no voltage is applied to a gate. Furthermore, “normally-off characteristics” mean a state where a current does not flow through a transistor when no potential or a ground potential is applied to a gate.

In this specification and the like, a top-view shape of a component means the outline of the component in a plan view (also referred to as a top view). A plan view means that the component is observed from a normal direction of a surface where the component is formed or from a normal direction of a surface of a support (e.g., a substrate) where the component is formed.

In this specification and the like, the expression “having substantially the same top-view shapes” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top-view shapes are substantially the same”. In the case where the top-view shapes are the same or substantially the same, it can be said that the end portions are aligned or substantially aligned with each other or the side end portions are aligned or substantially aligned with each other.

In this specification and the like, a tapered shape refers to such a shape that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is greater than 0° and less than 90°. Note that the side surface, the substrate surface, and the formation surface of the component are not necessarily completely flat and may have a substantially planar shape with a small curvature or a substantially planar shape with slight unevenness.

Note that in this specification and the like, an oxynitride refers to a material that contains more oxygen than nitrogen in its composition. A nitride oxide refers to a material that contains more nitrogen than oxygen in its composition.

The content of hydrogen, oxygen, nitrogen, or any other element can be analyzed by secondary ion mass spectrometry (SIMS) or X-ray photoelectron spectroscopy (XPS). XPS is suitable when the content percentage of a target element is high (e.g., higher than or equal to 0.5 atomic %, or higher than or equal to 1 atomic %). By contrast, SIMS is suitable when the content percentage of a target element is low (e.g., lower than or equal to 0.5 atomic %, or lower than or equal to 1 atomic %). To compare the contents of elements, analysis with a combination of SIMS and XPS is preferably used.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A overlaps with B” is used, at least part of A overlaps with B. In other words, A includes a region overlapping with B, for example.

In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

Note that in this specification and the like, step disconnection refers to a phenomenon in which a layer, a film, or an electrode is split because of the shape of the formation surface (e.g., a step).

### Embodiment 1

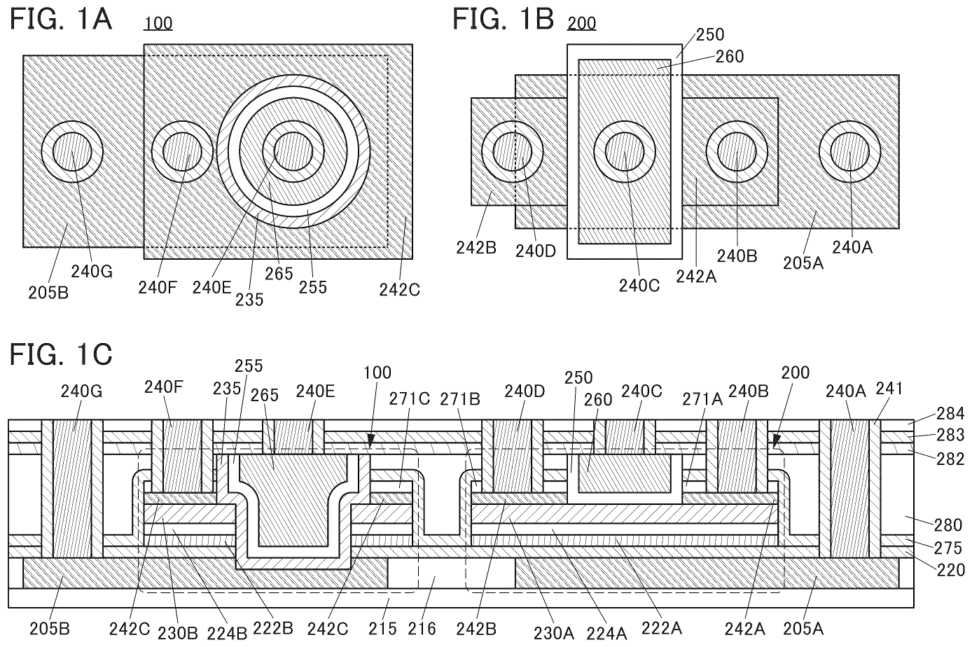

In this embodiment, a semiconductor device of one embodiment of the present invention will be described with reference to FIG. 1 to FIG. 5.

The semiconductor device of this embodiment includes transistors having at least two types of structures on the same plane. The transistors having the two types of structures can be formed by the steps some of which are shared. One of the transistors is used as a transistor required to have a high on-state current and the other of the transistors is used as a transistor required to have high saturation characteristics, for example, enabling the semiconductor device to have high performance. More specifically, a vertical transistor with an extremely short channel length is used as the transistor required to have a high on-state current. Meanwhile, a planar transistor with a long channel length and a back gate is used as the transistor required to have high saturation characteristics.

### Structure Example 1

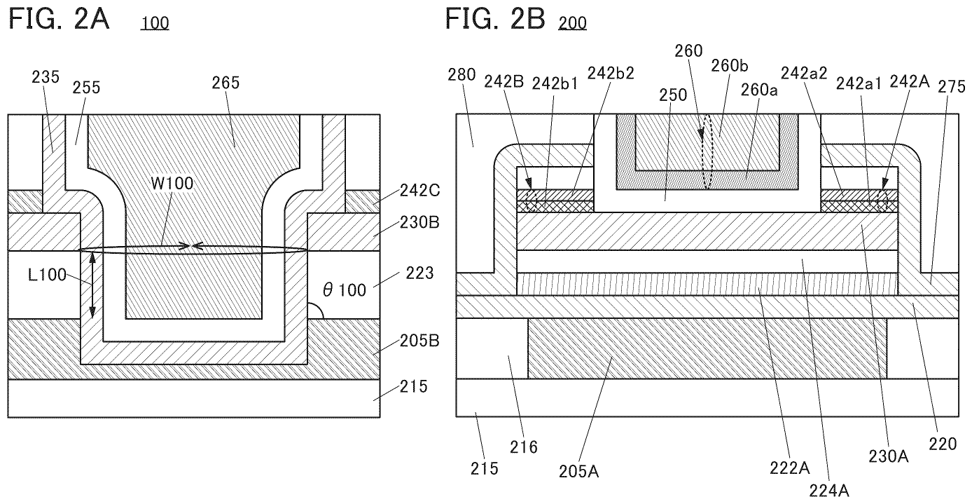

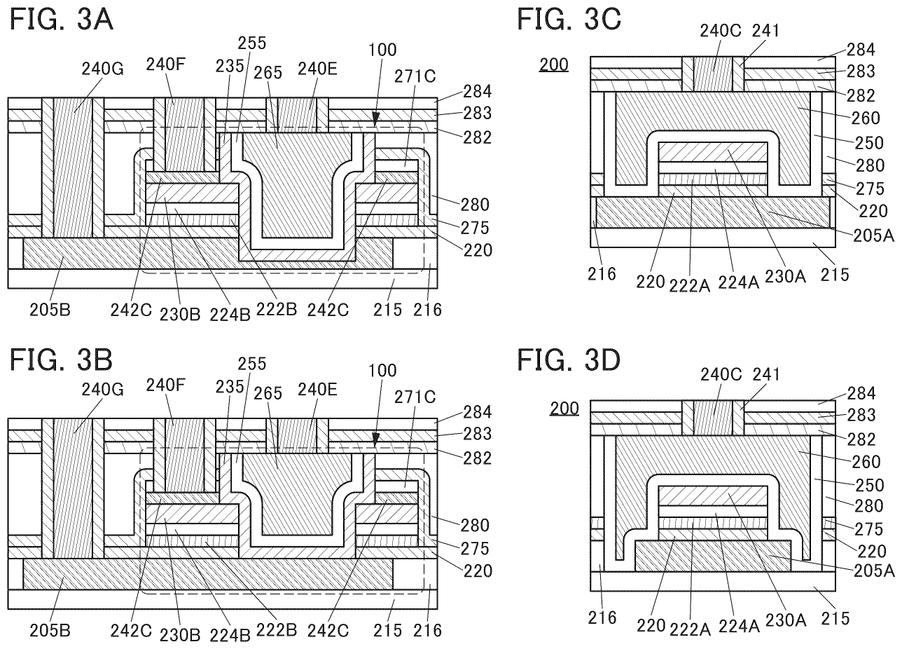

FIG. 1A is a top view of a transistor 100, FIG. 1B is a top view of a transistor 200, and FIG. 1C is a cross-sectional view of the transistor 100 and the transistor 200. FIG. 1C can also be regarded as a cross-sectional view of the transistor 200 in the channel length direction. FIG. 2A is an enlarged view of the transistor 100, and FIG. 2B is an enlarged view of the transistor 200. FIG. 3A and FIG. 3B are cross-sectional views each illustrating a modification example of the transistor 100. FIG. 3C and FIG. 3D are cross-sectional views of the transistor 200 in the channel width direction.

Any of a gate, a drain, and a source of the transistor 100 may be electrically connected to any of a gate, a drain, and a source of the transistor 200.

### <Transistor 100>

As illustrated in FIG. 1A and FIG. 1C, the transistor 100 includes a conductive layer 205B, a conductive layer 242C, an oxide layer 235, an insulating layer 255, and a conductive layer 265. Furthermore, one or more of an insulating layer 220, an insulating layer 222B, an insulating layer 224B, an oxide layer 230B, and an insulating layer 271C can also be regarded as the components of the transistor 100.

The insulating layer 255 functions as a gate insulating layer of the transistor 100. The conductive layer 265 functions as a gate electrode of the transistor 100.

The conductive layer 205B functions as one of a source electrode and a drain electrode of the transistor 100. The conductive layer 242C functions as the other of the source electrode and the drain electrode of the transistor 100.

The oxide layer 235 includes a channel formation region in the transistor 100. A region of the oxide layer 235 that is in contact with the conductive layer 205B functions as one of a source region and a drain region, a region of the oxide layer 235 that is in contact with the conductive layer 242C functions as the other of the source region and the drain region, and a region of the oxide layer 235 that is between the source region and the drain region functions as the channel formation region.

At least one of a region of the oxide layer 235 that is positioned between a side surface of the insulating layer 220 and the conductive layer 265, a region of the oxide layer 235 that is positioned between a side surface of the insulating layer 222B and the conductive layer 265, and a region of the oxide layer 235 that is positioned between a side surface of the insulating layer 224B and the conductive layer 265 functions as the channel formation region of the transistor 100. The diameter of an opening provided in the insulating layer 220, an opening provided in the insulating layer 222B, or an opening provided in the insulating layer 224B corresponds to the channel width of the transistor 100. The diameters of these openings may change in the depth direction. As the diameter of the opening, any of the following may be used: the diameter at the highest level of the insulating layer 220, the insulating layer 222B, or the insulating layer 224B in a cross-sectional view, the diameter at the lowest level of the insulating layer 220, the insulating layer 222B, or the insulating layer 224B in a cross-sectional view, and the diameter that is half of the sum of the diameter at the highest level and the diameter at the lowest level.

The oxide layer 230B is preferably an oxide conductive layer. Alternatively, the oxide layer 230B may be an oxide semiconductor layer having lower resistance than the channel formation region of the oxide layer 235. The oxide layer 230B may be regarded as part of the other of the source electrode and the drain electrode of the transistor 100. Alternatively, the oxide layer 230B may be regarded as part of the other of the source region and the drain region of the transistor 100.

FIG. 2A is an enlarged view of the transistor 100. In FIG. 2A, the insulating layers provided between the conductive layer 205B and the oxide layer 230B are collectively illustrated as an insulating layer 223. The insulating layer 223 may have either a single-layer structure or a stacked-layer structure. The insulating layer 223 corresponds to, for example, a stacked-layer structure of the insulating layers 220, 222B, and 224B in FIG. 1C.

In FIG. 2A, a channel length L100 and a channel width W100 of the transistor 100 are shown. It can be said that in FIG. 2A, the channel length L100 is the shortest distance between a portion of the oxide layer 235 that is in contact with the oxide layer 230B and a portion of the oxide layer 235 that is in contact with the conductive layer 205B. In FIG. 2A, the channel width W100 is represented by the diameter at the highest level of the insulating layer 223 in a cross-sectional view. Note that the diameter of the opening included in the insulating layer 223 may change in the depth direction. Thus, as the channel width W100, any of the following can be used, for example: the diameter at the highest level of the insulating layer 223 in a cross-sectional view, the diameter at the lowest level of the insulating layer 223 in a cross-sectional view, and the diameter at the midpoint between these levels. Alternatively, as the channel width W100, for example, the average value of the following three diameters can be used: the diameter at the highest level of the insulating layer 223 in a cross-sectional view, the diameter at the lowest level of the insulating layer 223 in a cross-sectional view, and the diameter at the midpoint between these levels.

Note that depending on the structure of the insulating layer 223, only part of a region of the oxide layer 235 that is in contact with the insulating layer 223 may be the channel formation region, and the channel length L100 may be shorter than the length shown in FIG. 2A.

For example, an oxide insulating film is preferably used for a portion of the insulating layer 223 that is in contact with the channel formation region of the oxide layer 235. It is particularly preferable to use an insulating film from which oxygen is released by heating (e.g., a silicon oxide film or a silicon oxynitride film). Over and/or under the insulating film, an insulating film that does not easily allow diffusion of oxygen and hydrogen (e.g., a silicon nitride film, a silicon nitride oxide film, an aluminum oxide film, or a hafnium oxide film) is preferably provided. This enables efficient supply of oxygen to the channel formation region of the oxide layer 235 and can inhibit diffusion of hydrogen. Thus, the electrical characteristics of the transistor 100 can be stabilized.

In FIG. 2A, the channel length L100 of the transistor 100 corresponds to the length of a side surface of the insulating layer 223 on the opening side in a cross-sectional view. In other words, the channel length L100 depends on the thickness of the insulating layer 223 and an angle 0100 formed by the side surface of the insulating layer 223 on the opening side and the formation surface of the insulating layer 223 (here, the top surface of the conductive layer 205B). Thus, for example, the channel length L100 can have a value smaller than that of the resolution limit of a light-exposure apparatus, which enables a transistor having a minute size. Specifically, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, a transistor with a channel length less than 10 nm can also be achieved without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

When the channel length L100 is small, the transistor 100 can have a high on-state current. With use of the transistor 100, a circuit capable of high-speed operation can be manufactured. Furthermore, the area occupied by the circuit can be reduced. Thus, a small semiconductor device can be obtained. The application of the semiconductor device of one embodiment of the present invention to a large display device or a high-definition display device can reduce signal delay in wirings and reduce display unevenness even if the number of wirings is increased, for example. In addition, since the area occupied by the circuit can be reduced, the bezel of the display device can be narrowed.

By adjusting the thickness of the insulating layer 223 and the angle θ100, the channel length L100 can be controlled.

The thickness of the insulating layer 223 can be at least larger than that of the oxide layer 235. For example, the thickness of the insulating layer 223 can be greater than or equal to 2 nm, greater than or equal to 5 nm, greater than or equal to 10 nm, or greater than or equal to 50 nm and less than or equal to 500 nm, less than or equal to 400 nm, less than or equal to 300 nm, less than or equal to 200 nm, or less than or equal to 150 nm.

The side surface of the insulating layer 223 on the opening side preferably has a vertical shape or a tapered shape. The angle θ100 formed by the side surface of the insulating layer 223 on the opening side and the formation surface of the insulating layer 223 (here, the top surface of the conductive layer 205B) is preferably less than or equal to 90°. By reducing the angle θ100, coverage with a layer provided over the insulating layer 223 (e.g., the oxide layer 235) can be improved. The smaller the angle θ100 is, the larger the channel length L100 is. The larger the angle θ100 is, the smaller the channel length L100 is. This embodiment describes an example in which the side surface of the insulating layer 223 on the opening side has a vertical shape (the angle θ100 is) 90°.

The angle θ100 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than or equal to 90°, less than or equal to 85°, or less than or equal to 80°. The angle θ100 may be less than or equal to 75°, less than or equal to 70°, less than or equal to 65°, or less than or equal to 60°.

In the case where the angle θ100 is greater than or equal to 80° and less than or equal to 90°, the film covering the insulating layer 223 is preferably formed by a film formation method that enables favorable coverage. For example, it is preferable that the conductive layer 265 be formed by a CVD method and the insulating layer 255 and the oxide layer 235 be formed by an ALD method. For another example, it is preferable that the conductive layer 265, the insulating layer 255, and the oxide layer 235 be formed by an ALD method. In the case where the angle 0100 is greater than or equal to 60° and less than or equal to 85°, the film covering the insulating layer 223 may be formed by a film formation method with higher productivity. For example, it is preferable that the oxide layer 235 be formed by a sputtering method.

In the example illustrated in FIG. 1A, the top-view shapes of the openings in the insulating layers 220, 222B, and 224B, the oxide layer 230B, the conductive layer 242C, and the insulating layer 271C are each a circular shape. When the top-view shapes of the openings are each a circular shape in this manner, the channel width of the transistor can be smaller than when the top-view shapes of the openings are any other shape.

In the case where the openings are formed by a photolithography method, the diameter of each opening is larger than or equal to the resolution limit of a light-exposure apparatus. The diameter can be, for example, greater than or equal to 20 nm, greater than or equal to 50 nm, greater than or equal to 100 nm, greater than or equal to 200 nm, greater than or equal to 300 nm, greater than or equal to 400 nm, or greater than or equal to 500 nm and less than 5.0 μm, less than or equal to 4.5 μm, less than or equal to 4.0 μm, less than or equal to 3.5 μm, less than or equal to 3.0 μm, less than or equal to 2.5 μm, less than or equal to 2.0 μm, less than or equal to 1.5 μm, or less than or equal to 1.0 μm.

There is no limitation on the top-view shapes of the openings provided in the layers, and the top-view shapes can each be a circle, an ellipse, a polygon such as a triangle, a quadrangle (including a rectangle, a rhombus, and a square), a pentagon, or a star polygon, or any of these polygons whose corners are rounded, for example. Note that the polygon may be a concave polygon (a polygon at least one of the interior angles of which is greater than 180°) or a convex polygon (a polygon all the interior angles of which are less than or equal to) 180°. The top-view shapes of the openings are each preferably a circular shape as illustrated in FIG. 1A and the like. When the top-view shapes of the openings are each a circular shape, processing accuracy at the time of formation of the openings can be high, whereby the openings can be formed to have a minute size. Note that in this specification and the like, a circular shape is not necessarily a perfect circular shape.

In this specification and the like, the top-view shape of an opening in a film can refer to the shape of an end portion of the top surface of the film on the opening side or the shape of an end portion of the bottom surface of the film on the opening side.

In the example illustrated in FIG. 1A, the top-view shapes of the insulating layers 222B and 224B, the oxide layer 230B, the conductive layer 242C, and the insulating layer 271C are each a quadrangular shape (specifically, a rectangular shape). There is no limitation on the top-view shapes of the layers provided to have island shapes, and the top-view shapes can each be a circle, an ellipse, a polygon such as a triangle, a quadrangle (including a rectangle, a rhombus, and a square), a pentagon, or a star polygon, or any of these polygons whose corners are rounded, for example.

In the transistor 100, the source electrode and the drain electrode are positioned at different levels, so that a current flows in the semiconductor layer in the height direction. In other words, the channel length direction can be regarded as having a component of the height direction (the vertical direction); accordingly, the transistor 100 can also be referred to as a VFET (Vertical Field Effect Transistor), a vertical transistor, a vertical-channel transistor, a vertical-channel-type transistor, and the like.

In the transistor 100, the source electrode, the semiconductor layer, and the drain electrode can be provided to overlap with each other; thus, the area occupied by the transistor can be significantly smaller than the area occupied by what is called a planar transistor, in which a semiconductor layer is provided to have a planar shape.

### <Transistor 200>

As illustrated in FIG. 1B and FIG. 1C, the transistor 200 includes a conductive layer 205A, the insulating layer 220, an insulating layer 222A, an insulating layer 224A, an oxide layer 230A, a conductive layer 242A, a conductive layer 242B, an insulating layer 250, and a conductive layer 260. Furthermore, an insulating layer 271A and an insulating layer 271B can also be regarded as the components of the transistor 200.

The insulating layer 250 functions as a gate insulating layer (which can also be regarded as a first gate insulating layer) of the transistor 200. The conductive layer 260 functions as a gate electrode (which can also be regarded as a first gate electrode) of the transistor 200.

The insulating layer 220, the insulating layer 222A, and the insulating layer 224A function as a back gate insulating layer (which can also be regarded as a second gate insulating layer) of the transistor 200. The conductive layer 205A functions as a back gate electrode (which can also be regarded as a second gate electrode) of the transistor 200.

The conductive layer 242A functions as one of a source electrode and a drain electrode of the transistor 200. The conductive layer 242B functions as the other of the source electrode and the drain electrode of the transistor 200.

The oxide layer 230A includes a channel formation region of the transistor 200 and a source region and a drain region provided to sandwich the channel formation region. At least part of the channel formation region overlaps with the conductive layer 260. One of the source region and the drain region overlaps with the conductive layer 242A, and the other overlaps with the conductive layer 242B. The channel formation region overlaps with the conductive layer 260 with the insulating layer 250 therebetween and overlaps with the conductive layer 205A with the insulating layers 220, 222A, and 224A therebetween.

The channel length of the transistor 200 can be determined by the width of the conductive layer 260; thus, the design flexibility of the channel length of the transistor 200 is higher than that of the transistor 100, which is a vertical transistor. For example, in the case where the semiconductor device includes a plurality of the transistors 200, all the transistors 200 may have the same channel length, or some of the transistors 200 may have channel lengths different from those of the other transistors 200. When the channel length of the transistor 200 is longer than the channel length of the transistor 100, the transistor 200 can have favorable saturation characteristics.

In each of the transistors, the channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration of each of the oxide layer 230A and the oxide layer 235, the impurity concentration in each of the oxide layer 230A and the oxide layer 235 is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration is sometimes referred to as a highly purified intrinsic or substantially highly purified intrinsic oxide semiconductor (or metal oxide).

Reducing the impurity concentration in the oxide layer 235 is effective in stabilizing the electrical characteristics of the transistor 100. Reducing the impurity concentration in the oxide layer 230A is effective in stabilizing the electrical characteristics of the transistor 200. To reduce the impurity concentration of each of the oxide layer 230A and the oxide layer 235, it is preferable that the impurity concentration in an adjacent film also be reduced. Examples of impurities include hydrogen, nitrogen, an alkali metal, an alkaline earth metal, iron, nickel, and silicon. Note that an impurity in the oxide layer 230A refers to, for example, an element other than the main components of the oxide layer 230A. For example, an element with a concentration lower than 0.1 atomic % can be regarded as an impurity. The same applies to an impurity in the oxide layer 235.

In the oxide layer 235 and the oxide layer 230A, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

### <Semiconductor Device>

Next, a stacked-layer structure in the semiconductor device illustrated in FIG. 1C is described.

An insulating layer 216, the conductive layer 205A, and the conductive layer 205B are provided over an insulating layer 215. The conductive layer 205A and the conductive layer 205B are provided to be embedded in openings of the insulating layer 216. The top surfaces of the insulating layer 216, the conductive layer 205A, and the conductive layer 205B are preferably level or substantially level with each other.

The insulating layer 220 is provided over the insulating layer 216, the conductive layer 205A, and the conductive layer 205B.

The insulating layer 222B, the insulating layer 224B, the oxide layer 230B, the conductive layer 242C, and the insulating layer 271C are stacked in this order over the insulating layer 220 so as to at least partly overlap with the conductive layer 205B. An insulating layer 275 is provided to cover side surfaces of the insulating layer 222B, the insulating layer 224B, the oxide layer 230B, the conductive layer 242C, and the insulating layer 271C and the top surface of the insulating layer 271C, and an insulating layer 280 is provided to cover the insulating layer 275. The insulating layer 222B, the insulating layer 224B, the oxide layer 230B, and the conductive layer 242C can be formed by collective processing into island shapes. Thus, the productivity of the semiconductor device can be increased. In the case of collective processing into island shapes, a structure as illustrated in FIG. 1C can be obtained, for example. Specifically, in a cross-sectional view of the transistor 100, a side end portion of the conductive layer 242C is aligned or substantially aligned with a side end portion of the oxide layer 230B, a side end portion of the insulating layer 224B, and a side end portion of the insulating layer 222B.

The insulating layer 271C may be provided over the conductive layer 242C. The insulating layer 271C can function as an etching stopper that protects the conductive layer 242C in the step of the collective processing into island shapes.

Although the insulating layer 222A and the insulating layer 222B are each formed into an island shape in the example described in this embodiment, an insulating layer 222 may be provided over the entire surface like the insulating layer 220. In that case, the transistor 100 and the transistor 200 share a stacked-layer structure of the insulating layer 220 and the insulating layer 222.

The opening reaching the conductive layer 205B is provided in the insulating layer 220, the insulating layer 222B, the insulating layer 224B, the oxide layer 230B, the conductive layer 242C, the insulating layer 271C, the insulating layer 275, and the insulating layer 280.

Here, the conductive layer 205B illustrated in FIG. 1C and FIG. 3A has a depressed portion in a position overlapping with the opening. Alternatively, as illustrated in FIG. 3B, the conductive layer 205B is not necessarily provided with a depressed portion.

The oxide layer 235 is provided to cover the inside of the opening and to be in contact with the top surface of the conductive layer 205B, the side surface of the insulating layer 220, the side surface of the insulating layer 222B, the side surface of the insulating layer 224B, the top surface and a side surface of the oxide layer 230B, a side surface of the conductive layer 242C, a side surface of the insulating layer 271C, a side surface of the insulating layer 275, and a side surface of the insulating layer 280. Furthermore, in the opening, the insulating layer 255 is provided over the oxide layer 235 and the conductive layer 265 is provided over the insulating layer 255.

As illustrated in FIG. 1C, FIG. 3A, and FIG. 3B, the size of the opening provided in the conductive layer 242C and the insulating layer 271C in a plan view is preferably larger than the size of the opening provided in the insulating layer 220, the insulating layer 222B, the insulating layer 224B, and the oxide layer 230B in a plan view. In that case, the oxide layer 235 is in contact with not only the side surface of the oxide layer 230B but also the top surface thereof. As described above, the oxide layer 230B can be regarded as part of the source electrode or the drain electrode of the transistor 100. When the contact area between the oxide layer 235 and the oxide layer 230B is increased, the contact resistance between the oxide layer 235 and the source electrode or the drain electrode can be reduced, and the on-state current of the transistor 100 can be increased.

In the case where the conductive layer 205B is provided with the depressed portion as illustrated in FIG. 1C and FIG. 3A, the oxide layer 235 is provided in contact with the bottom surface and a side surface of the depressed portion of the conductive layer 205B.

The conductive layer 265 is provided to be embedded in the opening. The top surfaces of the oxide layer 235, the insulating layer 255, the conductive layer 265, and the insulating layer 280 are preferably level or substantially level with each other.

In FIG. 3B, a region of the oxide layer 235 that is in contact with the side surface of the insulating layer 224B overlaps with the conductive layer 265. In other words, the region of the oxide layer 235 that is in contact with the side surface of the insulating layer 224B faces the conductive layer 265. The region of the oxide layer 235 that is in contact with the side surface of the insulating layer 224B functions as the channel formation region of the transistor 100. It is thus preferable to use an oxide insulating film for the insulating layer 224B.

In FIG. 1C, the region of the oxide layer 235 that is in contact with the side surface of the insulating layer 224B and a region of the oxide layer 235 that is in contact with the side surface of the insulating layer 222B overlap with the conductive layer 265. In other words, the region of the oxide layer 235 that is in contact with the side surface of the insulating layer 224B and the region of the oxide layer 235 that is in contact with the side surface of the insulating layer 222B face the conductive layer 265. This enables a region to which a gate electric field is less likely to be applied (an offset region) to be smaller than that in the structure illustrated in FIG. 3B, which is preferable. Similarly, a region of the oxide layer 235 that is in contact with the side surface of the insulating layer 220 also overlaps with the conductive layer 265 (faces the conductive layer 265) in FIG. 3A to enable an offset region to be smaller than that in the structure illustrated in FIG. 1C, which is preferable. Accordingly, a decrease in field-effect mobility due to the offset region can be inhibited.

The insulating layer 222A, the insulating layer 224A, and the oxide layer 230A are stacked in this order over the insulating layer 220 so as to at least partly overlap with the conductive layer 205A. Furthermore, the conductive layer 242A and the conductive layer 242B are provided over the oxide layer 230A to be separated from each other.

The insulating layer 222A, the insulating layer 224A, the oxide layer 230A, and a conductive layer to be the conductive layer 242A and the conductive layer 242B can be formed by collective processing into island shapes. Thus, the productivity of the semiconductor device can be increased. In the case of collective processing into island shapes, a structure as illustrated in FIG. 1C can be obtained, for example. Specifically, in a cross-sectional view of the transistor 200, one side end portion of the conductive layer 242A is aligned or substantially aligned with one side end portion of the oxide layer 230A, and one side end portion of the conductive layer 242B is aligned or substantially aligned with the other side end portion of the oxide layer 230A. Furthermore, a side end portion of the insulating layer 222A and a side end portion of the insulating layer 224A are aligned or substantially aligned with the side end portion of the oxide layer 230A.

The insulating layer 271A may be provided over the conductive layer 242A, and the insulating layer 271B may be provided over the conductive layer 242B. The insulating layer 271A and the insulating layer 271B can function as etching stoppers that protect the conductive layer 242A and the conductive layer 242B in the step of the collective processing into island shapes.

The insulating layer 275 is provided to cover side surfaces of the insulating layer 222A, the insulating layer 224A, the oxide layer 230A, the conductive layer 242A, the conductive layer 242B, the insulating layer 271A, and the insulating layer 271B and the top surfaces of the insulating layer 271A and the insulating layer 271B, and the insulating layer 280 is provided to cover the insulating layer 275.

In FIG. 1C, an opening reaching the oxide layer 230A is provided in the insulating layer 275 and the insulating layer 280. As illustrated in FIG. 3C, the insulating layer 220, the insulating layer 275, and the insulating layer 280 preferably include an opening reaching the conductive layer 205A. Note that it is also possible to employ a structure in which the insulating layer 275 includes an opening reaching the insulating layer 220 and the insulating layer 220 does not include an opening or a structure in which neither the insulating layer 220 nor the insulating layer 275 includes an opening. In that case, an opening reaching the insulating layer 275 or the insulating layer 220 is provided in the insulating layer 280. Alternatively, as illustrated in FIG. 3D, the insulating layer 216, the insulating layer 220, the insulating layer 275, and the insulating layer 280 preferably include an opening reaching the insulating layer 215 in a position overlapping with the conductive layer 205A.

The insulating layer 250 is provided to cover the opening reaching the oxide layer 230A and the opening reaching the conductive layer 205A or the insulating layer 215, and the conductive layer 260 is provided over the insulating layer 250. When the insulating layer 222A and the insulating layer 224A are each provided to have an island shape, at least part of the bottom surface of the conductive layer 260 can be provided below the bottom surface of the oxide layer 230A. Thus, the conductive layer 260 can be provided to face the top surface and the side surface of the oxide layer 230A, so that an electric field of the conductive layer 260 can be applied to the top surface and the side surface of the oxide layer 230A.

Here, in this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure and a planar structure. Meanwhile, the S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect does not easily occur can be provided.

When the transistor 200 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 200 has the S-channel structure, the GAA structure, or the LGAA structure, the channel formation region that would be formed at the interface between the oxide layer 230A and the insulating layer 250 or in the vicinity of the interface can be formed in the entire bulk of the oxide layer 230A. Accordingly, the density of a current flowing through the transistor can be increased, which can be expected to increase the on-state current of the transistor or increase the field-effect mobility of the transistor.

Furthermore, an insulating layer 282, an insulating layer 283, and an insulating layer 284 are provided over the transistor 100 and the transistor 200. In openings provided in the insulating layer 282, the insulating layer 283, the insulating layer 284, and the like, a conductive layer 240A electrically connected to the conductive layer 205A, a conductive layer 240B electrically connected to the conductive layer 242A, a conductive layer 240C electrically connected to the conductive layer 260, a conductive layer 240D electrically connected to the conductive layer 242B, a conductive layer 240E electrically connected to the conductive layer 265, a conductive layer 240F electrically connected to the conductive layer 242C, and a conductive layer 240G electrically connected to the conductive layer 205B are provided. An insulating layer 241 is preferably provided on a side surface of each of the openings provided in the insulating layer 282, the insulating layer 283, the insulating layer 284, and the like, and the conductive layer 205A to the conductive layer 240G are preferably embedded inside the insulating layer 241.

### [Material]

Materials that can be used for the semiconductor device of this embodiment are described below. Note that the layers included in the semiconductor device of this embodiment, the transistor 100, and the transistor 200 may each have a single-layer structure or a stacked-layer structure.

### <Oxide Layer 235, Oxide Layer 230A, and Oxide Layer 230B>

A metal oxide functioning as a semiconductor (hereinafter also referred to as an oxide semiconductor) is preferably used for the oxide layer 235, the oxide layer 230A, and the oxide layer 230B.

The oxide layer 235 and the oxide layer 230A each include the channel formation region, and the channel formation region is an i-type (intrinsic) or substantially i-type region. The oxide layer 235 and the oxide layer 230A each further include the source region and the drain region, and the source region and the drain region are each an n-type region (low-resistance region) having a higher carrier concentration than the channel formation region. The oxide layer 230B can have a structure similar to that of the source region and the drain region. The resistance of the oxide layer 230B is preferably lower than that of the channel formation region included in each of the oxide layer 235 and the oxide layer 230A. The oxide layer 230B is preferably a conductive metal oxide (also referred to as an oxide conductor (OC)).

The material that can be used for the oxide layer 235 will be mainly described below. The oxide layer 230A and the oxide layer 230B can be formed using a material similar to the material that can be used for the oxide layer 235. The oxide layer 230A and the oxide layer 230B can be formed using the same process and the same material. The oxide layer 230A and the oxide layer 230B may be formed using the same material as the oxide layer 235 or may be formed using a material different from that for the oxide layer 235.

There is no particular limitation on the crystallinity of a semiconductor material used for the oxide layer 235, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The metal oxide functioning as a semiconductor preferably has a band gap larger than or equal to 2.0 eV, further preferably larger than or equal to 2.5 eV. With the use of a metal oxide having a larger band gap, the off-state current of the transistor can be reduced. Such a transistor including a metal oxide in a channel formation region is referred to as an OS transistor. The off-state current of the OS transistor is low, so that power consumption of the semiconductor device can be adequately reduced. The OS transistor has excellent frequency characteristics, which enables the semiconductor device to operate at high speed.

Examples of the metal oxide that can be used for the oxide layer 235 include indium oxide, gallium oxide, and zinc oxide. The metal oxide preferably contains at least indium (In) or zinc (Zn). The metal oxide preferably contains two or three elements selected from indium, an element M, and zinc. The element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably any one or more of the above elements, further preferably one or more selected from aluminum, gallium, tin, and yttrium, still further preferably gallium. In this specification and the like, a metal element and a metalloid element may be collectively referred to as a “metal element”, and a “metal element” described in this specification and the like may refer to a metalloid element.

For example, the oxide layer 235 can be formed using indium zinc oxide (In—Zn oxide, also referred to as IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, it is possible to use indium tin oxide containing silicon, gallium tin oxide (Ga—Sn oxide), aluminum tin oxide (Al—Sn oxide), or the like.

By increasing the proportion of the number of indium atoms in the total number of atoms of all the metal elements contained in the metal oxide, the field-effect mobility of the transistor can be increased. In addition, the transistor can have a high on-state current.

Note that the metal oxide may contain, instead of indium or in addition to indium, one or more metal elements belonging to a period of a higher number in the periodic table. The larger the overlap between orbits of metal elements is, the more likely it is that the metal oxide will have high carrier conductivity. Thus, a transistor including a metal element belonging to a period of a higher number in the periodic table can have high field-effect mobility in some cases. Examples of the metal element belonging to a period of a higher number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium.

Note that lanthanum, cerium, praseodymium, neodymium, promethium, samarium, and europium are called light rare-earth elements.

The metal oxide may contain one or more nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed, and the reliability of the transistor can be increased.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor is suppressed, and the reliability of the transistor can be increased.

The electrical characteristics and reliability of the transistor depend on the composition of the metal oxide used for the oxide layer 235. Thus, by varying the composition of the metal oxide in accordance with the electrical characteristics and reliability required for the transistor, the semiconductor device can have both good electrical characteristics and high reliability.

When the metal oxide is an In—M—Zn oxide, the proportion of the number of In atoms is preferably higher than or equal to that of the number of M atoms in the In—M—Zn oxide. Examples of the atomic ratio of the metal elements of such an In—M—Zn oxide include In:M:Zn=1:1:1, In:M:Zn=1:1:1.2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood of any of the above atomic ratios. Note that a composition in the neighborhood includes the range of +30% of an intended atomic ratio. By increasing the proportion of the number of indium atoms in the metal oxide, the on-state current, field-effect mobility, or the like of the transistor can be increased.

The proportion of the number of In atoms may be less than that of the number of M atoms in the In—M—Zn oxide. Examples of the atomic ratio of the metal elements in such an In—M—Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of the metal elements can be the proportion of the number of element M atoms.

In this specification and the like, the proportion of the number of indium atoms in the total number of atoms of all the metal elements contained is sometimes referred to as the content percentage of indium. The same applies to other metal elements.

A sputtering method or an atomic layer deposition (ALD) method can be suitably used to form the metal oxide. Note that in the case where the metal oxide is formed by a sputtering method, the composition of the formed metal oxide film may be different from the composition of a target. In particular, the content percentage of zinc in the formed metal oxide film may be reduced to approximately 50% of that of the target.

The oxide layer 235 may have a stacked-layer structure of two or more metal oxide layers. The two or more metal oxide layers included in the oxide layer 235 may have the same composition or substantially the same compositions. When the compositions of the stacked metal oxide layers are the same, they can be formed using the same sputtering target, for example, and the manufacturing cost can thus be reduced.

The two or more metal oxide layers included in the oxide layer 235 may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In addition, it is particularly preferable to use gallium, aluminum, or tin as the element M. For example, a stacked-layer structure of any one selected from indium oxide, indium gallium oxide, and IGZO, and any one selected from IAZO, IAGZO, and ITZO (registered trademark) may be employed.

It is preferable that the oxide layer 235 include a metal oxide layer having crystallinity. Examples of the structure of a metal oxide having crystallinity include a CAAC (c-axis aligned crystal) structure, a polycrystalline structure, and a nano-crystal (nc) structure. With use of a metal oxide layer having crystallinity as the oxide layer 235, the density of defect states in the oxide layer 235 can be reduced, which enables the semiconductor device to have high reliability.

The higher the crystallinity of the metal oxide layer used as the oxide layer 235 is, the lower the density of defect states in the oxide layer 235 can be. By contrast, with the use of a metal oxide layer having low crystallinity, a large amount of current can flow through the transistor.

In the case where the metal oxide layer is formed by a sputtering method, the higher the substrate temperature (the stage temperature) in the formation is, the higher the crystallinity of the formed metal oxide layer can be. Furthermore, the higher the proportion of the flow rate of an oxygen gas to the total flow rate of the film formation gas (also referred to as an oxygen flow rate ratio) used in the formation is, the higher the crystallinity of the formed metal oxide layer can be.

The oxide layer 235 may have a stacked-layer structure of two or more metal oxide layers having different crystallinities. For example, a stacked-layer structure of a first metal oxide layer and a second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

The thickness of the oxide layer 235 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm.

In the case where an oxide semiconductor is used for the oxide layer 235, hydrogen contained in the oxide semiconductor reacts with oxygen bonded to a metal atom to be water, and thus sometimes forms an oxygen vacancy (Vo) in the oxide semiconductor. In some cases, a defect that is an oxygen vacancy into which hydrogen enters (hereinafter referred to as VoH) functions as a donor and generates an electron serving as a carrier. In other cases, bonding of part of hydrogen to oxygen bonded to a metal atom generates electrons serving as carriers. Thus, a transistor including an oxide semiconductor that contains a large amount of hydrogen is likely to have normally-on characteristics (i.e., a negative threshold voltage value). Moreover, hydrogen in the oxide semiconductor is easily transferred by a stress such as heat or an electric field; thus, a large amount of hydrogen in the oxide semiconductor might reduce the reliability of the transistor.

In the case where an oxide semiconductor is used for the oxide layer 235, the amount of VoH in the oxide layer 235 is preferably reduced as much as possible so that the oxide layer 235 becomes a highly purified intrinsic or substantially highly purified intrinsic oxide layer. In order to obtain such an oxide semiconductor with sufficiently reduced VoH, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that repairing oxygen vacancies by supplying oxygen to an oxide semiconductor is sometimes referred to as oxygen adding treatment.

When an oxide semiconductor is used for the oxide layer 235, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

Note that for the semiconductor device of this embodiment, a transistor including a different semiconductor material in its channel formation region may be used. Examples of the different semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. These semiconductor materials may include an impurity as a dopant.

As examples of silicon that can be used for the semiconductor material of the transistor, single crystal silicon, polycrystalline silicon, microcrystalline silicon, and amorphous silicon can be given. An example of polycrystalline silicon is low-temperature polysilicon (LTPS).

The semiconductor layer of the transistor may include a layered substance that functions as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substances include graphene, silicene, and chalcogenide.

Chalcogenide is a compound containing chalcogen (an element belonging to Group 16). Examples of chalcogenide include transition metal chalcogenide and chalcogenide of Group 13 elements. Specific examples of the transition metal chalcogenide that can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### <Insulating Layer 250 and Insulating Layer 255>

The insulating layer 250 is in contact with the channel formation region of the oxide layer 230A. The insulating layer 255 is in contact with the channel formation region of the oxide layer 235.

The material that can be used for the insulating layer 250 will be mainly described below. The insulating layer 255 can be formed using a material similar to the material that can be used for the insulating layer 250. The insulating layer 255 may be formed using the same material as the insulating layer 250 or may be formed using a material different from that for the insulating layer 250.

The insulating layer 250 preferably has a function of capturing and fixing hydrogen. In that case, the hydrogen concentration in the channel formation region of the oxide layer 230A can be reduced. Accordingly, VoH in the channel formation region can be reduced, so that the channel formation region can be an i-type or substantially i-type region.

In the case where the insulating layer 250 has a stacked-layer structure, a layer that is in contact with the oxide layer 230A preferably has a function of capturing and fixing hydrogen. Examples of a material of the insulating layer having a function of capturing and fixing hydrogen include a metal oxide having an amorphous structure. For example, a metal oxide, such as magnesium oxide or an oxide containing one or both of aluminum and hafnium, is preferably used. In such a metal oxide having an amorphous structure, an oxygen atom has a dangling bond and sometimes has a property of capturing or fixing hydrogen with the dangling bond. In other words, the metal oxide having an amorphous structure has high capability of capturing or fixing hydrogen.

A high-permittivity (high-k) material is preferably used for the insulating layer 250. An example of the high-k material is an oxide containing one or both of aluminum and hafnium. With use of the high-k material for the insulating layer 250, a gate potential applied during the operation of the transistor can be reduced while the physical thickness of the gate insulating layer is maintained. In addition, the equivalent oxide thickness (EOT) of the insulating layer functioning as the gate insulating layer can be reduced.

As described above, the layer that is included in the insulating layer 250 and is in contact with the oxide layer 230A is preferably formed using an oxide containing one or both of aluminum and hafnium, further preferably an oxide that has an amorphous structure and contains one or both of aluminum and hafnium, still further preferably aluminum oxide having an amorphous structure. In this embodiment, the layer that is included in the insulating layer 250 and is in contact with the oxide layer 230A is formed using aluminum oxide. Here, the layer that is included in the insulating layer 250 and is in contact with the oxide layer 230A is an insulating layer containing at least oxygen and aluminum. The aluminum oxide has an amorphous structure. In this case, the layer that is included in the insulating layer 250 and is in contact with the oxide layer 230A has an amorphous structure.

Furthermore, the insulating layer 250 may include an insulating layer with a thermally stable structure, such as silicon oxide or silicon oxynitride.

The insulating layer 250 may include, between a pair of insulating layers having a function of capturing and fixing hydrogen, an insulating layer with a thermally stable structure.

The insulating layer 250 preferably includes a barrier insulating layer against oxygen. This can inhibit oxidation of the conductive layer 242A, the conductive layer 242B, the conductive layer 260, and the like. In the case where the insulating layer 250 has a stacked-layer structure, a layer that is in contact with the conductive layer 242A and the conductive layer 242B and a layer that is in contact with the conductive layer 260 are each preferably a barrier insulating layer against oxygen.

Note that in this specification and the like, a barrier insulating layer refers to an insulating layer having a barrier property. A barrier property in this specification and the like means a function of inhibiting diffusion of a target substance (also referred to as having low permeability). Alternatively, the barrier property means a function of capturing and fixing (also referred to as gettering) a target substance.

Examples of a material of the barrier insulating layer against oxygen include an oxide containing one or both of aluminum and hafnium, magnesium oxide, gallium oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

The layer that is included in the insulating layer 250 and is in contact with the conductive layer 242A and the conductive layer 242B is preferably less likely to transmit oxygen than at least the insulating layer 280. When the layer has a barrier property against oxygen, oxidation of side surfaces of the conductive layer 242A and the conductive layer 242B and formation of oxide films on the side surfaces can be inhibited. Accordingly, a decrease in on-state current or field-effect mobility of the transistor 200 can be inhibited.

As illustrated in FIG. 3C and FIG. 3D, the insulating layer 250 is provided in contact with a side surface of the insulating layer 220, a side surface of the insulating layer 222A, a side surface of the insulating layer 224A, and the top surface and a side surface of the oxide layer 230A. When the layer that is included in the insulating layer 250 and is in contact with these surfaces has a barrier property against oxygen, release of oxygen from the channel formation region of the oxide layer 230A caused by heat treatment or the like can be inhibited. This can inhibit formation of oxygen vacancies in the oxide layer 230A. Even when an excess amount of oxygen is contained in the insulating layer 280, the oxygen can be inhibited from being excessively supplied to the oxide layer 230A, and an appropriate amount of oxygen can be supplied to the oxide layer 230A through the insulating layer 250. Thus, it is possible to prevent excessive oxidation of the source region and the drain region of the oxide layer 230A and inhibit a decrease in on-state current and field-effect mobility of the transistor 200.

The thickness of the insulating layer 250 is preferably greater than or equal to 0.1 nm and less than or equal to 30 nm, further preferably greater than or equal to 0.1 nm and less than or equal to 20 nm, still further preferably greater than or equal to 0.1 nm and less than or equal to 10 nm, yet still further preferably greater than or equal to 0.1 nm and less than or equal to 5.0 nm, yet still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm.

To form the insulating layer 250 having a small thickness as described above, an atomic layer deposition (ALD) method is preferably used for film formation. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables film formation at a lower temperature.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulating layer 250 can be formed on a side surface of the opening formed in the insulating layer 280 and the like, side end portions of the conductive layers 242A and 242B, and the like, with a small thickness like the above-described thickness and favorable coverage.

Note that some precursors used in an ALD method contain carbon or the like. Thus, in some cases, a film provided by an ALD method includes impurities such as carbon in a larger amount than a film provided by another film formation method. Note that impurities can be quantified by secondary ion mass spectrometry (SIMS), X-ray photoelectron spectroscopy (XPS), or auger electron spectroscopy (AES).

### <Insulating Layer 241 and Insulating Layer 275>

The insulating layer 275 is preferably a barrier insulating layer against oxygen to inhibit oxidation of the conductive layer 242A, the conductive layer 242B, the conductive layer 242C, and the like. Similarly, the insulating layer 241 is preferably a barrier insulating layer against oxygen to inhibit oxidation of the conductive layer 240A to the conductive layer 240G.

For the barrier insulating layer against oxygen, the description of the insulating layer 250 can be referred to.

The insulating layer 275 is preferably a barrier insulating layer against hydrogen to inhibit a reduction in hydrogen concentration of the source region and the drain region of the oxide layer 230A.

Examples of a material of the barrier insulating layer against hydrogen include oxides such as aluminum oxide, hafnium oxide, and tantalum oxide and nitrides such as silicon nitride.

### <Insulating Layer 215, Insulating Layer 220, Insulating Layer 222, Insulating Layer 282, and Insulating Layer 283>

To inhibit entry of hydrogen into the transistor 100 and the transistor 200, an insulating layer having a function of inhibiting diffusion of hydrogen is preferably used as one or both of an insulating layer covering the upper side of the transistor 100 and the transistor 200 and an insulating layer positioned below the transistor 100 and the transistor 200. Thus, at least one of the insulating layer 215, the insulating layer 220, and the insulating layer 222 (the insulating layer 222A and the insulating layer 222B) positioned below the transistor 100 and the transistor 200 is preferably an insulating layer having a function of inhibiting diffusion of hydrogen. At least one of the insulating layer 282 and the insulating layer 283 covering the upper side of the transistor 100 and the transistor 200 is preferably an insulating layer having a function of inhibiting diffusion of hydrogen.

At least one of the insulating layer 215, the insulating layer 220, the insulating layer 222, the insulating layer 282, and the insulating layer 283 preferably functions as a barrier insulating layer that inhibits diffusion of impurities such as water and hydrogen from the substrate side or from above the transistors into the transistors. Thus, at least one of the insulating layer 215, the insulating layer 220, the insulating layer 222, the insulating layer 282, and the insulating layer 283 preferably includes an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material that does not easily transmit the impurities). Alternatively, it is preferable to include an insulating material having a function of inhibiting diffusion of oxygen (e.g., at least one of an oxygen atom, an oxygen molecule, and the like) (an insulating material that does not easily transmit the oxygen).

Each of the insulating layer 215, the insulating layer 220, the insulating layer 222, the insulating layer 282, and the insulating layer 283 preferably includes an insulating layer having a function of inhibiting diffusion of oxygen and impurities such as water and hydrogen and can be formed using aluminum oxide, magnesium oxide, hafnium oxide, zirconium oxide, an oxide containing aluminum and hafnium (hafnium aluminate), an oxide containing hafnium and zirconium (hafnium zirconium oxide), gallium oxide, silicon nitride, silicon nitride oxide, or the like. For example, silicon nitride, which has a higher hydrogen barrier property, is preferably used for the insulating layer 283 and the insulating layer 220. For example, the insulating layer 282 preferably includes aluminum oxide, magnesium oxide, or the like, which has a function of capturing and fixing hydrogen well. For example, hafnium oxide, which has high capability of capturing or fixing hydrogen and is a high-permittivity (high-k) material, is preferably used for the insulating layer 222.

Such a structure can inhibit impurities such as water and hydrogen from diffusing into the transistors from an interlayer insulating film or the like placed above the insulating layer 283. Furthermore, impurities such as water and hydrogen can be inhibited from diffusing into the transistors from an interlayer insulating film or the like placed below the insulating layer 220. Moreover, hydrogen contained in the insulating layer 280, an insulating layer 224, the insulating layer 250, and the like can be captured and fixed in the insulating layer 282 or the insulating layer 222. Providing the insulating layer 282 and the insulating layer 283 can inhibit oxygen contained in the insulating layer 280 and the like from diffusing to above the transistors. Providing the insulating layer 222 and the insulating layer 220 can inhibit oxygen contained in the insulating layer 224 and the like from diffusing to below the transistors. With such a structure where the transistors are surrounded by upper and lower insulating layers having a function of inhibiting diffusion of oxygen and impurities such as water and hydrogen, excess oxygen and hydrogen can be inhibited from diffusing into the oxide semiconductor. Thus, the semiconductor device can have improved electrical characteristics and reliability.

### <Insulating Layer 224A and Insulating Layer 224B>

The insulating layer 224A and the insulating layer 224B can be formed using the same process and the same material. The insulating layer 224A is in contact with the oxide layer 230A and is thus preferably an oxide. Similarly, the insulating layer 224B is in contact with the oxide layer 235 and is thus preferably an oxide. For example, the insulating layer 224A and the insulating layer 224B preferably include silicon oxide or silicon oxynitride. In that case, oxygen can be supplied from the insulating layer 224A to the oxide layer 230A, so that oxygen vacancies can be reduced. Similarly, oxygen can be supplied from the insulating layer 224B to the oxide layer 235, so that oxygen vacancies can be reduced.

An insulating layer to be the insulating layer 224A is preferably processed into an island shape like an oxide layer to be the oxide layer 230A. In that case, the plurality of transistors 200 provided include the insulating layers 224A having substantially the same sizes. Accordingly, among the transistors 200, the amount of oxygen supplied from the insulating layer 224A to the oxide layer 230A is substantially the same. This can reduce variations in electrical characteristics of the transistors 200 in the substrate plane. Note that one embodiment of the present invention is not limited to this, and it is possible to employ a structure in which like the insulating layer 220, the insulating layer 224 is not patterned.

### <Insulating Layer 216, Insulating Layer 280, and Insulating Layer 284>

The insulating layer 216, the insulating layer 280, and the insulating layer 284 each preferably have a lower permittivity than the insulating layer 222. When a material with a low permittivity is used for an interlayer film, parasitic capacitance generated between wirings can be reduced.

For example, the insulating layer 216, the insulating layer 280, and the insulating layer 284 each preferably include one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region including oxygen that is released by heating can be easily formed.

The top surfaces of the insulating layer 216, the insulating layer 280, and the insulating layer 284 may be planarized.

The concentration of impurities such as water and hydrogen in the insulating layer 280 is preferably reduced. For example, the insulating layer 280 preferably includes an oxide containing silicon, such as silicon oxide or silicon oxynitride.

### <Conductive Layer 205A, Conductive Layer 205B, and Conductive Layer 242A to Conductive Layer 242C>

The conductive layer 205A, the conductive layer 205B, and the conductive layer 242A to the conductive layer 242C may each have a single-layer structure or a stacked-layer structure. The conductive layer 205A and the conductive layer 205B can be formed using the same process and the same material. The conductive layer 242A to the conductive layer 242C can be formed using the same process and the same material.

The conductive layer 205A, the conductive layer 205B, and the conductive layer 242A to the conductive layer 242C can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 205A, the conductive layer 205B, and the conductive layer 242A to the conductive layer 242C, a conductive material with low resistance that contains one or more of copper, silver, gold, and aluminum can be suitably used. Copper or aluminum is particularly preferable because of its high mass-productivity.

Each of the conductive layer 205B and the conductive layer 242A to the conductive layer 242C is in contact with the oxide layers, and is thus preferably formed using a conductive material that is not easily oxidized, a conductive material that maintains its low electrical resistance even after being oxidized, an oxide conductive material, or a conductive material that has a function of inhibiting diffusion of oxygen. Examples of the conductive material include a conductive material containing nitrogen and a conductive material containing oxygen. Thus, a decrease in conductivity of each of the conductive layer 205B and the conductive layer 242A to the conductive layer 242C can be inhibited.

An oxide conductor can be used for each of the conductive layer 205A, the conductive layer 205B, and the conductive layer 242A to the conductive layer 242C. Examples of an oxide conductor include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. A conductive oxide containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 205A, the conductive layer 205B, and the conductive layer 242A to the conductive layer 242C may have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 205A, the conductive layer 205B, and the conductive layer 242A to the conductive layer 242C. The use of a Cu—X alloy film results in lower manufacturing cost because the film can be processed by a wet etching process.

For each of the conductive layer 205A, the conductive layer 205B, and the conductive layer 242A to the conductive layer 242C, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain the conductivity even after being oxidized. Note that in the case where the conductive layer 205B and the conductive layer 242A to the conductive layer 242C each have a stacked-layer structure, at least a layer that is in contact with the oxide layer 230A or the oxide layer 230B is preferably formed using a conductive material that is less likely to be oxidized.

A nitride conductor may be used for each of the conductive layer 205A, the conductive layer 205B, and the conductive layer 242A to the conductive layer 242C. Examples of the nitride conductor include tantalum nitride and titanium nitride.

For example, the conductive layer 205A, the conductive layer 205B, and the conductive layer 242A to the conductive layer 242C can each have a single-layer structure of an oxide conductor film, a stacked-layer structure of a metal film and an oxide conductor film, or a stacked-layer structure of metal films. Examples of the oxide conductor film include an ITSO film. Examples of the metal film include a single-layer structure of a tungsten film, a single-layer structure of a titanium film, a single-layer structure of a copper film, or a three-layer structure of a titanium film, an aluminum film, and a titanium film.

For example, an ITSO film is preferably used for each of the conductive layer 205A, the conductive layer 205B, and the conductive layer 242A to the conductive layer 242C.

In FIG. 2B, the conductive layer 242A and the conductive layer 242B each have a two-layer structure. The conductive layer 242A is a stacked film of a conductive layer 242al and a conductive layer 242a2 over the conductive layer 242al, and the conductive layer 242B is a stacked film of a conductive layer 242b1 and a conductive layer 242b2 over the conductive layer 242b1. Here, a conductive material that is less likely to be oxidized or a conductive material having a function of inhibiting diffusion of oxygen is preferably used for the layers (the conductive layer 242al and the conductive layer 242b1) in contact with the oxide layer 230A. In that case, a decrease in conductivity of the conductive layer 242A and the conductive layer 242B can be inhibited. It is also possible to inhibit oxygen extraction from the oxide layer 230A and formation of an excessive amount of oxygen vacancies. For the layers (the conductive layer 242al and the conductive layer 242b1) in contact with the oxide layer 230A, a material that easily absorbs (extracts) hydrogen is preferably used, in which case the hydrogen concentration of an oxide layer 230 can be reduced.

For the conductive layer 242al and the conductive layer 242b1, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. For another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

For example, tantalum nitride or titanium nitride can be used for the conductive layer 242al and the conductive layer 242b1, and tungsten can be used for the conductive layer 242a2 and the conductive layer 242b2.

### <Conductive Layer 260 and Conductive Layer 265>

Each of the conductive layer 260 and the conductive layer 265 may have a single-layer structure or a stacked-layer structure. The conductive layer 260 and the conductive layer 265 can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 260 and the conductive layer 265, a conductive material with low resistance that contains one or more of copper, silver, gold, and aluminum can be suitably used. Copper or aluminum is particularly preferable because of its high mass-productivity.

An oxide conductor can be used for each of the conductive layer 260 and the conductive layer 265. Examples of the oxide conductor include the materials that are given as examples in the description of the conductive layer 205A and the like.

Each of the conductive layer 260 and the conductive layer 265 may have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 260 and the conductive layer 265. The use of a Cu—X alloy film results in lower manufacturing cost because the film can be processed by a wet etching process.

For example, it is preferable that the conductive layer 260 and the conductive layer 265 each have a stacked-layer structure of three layers: a titanium film, an aluminum film, and a titanium film.

The conductive layer 260 has a two-layer structure in the example illustrated in FIG. 2B. The conductive layer 260 illustrated in FIG. 2B includes a conductive layer 260a and a conductive layer 260b placed over the conductive layer 260a. For example, the conductive layer 260a is preferably placed to cover the bottom surface and a side surface of the conductive layer 260b. Here, the conductive layer 260a is preferably formed using a conductive material that is less likely to be oxidized or a conductive material having a function of inhibiting diffusion of oxygen.

For the conductive layer 260a, it is preferable to use a conductive material having a function of inhibiting diffusion of impurities such as a hydrogen atom, a hydrogen molecule, a water molecule, a nitrogen atom, a nitrogen molecule (e.g., N₂O, NO, and NO₂), a nitrogen oxide molecule, and a copper atom. Alternatively, it is preferable to use a conductive material having a function of inhibiting diffusion of oxygen (e.g., at least one of an oxygen atom, an oxygen molecule, and the like).

When the conductive layer 260a has a function of inhibiting diffusion of oxygen, the conductivity of the conductive layer 260b can be inhibited from being lowered because of oxidation due to oxygen included in the insulating layer 280 or the like. As the conductive material having a function of inhibiting diffusion of oxygen, for example, titanium, titanium nitride, tantalum, tantalum nitride, ruthenium, or ruthenium oxide is preferably used.

As the conductive layer 260b, a conductive layer having high conductivity is preferably used. For example, a conductive material containing tungsten, copper, or aluminum as its main component can be used for the conductive layer 260b. The conductive layer 260b may have a stacked-layer structure, for example, a stacked-layer structure of any of the above conductive materials and titanium or titanium nitride.

The conductive layer 260 and the conductive layer 265 are each formed in a self-aligned manner to fill the opening formed in the insulating layer 280 and the like. Through such formation, the conductive layer 260 can be placed to overlap with a region between the conductive layer 242A and the conductive layer 242B without alignment. Similarly, the conductive layer 265 can be placed in a predetermined position without alignment.

### <Conductive Layer 240A to Conductive Layer 240G>

The conductive layer 240A, the conductive layer 240B, the conductive layer 240C, the conductive layer 240D, the conductive layer 240E, the conductive layer 240F, and the conductive layer 240G may each have a single-layer structure or a stacked-layer structure.

In each of the conductive layer 240A to the conductive layer 240G, a layer that is in contact with the insulating layer 241 is preferably formed using a conductive material having a function of inhibiting transmission of impurities such as water and hydrogen. For example, a single-layer structure or a stacked-layer structure including one or more of tantalum, tantalum nitride, titanium, titanium nitride, ruthenium, and ruthenium oxide can be employed. In that case, impurities such as water and hydrogen can be inhibited from entering the oxide layer 230A and the like through the conductive layer 240A to the conductive layer 240G.

Each of the conductive layer 240A to the conductive layer 240G also functions as a wiring and thus preferably includes a conductive layer having high conductivity. For example, a conductive material containing tungsten, copper, or aluminum as its main component can be used.

The conductive layer 240A to the conductive layer 240G each preferably have a two-layer structure of titanium nitride and tungsten, for example.

### <Insulating Layer 271A to Insulating Layer 271C>

The insulating layer 271A, the insulating layer 271B, and the insulating layer 271C each function as the etching stopper at the time of processing a conductive film to be the conductive layer 242A, the conductive layer 242B, and the conductive layer 242C and are inorganic insulating layers that protect the conductive layer 242A, the conductive layer 242B, and the conductive layer 242C. Since the insulating layer 271A, the insulating layer 271B, and the insulating layer 271C are in contact with the conductive layer 242A, the conductive layer 242B, and the conductive layer 242C, the insulating layer 271A, the insulating layer 271B, and the insulating layer 271C are preferably inorganic insulating layers that are less likely to oxidize the conductive layer 242A, the conductive layer 242B, and the conductive layer 242C. For example, it is preferable that the insulating layer 271A, the insulating layer 271B, and the insulating layer 271C each have a two-layer structure, and it is preferable that nitride insulating films (e.g., silicon nitride or silicon nitride oxide) be used for layers that are in contact with the conductive layer 242A, the conductive layer 242B, and the conductive layer 242C and oxide insulating films as etching stoppers be formed over the nitride insulating films. Each of the oxide insulating films can be, for example, an oxide insulating film that can be used for the insulating layer 250, or specifically, a silicon oxide film.

### Structure Example 2

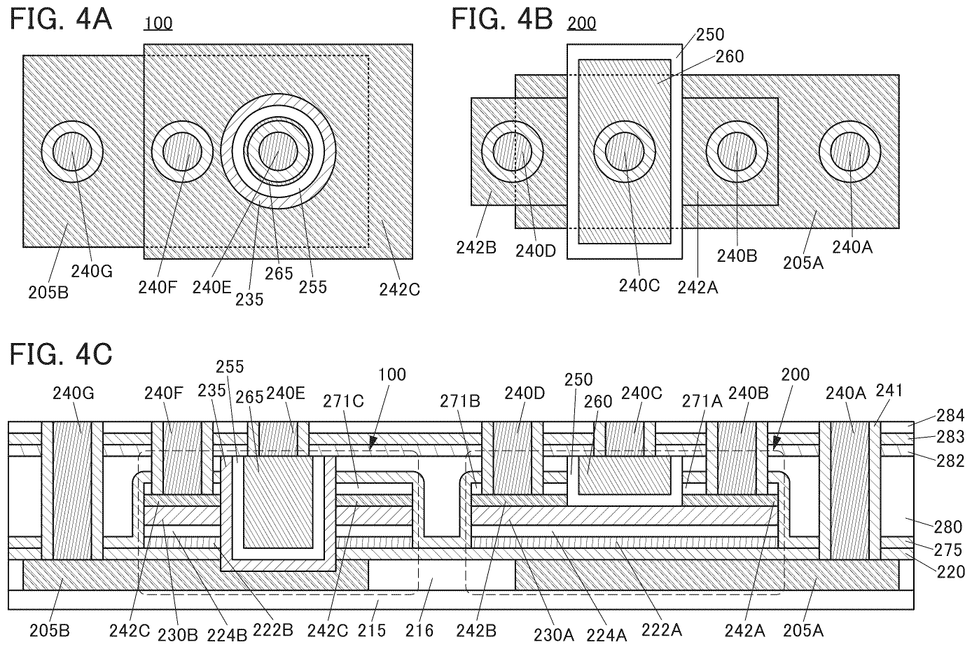

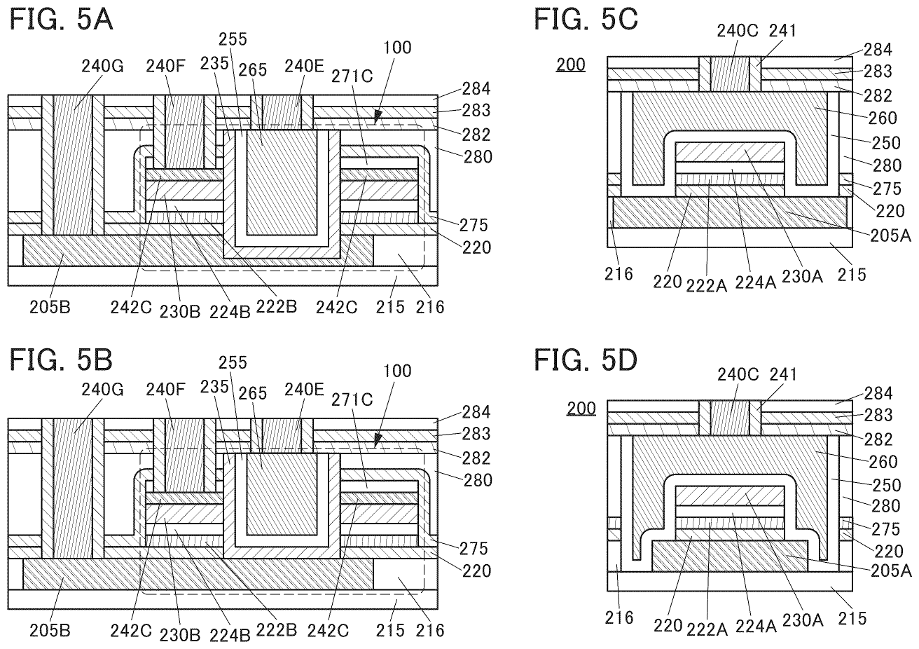

FIG. 4A is a top view of the transistor 100, FIG. 4B is a top view of the transistor 200, and FIG. 4C is a cross-sectional view of the transistor 100 and the transistor 200. FIG. 4C can also be regarded as a cross-sectional view of the transistor 200 in the channel length direction. FIG. 5A and FIG. 5B are cross-sectional views each illustrating a modification example of the transistor 100. FIG. 5C and FIG. 5D are cross-sectional views of the transistor 200 in the channel width direction.

Structure example 1 describes the example in which the size of the opening provided in the conductive layer 242C and the insulating layer 271C in a plan view is larger than the size of the opening provided in the insulating layer 220, the insulating layer 222B, the insulating layer 224B, and the oxide layer 230B in a plan view. Structure example 2 will describe an example in which the size of the opening provided in the conductive layer 242C and the insulating layer 271C in a plan view is the same as or substantially the same as the size of the opening provided in the insulating layer 220, the insulating layer 222B, the insulating layer 224B, and the oxide layer 230B in a plan view.

In FIG. 4C, the conductive layer 242C is in contact with the top surface of the oxide layer 230B, and the oxide layer 235 is not in contact with the top surface of the oxide layer 230B. The oxide layer 235 is in contact with the side surface of the conductive layer 242C and the side surface of the oxide layer 230B.

In the semiconductor device described in Structure example 2, openings can be formed in the insulating layer 220, the insulating layer 222B, the insulating layer 224B, the oxide layer 230B, the conductive layer 242C, and the insulating layer 271C at a time (without another step in between); thus, misalignment of the openings formed in the layers can be prevented and the manufacturing process can be simplified.

Here, the conductive layer 205B illustrated in FIG. 4C and FIG. 5A has a depressed portion in a position overlapping with the openings. Alternatively, as illustrated in FIG. 5B, the conductive layer 205B is not necessarily provided with a depressed portion.

In FIG. 5B, the region of the oxide layer 235 that is in contact with the side surface of the insulating layer 224B overlaps with the conductive layer 265. The region of the oxide layer 235 that is in contact with the side surface of the insulating layer 224B functions as the channel formation region of the transistor 100. It is thus preferable to use an oxide insulating film for the insulating layer 224B.

In FIG. 4C, the region of the oxide layer 235 that is in contact with the side surface of the insulating layer 224B and the region of the oxide layer 235 that is in contact with the side surface of the insulating layer 222B overlap with the conductive layer 265 (faces the conductive layer 265) to enable an offset region to be smaller than that in the structure illustrated in FIG. 5B, which is preferable. Similarly, the region of the oxide layer 235 that is in contact with the side surface of the insulating layer 220 also overlaps with the conductive layer 265 (faces the conductive layer 265) in FIG. 5A to enable an offset region to be smaller than that in the structure illustrated in FIG. 4C, which is preferable. Accordingly, a decrease in field-effect mobility due to the offset region can be inhibited.

Note that the structure of the transistor 200 illustrated in each of FIG. 4B, FIG. 4C, FIG. 5C, and FIG. 5D is similar to that in Structure example 1.

As described above, the semiconductor device of this embodiment includes the transistors having at least two types of structures and formed on the same plane by the steps some of which are shared. The vertical transistor with an extremely short channel length is used as a transistor required to have a high on-state current. Meanwhile, the planar transistor with a long channel length and a back gate is used as a transistor required to have high saturation characteristics. Accordingly, the semiconductor device can have high performance.

This embodiment can be combined with the other embodiments as appropriate. In this specification, in the case where a plurality of structure examples are shown in one embodiment, the structure examples can be combined as appropriate.

### Embodiment 2

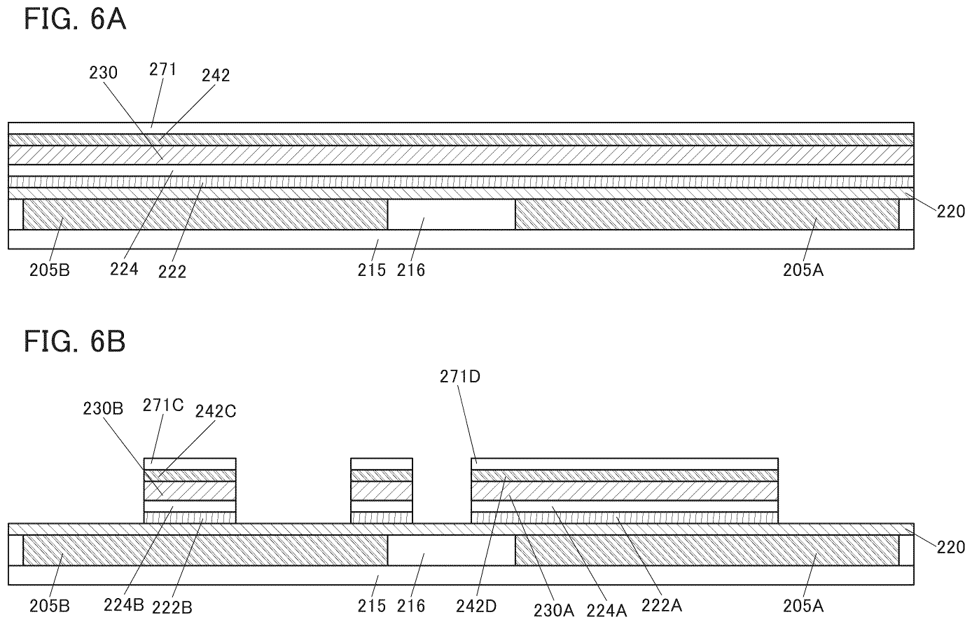

In this embodiment, a method for manufacturing the semiconductor device of one embodiment of the present invention will be described with reference to FIG. 6 to FIG. 13. Note that as for a material and a formation method of each component, portions similar to the portions described in Embodiment 1 are not described in some cases.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

Furthermore, CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, a thermal CVD method, which does not use plasma, does not cause such plasma damage, and thus can increase the yield of the semiconductor device. Furthermore, a film with few defects can be obtained by a thermal CVD method, which does not cause plasma damage during film formation.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are film formation methods that enable good step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

By a CVD method, a film with a certain composition can be formed depending on the flow rate ratio of the source gas. For example, when the flow rate ratio of the source gas is changed during the film formation by a CVD method, a film having a continuously changed composition can be formed. In the case where a film is formed while the flow rate ratio of the source gas is changed, the time taken for transfer or pressure adjustment is saved, and thus, the time taken for the film formation can be shortened as compared to the case where a film is formed using a plurality of film formation chambers. Thus, the productivity of the semiconductor device can be increased in some cases.

By an ALD method, a film with a certain composition can be formed by concurrently introducing different kinds of precursors. In the case where different kinds of precursors are introduced, a film with a certain composition can be formed by controlling the number of cycles for each of the precursors.

Thin films included in the semiconductor device (e.g., insulating films, semiconductor films, and conductive films) can be formed by a wet film-formation method such as a spin coating method, a dip coating method, a spray coating method, an inkjet method, dispensing, screen printing, offset printing, a doctor knife method, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet rays, KrF laser light, ArF laser light, or the like can be used. The light exposure may be performed by liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely fine processing can be performed. Note that a photomask is not needed when the light exposure is performed by scanning with a beam such as an electron beam. For etching of thin films, a dry etching method, a wet etching method, a sandblasting method, or the like can be used.

### Manufacturing Method Example 1

First, the insulating layer 216 is formed over the insulating layer 215, and openings reaching the insulating layer 215 are formed in the insulating layer 216. Next, a conductive film to be the conductive layer 205A and the conductive layer 205B is formed over the insulating layer 215 and over the insulating layer 216. Then, part of the conductive film is removed by CMP treatment, so that the insulating layer 216 is exposed. As a result, the conductive layer 205A and the conductive layer 205B can be provided in the openings in the insulating layer 216 (FIG. 6A).

The insulating layer 215 and the insulating layer 216 can each be formed by a sputtering method, a CVD method, an MBE method, a PLD method, or an ALD method. A sputtering method is preferably employed, in which case the film formation gas does not need to include a molecule containing hydrogen, and thus, the hydrogen concentration in the insulating layers can be reduced.

The insulating layer 215 and the insulating layer 216 are preferably formed successively without exposure to the air. For example, a multi-chamber film formation apparatus is preferably used. In that case, the amount of hydrogen in the insulating layer 215 and the insulating layer 216 can be reduced, and furthermore, entry of hydrogen into the films in intervals between film formation steps can be inhibited.

At the time of the formation of the openings in the insulating layer 216, a depressed portion may be formed in the insulating layer 215.

The conductive film to be the conductive layer 205A and the conductive layer 205B can be formed by a sputtering method, a CVD method, an MBE method, a PLD method, an ALD method, a plating method, or the like.

Note that the insulating layer 216 may be partly removed during the CMP treatment.

Next, the insulating layer 220, the insulating layer 222, the insulating layer 224, the oxide layer 230, a conductive layer 242, and an insulating layer 271 are formed over the conductive layer 205A, the conductive layer 205B, and the insulating layer 216 (FIG. 6A).

In this embodiment, the insulating layer 222A and the insulating layer 222B each having an island shape are formed over the insulating layer 220; thus, the insulating layer 222 is preferably a film having high etching selectivity with respect to the insulating layer 220. For example, one of the insulating layer 220 and the insulating layer 222 is preferably formed using silicon nitride or silicon nitride oxide. The other of the insulating layer 220 and the insulating layer 222 is preferably formed using aluminum oxide, hafnium oxide, an oxide containing aluminum and hafnium (hafnium aluminate), or hafnium zirconium oxide.

Note that in the case where the insulating layer 222A and the insulating layer 222B are not provided to have island shapes, i.e., in the case where the insulating layer 224A and the insulating layer 224B each having an island shape are provided over the insulating layer 220 and the insulating layer 222, the insulating layer 224 is preferably a film having high etching selectivity with respect to the insulating layer 222.

The insulating layer 220, the insulating layer 222, and the insulating layer 224 can each be formed by a sputtering method, a CVD method, an MBE method, a PLD method, or an ALD method, for example.

The insulating layer 224 is preferably formed by a sputtering method. In that case, the film formation gas does not need to include a molecule containing hydrogen; thus, the hydrogen concentration in the insulating layer 224 can be reduced. Since the oxide layer 230 is provided over and in contact with the insulating layer 224, the hydrogen concentration of the insulating layer 224 is preferably reduced.

Specifically, it is preferable that the insulating layer 220 be formed using silicon nitride or silicon nitride oxide, the insulating layer 222 be formed using aluminum oxide, hafnium oxide, an oxide containing aluminum and hafnium (hafnium aluminate), or hafnium zirconium oxide, and the insulating layer 224 be formed using silicon oxide or silicon oxynitride.

Note that heat treatment may be performed before the insulating layer 224 is formed. The heat treatment may be performed under reduced pressure, and the insulating layer 224 may be successively formed without exposure to the air. Such treatment can remove moisture and hydrogen adsorbed onto the surface of the insulating layer 222 and further can reduce the moisture concentration and the hydrogen concentration in the insulating layer 222. The insulating layer 220 is provided in contact with the bottom surface of the insulating layer 222, whereby entry of an impurity such as moisture or hydrogen from below the insulating layer 220, which is caused by the heat treatment, can be prevented. The temperature of the heat treatment is preferably higher than or equal to 100° C. and lower than or equal to 400° C. In this embodiment, the temperature of the heat treatment is 250° C.

The oxide layer 230 can be formed by a sputtering method, a CVD method, an MBE method, a PLD method, or an ALD method, for example.

In the case where the oxide layer 230 is formed by a sputtering method, oxygen or a mixed gas of oxygen and a noble gas is used as a sputtering gas. Increasing the proportion of oxygen included in the sputtering gas can increase the amount of excess oxygen in the formed oxide film. In the case where the oxide layer 230 is formed by a sputtering method, an In—M—Zn oxide target or the like can be used.

During the formation of the oxide layer 230, part of oxygen contained in the sputtering gas is supplied to the insulating layer 224 in some cases. Thus, the proportion of oxygen contained in the sputtering gas is preferably higher than or equal to 70%, further preferably higher than or equal to 80%, still further preferably 100%.

In the formation of the oxide layer 230 by a sputtering method, setting the proportion of oxygen contained in the sputtering gas to higher than 30% and lower than or equal to 100%, preferably higher than or equal to 70% and lower than or equal to 100% allows formation of an oxygen-excess oxide semiconductor. A transistor including an oxygen-excess oxide semiconductor in its channel formation region can have relatively high reliability. Note that one embodiment of the present invention is not limited thereto. When the proportion of oxygen contained in the sputtering gas at the time of the film formation is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in its channel formation region can have relatively high field-effect mobility. When the film formation is performed while the substrate is heated, the crystallinity of the oxide layer can be improved.

Alternatively, the oxide layer 230 is preferably formed by an ALD method. By an ALD method, a thin film can be formed with good controllability.

Note that the insulating layer 224 and the oxide layer 230 are preferably formed without exposure to the air. For example, a multi-chamber film formation apparatus is preferably used. In that case, entry of hydrogen into the insulating layer 224 and the oxide layer 230 in intervals between film formation steps can be inhibited.

Next, heat treatment is preferably performed. The heat treatment is performed in a temperature range where the oxide layer 230 does not become polycrystal. The temperature of the heat treatment is preferably higher than or equal to 100° C. and lower than or equal to 650° C., further preferably higher than or equal to 250° C. and lower than or equal to 600° C., still further preferably higher than or equal to 350° C. and lower than or equal to 550° C.

Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, heat treatment may be performed in a nitrogen gas or inert gas atmosphere, and then another heat treatment may be performed in an atmosphere containing an oxidizing gas at higher than or equal to 10 ppm, higher than or equal to 1%, or higher than or equal to 10% in order to compensate for released oxygen.

The gas used in the above heat treatment is preferably highly purified. For example, the amount of moisture contained in the gas used in the above heat treatment is preferably lower than or equal to 1 ppb, further preferably lower than or equal to 0.1 ppb, still further preferably lower than or equal to 0.05 ppb. The heat treatment performed using a highly purified gas can prevent entry of moisture or the like into the oxide layer 230 as much as possible.

In this embodiment, the heat treatment is performed at 450° C. for one hour with the flow rate ratio of a nitrogen gas to an oxygen gas being 4:1. By the heat treatment using the oxygen gas, impurities such as carbon, water, and hydrogen in the oxide layer 230 can be reduced. The reduction of impurities in the film improves the crystallinity of the oxide layer 230, thereby offering a dense structure with higher density. Accordingly, the crystal region in the oxide layer 230 can be expanded, and an in-plane variation in the crystal region in the oxide layer 230 can be reduced. Accordingly, an in-plane variation of electrical characteristics of transistors can be reduced.

By the heat treatment, hydrogen in the insulating layer 216, the insulating layer 224, and the oxide layer 230 moves to the insulating layer 222 and is absorbed by the insulating layer 222. In other words, hydrogen in the insulating layer 216, the insulating layer 224, and the oxide layer 230 diffuses to the insulating layer 222. Accordingly, the hydrogen concentration of the insulating layer 222 increases, while the hydrogen concentrations in the insulating layer 216, the insulating layer 224, and the oxide layer 230 decrease.

In particular, the insulating layer 224 includes a portion functioning as the gate insulating layer of the transistor 200, and the oxide layer 230 includes a portion functioning as the channel formation region of the transistor 200. The transistor 200 formed using the insulating layer 224 and the oxide layer 230 with reduced hydrogen concentrations is preferable because of having favorable reliability.

When the conductive layer 242 is formed over and in contact with the oxide layer 230 after the formation of the oxide layer 230 without an etching step or the like in between, the top surface of the oxide layer 230 can be protected by the conductive layer 242. This can inhibit diffusion of impurities into the oxide layer 230 included in the transistor 200, whereby the electrical characteristics and reliability of the semiconductor device can be improved.

The conductive layer 242 can be formed by a sputtering method, a CVD method, an MBE method, a PLD method, a plating method, or an ALD method.

Note that heat treatment may be performed before the formation of the conductive layer 242. This heat treatment may be performed under reduced pressure, and the conductive layer 242 may be successively formed without exposure to the air. Such treatment can remove moisture and hydrogen adsorbed onto the surface of the oxide layer 230, and further can reduce the moisture concentration and the hydrogen concentration in the oxide layer 230. The temperature of the heat treatment is preferably higher than or equal to 100° C. and lower than or equal to 400° C. In this embodiment, the temperature of the heat treatment is 250° C.

The insulating layer 271 can be formed by a sputtering method, a CVD method, an MBE method, a PLD method, an ALD method, or the like.

Note that heat treatment may be performed before the insulating layer 271 is formed. The heat treatment may be performed under reduced pressure, and the insulating layer 271 may be successively formed without exposure to the air. Such treatment can remove moisture and hydrogen adsorbed onto the surface of the conductive layer 242 and can reduce the moisture concentration and the hydrogen concentration in the conductive layer 242. The temperature of the heat treatment is preferably higher than or equal to 100° C. and lower than or equal to 400° C. In this embodiment, the temperature of the heat treatment is 250° C.

Next, the insulating layer 222, the insulating layer 224, the oxide layer 230, the conductive layer 242, and the insulating layer 271 are processed into island shapes by a lithography method to form the insulating layer 222A, the insulating layer 222B, the insulating layer 224A, the insulating layer 224B, the oxide layer 230A, the oxide layer 230B, the conductive layer 242C, a conductive layer 242D, the insulating layer 271C, and an insulating layer 271D (FIG. 6B). Note that in a portion where none of these components are provided, the insulating layer 220 is exposed.

Specifically, a stacked-layer structure of the insulating layer 222A, the insulating layer 224A, the oxide layer 230A, the conductive layer 242D, and the insulating layer 271D is formed so as to at least partly overlap with the conductive layer 205A. Furthermore, a stacked-layer structure of the insulating layer 222B, the insulating layer 224B, the oxide layer 230B, the conductive layer 242C, and the insulating layer 271C is formed so as to at least partly overlap with the conductive layer 205B. Furthermore, an opening reaching the insulating layer 220 is provided in the insulating layer 222B, the insulating layer 224B, the oxide layer 230B, the conductive layer 242C, and the insulating layer 271C in a position overlapping with the conductive layer 205B.

The step of processing into island shapes and the step of providing the opening in FIG. 6B can be performed independently, and in that case, there is no limitation on the order. Alternatively, the processing into island shapes and the formation of the opening may be performed at a time in the following manner: light exposure using a mask for processing into a quadrangular island shape and light exposure using a mask for providing a circular opening are performed, and then, etching is performed. Light exposure using a multi-tone mask (typically a half-tone mask or a gray-tone mask) may be used.

It is preferable that the insulating layer 222, the insulating layer 224, the oxide layer 230, the conductive layer 242, and the insulating layer 271 be collectively processed into island shapes. In that case, it is preferable that a side end portion of the conductive layer 242D be substantially aligned with the side end portion of the oxide layer 230A. Furthermore, it is preferable that the side end portion of the insulating layer 224A be substantially aligned with the side end portion of the oxide layer 230A. Furthermore, it is preferable that the side end portion of the insulating layer 222A be substantially aligned with the side end portion of the oxide layer 230A. Moreover, it is preferable that a side end portion of the insulating layer 271D be substantially aligned with the side end portion of the conductive layer 242D. In a similar manner, it is preferable that the side end portion of the conductive layer 242C be substantially aligned with the side end portion of the oxide layer 230B. Furthermore, it is preferable that the side end portion of the insulating layer 224B be substantially aligned with the side end portion of the oxide layer 230B. Furthermore, it is preferable that the side end portion of the insulating layer 222B be substantially aligned with the side end portion of the oxide layer 230B. Moreover, it is preferable that a side end portion of the insulating layer 271C be substantially aligned with the side end portion of the conductive layer 242C. With such a structure, the number of steps for the semiconductor device of one embodiment of the present invention can be reduced. Thus, a method for manufacturing a semiconductor device with high productivity can be provided.

Processing the insulating layer 224 into an island shape allows the insulating layer 275 to be provided in contact with the side surface of the insulating layer 224A and the top surface of the insulating layer 220 in a step to be described later. That is, the insulating layer 224A can be separated from the insulating layer 280 by the insulating layer 275. Such a structure can prevent an excess amount of oxygen and an impurity such as hydrogen from entering the oxide layer 230A from the insulating layer 280 through the insulating layer 224.

A dry etching method or a wet etching method can be used for the processing. A dry etching method is preferable because it is suitable for fine processing.

The processing of the insulating layer 222, the processing of the insulating layer 224, the processing of the oxide layer 230, the processing of the conductive layer 242, and the processing of the insulating layer 271 may be performed under different conditions.

Note that in a lithography method, first, a resist is exposed to light through a mask. Next, a region exposed to light is removed or left using a developing solution, so that a resist mask is formed. Then, etching treatment through the resist mask is performed, whereby a conductive layer, a semiconductor layer, an insulating layer, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that the use of a mask may be unnecessary in the case of using an electron beam or an ion beam.

Note that the resist mask that is no longer needed after the processing can be removed by dry etching treatment such as ashing using oxygen plasma (hereinafter, referred to oxygen plasma treatment in some cases), wet etching treatment, wet etching treatment after dry etching treatment, or dry etching treatment after wet etching treatment.

In addition, a hard mask formed of an insulating layer or a conductive layer may be used under the resist mask. In the case of using a hard mask, a hard mask with a desired shape can be formed in the following manner: an insulating film or a conductive film that is the material of the hard mask is formed over the insulating layer 271, a resist mask is formed thereover, and then the hard mask material is etched. The etching of the insulating layer 271 and the like may be performed after removing the resist mask or with the resist mask remaining. In the latter case, the resist mask is sometimes eliminated during the etching. The hard mask may be removed by etching after the etching of the oxide layer 230 and the like. Meanwhile, the hard mask is not necessarily removed when the hard mask material does not affect later steps or can be utilized in later steps.

An SOC (Spin On Carbon) film and an SOG (Spin On Glass) film may be formed between an object to be processed and the resist mask. Using the SOC film and the SOG film as masks can improve the adhesion of the resist mask, resulting in enhancement of the durability of a mask pattern. For example, the SOC film, the SOG film, and the resist mask are formed in this order over the object to be processed and lithography can be performed.

An etching gas containing a halogen can be used as an etching gas for dry etching treatment; specifically, an etching gas containing one or more of fluorine, chlorine, and bromine can be used. As the etching gas, for example, a C₄F₆ gas, a CF₆ gas, a C₄F₈ gas, a CF₄ gas, a SF₆ gas, a CHF₃ gas, a CH₂F₂ gas, a Cl₂ gas, a BCl₃ gas, a SiCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. Depending on an object to be subjected to the dry etching treatment, a gas that contains a hydrocarbon gas or a hydrogen gas and does not contain a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched.

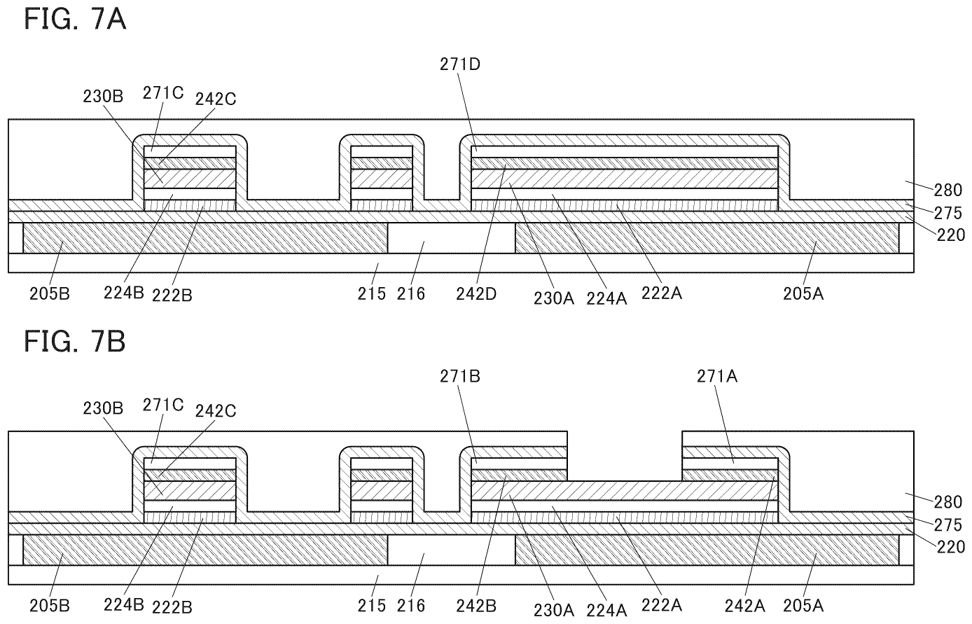

Next, the insulating layer 275 is formed over and in contact with the insulating layer 220 to cover the stacked-layer structure of the insulating layer 222A, the insulating layer 224A, the oxide layer 230A, the conductive layer 242D, and the insulating layer 271D and the stacked-layer structure of the insulating layer 222B, the insulating layer 224B, the oxide layer 230B, the conductive layer 242C, and the insulating layer 271C, and the insulating layer 280 is formed over the insulating layer 275 (FIG. 7A).

For the insulating layer 280, an insulating film having a flat top surface is preferably formed by forming an insulating film to be the insulating layer 280 and then performing CMP treatment on the insulating film.

The insulating layer 275 and the insulating layer 280 can each be formed by a sputtering method, a CVD method, an MBE method, a PLD method, or an ALD method, for example.

For example, for the insulating layer 275, a film of silicon nitride is preferably formed by a PEALD method. Alternatively, for the insulating layer 275, it is preferable that a film of aluminum oxide be formed by a sputtering method and a film of silicon nitride be formed thereover by a PEALD method. When the insulating layer 275 has the above-described structure, the function of inhibiting diffusion of oxygen and impurities such as water and hydrogen can be improved.

In this manner, the oxide layer 230A and the conductive layer 242D can be covered with the insulating layer 275 having a function of inhibiting diffusion of oxygen. This can inhibit direct diffusion of oxygen from the insulating layer 280 or the like into the insulating layer 222A, the insulating layer 224A, the oxide layer 230A, and the conductive layer 242D in a later step.

For the insulating layer 280, a film of silicon oxide is preferably formed by a sputtering method. When the insulating film to be the insulating layer 280 is formed by a sputtering method in an oxygen-containing atmosphere, the insulating layer 280 including excess oxygen can be formed. With the use of a sputtering method, which does not need to use a molecule containing hydrogen in a film formation gas, the hydrogen concentration in the insulating layer 280 can be reduced. Note that heat treatment may be performed before the formation of the insulating film.

The heat treatment may be performed under reduced pressure, and the insulating film may be successively formed without exposure to the air. Such treatment can remove moisture and hydrogen adsorbed onto the surface of the insulating layer 275 and the like, and further can reduce the moisture concentration and the hydrogen concentration in each of the oxide layer 230A and the insulating layer 224A. For the heat treatment, the above heat treatment conditions can be used.

Next, the conductive layer 242D, the insulating layer 271D, the insulating layer 275, and the insulating layer 280 are processed by a lithography method to form an opening reaching the oxide layer 230A (FIG. 7B). The opening reaching the oxide layer 230A is provided in a region where the oxide layer 230A and the conductive layer 205A overlap with each other.

A dry etching method or a wet etching method can be used for the processing. A dry etching method is preferable because it is suitable for fine processing. A dry etching method enables anisotropic etching and is thus suitable for forming an opening with a high aspect ratio. Note that the above description can be referred to for the conditions and an apparatus for a dry etching method.

The processing of the conductive layer 242D, the processing of the insulating layer 271D, the processing of the insulating layer 275, and the processing of the insulating layer 280 may be performed under different conditions.

By the processing, the conductive layer 242D is divided into the conductive layer 242A and the conductive layer 242B each having an island shape. Similarly, the insulating layer 271D is divided into the insulating layer 271A and the insulating layer 271B each having an island shape.

The width of the opening is preferably small because the channel length of the transistor 200 reflects the width. For example, the width of the opening is preferably less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm. In order to process the opening minutely, a lithography method using an electron beam or short-wavelength light such as EUV light is preferably employed.

For example, an SOC film, an SOG film, and a resist mask are formed in this order over the insulating layer 280 and lithography can be performed. A resist mask having an opening is formed using an electron beam or short-wavelength light such as EUV light, and the SOG film, the SOC film, the insulating layer 280, the insulating layer 275, the insulating layer 271D, and the conductive layer 242D are processed with use of the resist mask.

By the above etching treatment, impurities might be attached onto the top surface and the side surface of the oxide layer 230A, the side surfaces of the conductive layers 242A and 242B, side surfaces of the insulating layers 271A and 271B, the side surface of the insulating layer 275, a side surface of the insulating layer 280, and the like or the impurities might diffuse thereinto. A step of removing the impurities may be performed. In addition, a damaged region might be formed on the surface of the oxide layer 230A by the above dry etching. Such a damaged region may be removed. The impurities come from components contained in the insulating layer 280, the insulating layer 275, the insulating layers 271A and 271B, and the conductive layers 242A and 242B; components contained in a member of an apparatus used to form the opening; and components contained in a gas or a liquid used for the etching, for instance. Examples of the impurities include hafnium, aluminum, silicon, tantalum, fluorine, and chlorine.

In particular, impurities such as aluminum and silicon might reduce the crystallinity of the oxide layer 230A. Thus, it is preferable that impurities such as aluminum and silicon be removed from the surface of the oxide layer 230A and the vicinity thereof. The concentration of the impurities is preferably reduced. For example, the concentration of aluminum atoms at the surface of the oxide layer 230A and the vicinity thereof is preferably lower than or equal to 5.0 atomic %, further preferably lower than or equal to 2.0 atomic %, still further preferably lower than or equal to 1.5 atomic %, yet still further preferably lower than or equal to 1.0 atomic %, yet still further preferably lower than 0.3 atomic %.

Note that since the density of a crystal structure is reduced in a low-crystallinity region of the oxide layer 230A due to impurities such as aluminum and silicon, a large amount of VoH is formed; thus, the transistor 200 is likely to have normally-on characteristics. Hence, the low-crystallinity region of the oxide layer 230A is preferably reduced or removed.

In contrast, the oxide layer 230A preferably has a layered CAAC structure. In particular, the CAAC structure preferably reaches a lower end portion of the drain in the oxide layer 230A. Here, in the transistor 200, the conductive layer 242A or the conductive layer 242B preferably functions as the drain. In other words, the oxide layer 230A in the vicinity of the lower end portion of the conductive layer 242A or the conductive layer 242B preferably has a CAAC structure. Such removal of the low-crystallinity region of the oxide layer 230A and formation of the CAAC structure also in an end portion of the drain, which significantly affects the drain breakdown voltage, can further suppress a change in electrical characteristics of the transistor 200. In addition, the reliability of the transistor 200 can be improved.

In order to remove impurities and the like attached to the surface of the oxide layer 230A in the above etching step, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in combination as appropriate.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, these cleanings may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferably used, and a frequency higher than or equal to 900 kHz is further preferably used. Damage to the oxide layer 230A and the like can be reduced with such a frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the above cleaning treatment, wet cleaning using diluted ammonia water is performed in this embodiment. The cleaning treatment can remove impurities that are attached onto the surfaces of the oxide layer 230A and the like or diffuse into the oxide layer 230A and the like. Furthermore, the crystallinity of the oxide layer 230A can be increased.

After the etching or the cleaning, heat treatment may be performed. The temperature of the heat treatment is preferably higher than or equal to 100° C. and lower than or equal to 650° C., further preferably higher than or equal to 250° C. and lower than or equal to 600° C., still further preferably higher than or equal to 350° C. and lower than or equal to 550° C., yet still further preferably higher than or equal to 350° C. and lower than or equal to 400° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed at 350° C. for one hour at a flow rate ratio of a nitrogen gas to an oxygen gas of 4:1. In that case, oxygen can be supplied to the oxide layer 230A to reduce oxygen vacancies. In addition, the crystallinity of the oxide layer 230A can be improved by such heat treatment. Furthermore, hydrogen remaining in the oxide layer 230A reacts with supplied oxygen, so that the hydrogen can be removed as H₂O (dehydration). This can inhibit recombination of hydrogen remaining in the oxide layer 230A with oxygen vacancies and resultant formation of VoH. The heat treatment may be performed under reduced pressure. Alternatively, heat treatment may be performed in an oxygen atmosphere, and then heat treatment may be successively performed in a nitrogen atmosphere without exposure to the air.

In the case where heat treatment is performed in a state where the conductive layer 242A and the conductive layer 242B are in contact with the oxide layer 230A, the sheet resistance sometimes decreases in each of a region of the oxide layer 230A that overlaps with the conductive layer 242A and a region of the oxide layer 230A that overlaps with the conductive layer 242B. Furthermore, the carrier concentration sometimes increases. Thus, the resistance of each of the region of the oxide layer 230A that overlaps with the conductive layer 242A and the region of the oxide layer 230A that overlaps with the conductive layer 242B can be lowered in a self-aligned manner. Similarly, when heat treatment is performed in a state where the conductive layer 242C is in contact with the oxide layer 230B, the resistance of the oxide layer 230B can be reduced.

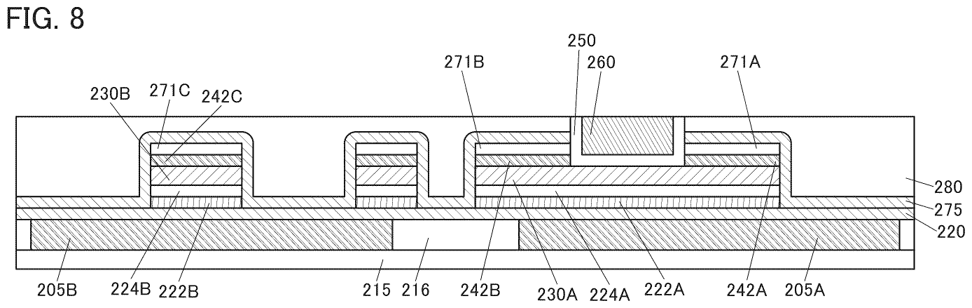

Next, an insulating film to be the insulating layer 250 is formed to fill the opening, a conductive film to be the conductive layer 260 is formed over the insulating film, and the insulating film and the conductive film are polished by CMP treatment until the insulating layer 280 is exposed. That is, portions of the insulating film and the conductive film that are exposed from the opening are removed. In this manner, the insulating layer 250 and the conductive layer 260 are formed in the opening overlapping with the conductive layer 205A (FIG. 8). Accordingly, the insulating layer 250 is provided in contact with the inner wall and the side surface of the opening overlapping with the oxide layer 230A. The conductive layer 260 is positioned to fill the opening with the insulating layer 250 therebetween. In this manner, the transistor 200 is formed.

The insulating film to be the insulating layer 250 can be formed by a sputtering method, a CVD method, an MBE method, a PLD method, or an ALD method, for example. The insulating film is preferably formed by an ALD method. The insulating layer 250 is preferably formed to have a small thickness, and a variation in the film thickness needs to be reduced. Since an ALD method is a film formation method in which a precursor and a reactant (e.g., oxidizer) are alternately introduced and the thickness can be adjusted with the number of repetition times of the cycle, accurate control of the thickness is possible. Furthermore, the insulating layer 250 needs to be formed to favorably cover the bottom surface and the side surface of the opening. By an ALD method, atomic layers can be deposited one by one along the bottom surface and the side surface of the opening, whereby the insulating layer 250 can be formed in the opening with good coverage.

When the insulating film to be the insulating layer 250 is formed by an ALD method, ozone (O₃), oxygen (O₂), water (H₂O), or the like can be used as the oxidizer. When an oxidizer that does not contain hydrogen, such as ozone (O₃) or oxygen (O₂), is used, the amount of hydrogen diffusing to the oxide layer 230A can be reduced.

As the insulating film to be the insulating layer 250, for example, an insulating film having a three-layer structure can be formed in the following manner: a film of aluminum oxide is formed by a thermal ALD method, a film of silicon oxide is formed by a PEALD method, and a film of silicon nitride is formed by a PEALD method. Alternatively, an insulating film having a four-layer structure may be formed by forming a film of hafnium oxide by a thermal ALD method between the film of silicon oxide and the film of silicon nitride.

After the insulating film to be the insulating layer 250 is formed, microwave treatment is preferably performed in an oxygen-containing atmosphere. Here, the microwave treatment refers to, for example, treatment using an apparatus including a power source that generates high-density plasma with the use of a microwave. In this specification and the like, a microwave refers to an electromagnetic wave having a frequency higher than or equal to 300 MHz and lower than or equal to 300 GHz. Note that in the case where the insulating layer 250 has a stacked-layer structure, the microwave treatment is not necessarily performed after the formation of all layers. In the case where the insulating film having the above three-layer structure is formed, formation of the film of aluminum oxide and the film of silicon oxide may be followed by microwave treatment and subsequent formation of the film of silicon nitride. In the case where the insulating film having the above four-layer structure is formed, formation of the film of aluminum oxide and the film of silicon oxide may be followed by microwave treatment, subsequent formation of the film of hafnium oxide, further microwave treatment, and subsequent formation of the film of silicon nitride. In the above manner, the microwave treatment in an oxygen-containing atmosphere may be performed multiple times (at least two or more times).

The microwave treatment is preferably performed with a microwave treatment apparatus including a power source for generating high-density plasma using microwaves, for example. Here, the frequency of the microwave treatment apparatus is preferably higher than or equal to 300 MHz and lower than or equal to 300 GHz, further preferably higher than or equal to 2.4 GHz and lower than or equal to 2.5 GHZ, and can be set to 2.45 GHz, for example. Oxygen radicals at a high density can be generated with high-density plasma. The electric power of the power source that applies microwaves of the microwave treatment apparatus is preferably higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be efficiently introduced into the oxide layer 230A.

The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa. The treatment temperature is preferably lower than or equal to 750° C., further preferably lower than or equal to 500° C., and can be set to approximately 250° C., for example. The oxygen plasma treatment may be followed successively by heat treatment without exposure to the external air. The temperature of the heat treatment is preferably higher than or equal to 100° C. and lower than or equal to 750° C., further preferably higher than or equal to 300° C. and lower than or equal to 500° C., for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration in the oxide layer 230A can be reduced by thus performing the microwave treatment in an oxygen-containing atmosphere. In addition, the carrier concentration in the oxide layer 230A can be prevented from being excessively reduced by preventing an excess amount of oxygen from being introduced into the chamber in the microwave treatment.

The microwave treatment in an oxygen-containing atmosphere can convert an oxygen gas into plasma using a high-frequency wave such as a microwave or RF, and apply the oxygen plasma to a region of the oxide layer 230A that is between the conductive layer 242A and the conductive layer 242B. By the effect of the plasma, the microwave, or the like, VoH in the region can be separated into an oxygen vacancy and hydrogen, and hydrogen can be removed from the region. Here, an insulating film having a function of capturing and fixing hydrogen (e.g., aluminum oxide) is preferably used as a layer that is included in the insulating film to be the insulating layer 250 and that is in contact with the oxide layer 230A. With such a structure, hydrogen generated by the microwave treatment can be captured or fixed in the insulating layer 250. Accordingly, VoH included in the channel formation region can be reduced. In the above manner, oxygen vacancies and VoH in the channel formation region can be reduced to lower the carrier concentration. In addition, oxygen radicals generated by the oxygen plasma can be supplied to oxygen vacancies formed in the channel formation region, thereby further reducing oxygen vacancies in the channel formation region and lowering the carrier concentration.

The oxygen implanted into the channel formation region has any of a variety of forms such as an oxygen atom, an oxygen molecule, an oxygen ion, and an oxygen radical (also referred to as O radical, which is an atom, a molecule, or an ion having an unpaired electron). Note that the oxygen implanted into the channel formation region has any one or more of the above forms, particularly suitably an oxygen radical.

Meanwhile, the oxide layer 230A includes the region overlapping with the conductive layer 242A and the region overlapping with the conductive layer 242B. The regions can function as the source region and the drain region. Here, the conductive layer 242A and the conductive layer 242B preferably function as blocking films preventing the effect caused by the high-frequency wave such as a microwave or RF, the oxygen plasma, or the like in the microwave treatment in an oxygen-containing atmosphere. Therefore, the conductive layer 242A and the conductive layer 242B preferably have a function of blocking an electromagnetic wave at higher than or equal to 300 MHz and lower than or equal to 300 GHz, for example, higher than or equal to 2.4 GHz and lower than or equal to 2.5 GHz.

The effect of the high-frequency wave such as a microwave or RF, the oxygen plasma, or the like is blocked by the conductive layer 242A and the conductive layer 242B and does not affect the region of the oxide layer 230A that overlaps with the conductive layer 242A or the conductive layer 242B. This prevents a reduction in VoH and supply of an excess amount of oxygen in the source region and the drain region by the microwave treatment, so that the carrier concentration can be prevented from being lowered.

The insulating layer 250 having a barrier property against oxygen is provided in contact with the side surfaces of the conductive layer 242A and the conductive layer 242B. This can inhibit formation of oxide films on the side surfaces of the conductive layer 242A and the conductive layer 242B by the microwave treatment.

Furthermore, the film quality of the insulating layer 250 can be improved, leading to higher reliability of the transistor 200.

In the above manner, oxygen vacancies and VoH can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited, and the conductivity (the state of the low-resistance regions) before the microwave treatment is performed can be maintained. As a result, a change in the electrical characteristics of the transistor 200 can be inhibited, and thus a variation in the electrical characteristics of the transistors 200 in the substrate plane can be inhibited.

In the microwave treatment, thermal energy is directly transmitted to the oxide layer 230A in some cases owing to an electromagnetic interaction between the microwave and a molecule in the oxide layer 230A. The oxide layer 230A may be heated by this thermal energy. Such heat treatment is sometimes referred to as microwave annealing. When microwave treatment is performed in an oxygen-containing atmosphere, an effect equivalent to that of oxygen annealing is sometimes obtained. In the case where hydrogen is included in the oxide layer 230A, it is probable that the thermal energy is transmitted to the hydrogen in the oxide layer 230A and the hydrogen activated by the energy is released from the oxide layer 230A.

Note that microwave treatment may be performed before the formation of the insulating film to be the insulating layer 250, without the microwave treatment performed after the formation of the insulating film.

After the microwave treatment following the formation of the insulating film to be the insulating layer 250, heat treatment may be performed with the reduced pressure being maintained. Such treatment enables hydrogen in the insulating film and the oxide layer 230A to be removed efficiently. Part of hydrogen is gettered by the conductive layer 242A and the conductive layer 242B in some cases. Alternatively, the step of performing microwave treatment and then performing heat treatment with the reduced pressure being maintained may be repeated a plurality of times. The repetition of the heat treatment enables hydrogen in the insulating film and the oxide layer 230A to be removed more efficiently. Note that the temperature of the heat treatment is preferably higher than or equal to 300° C. and lower than or equal to 500° C. The microwave treatment, i.e., the microwave annealing, may also serve as the heat treatment. The heat treatment is not necessarily performed in the case where the oxide layer 230A and the like are adequately heated by the microwave annealing.

Furthermore, the microwave treatment improves the film quality of the insulating layer 250, thereby inhibiting diffusion of hydrogen, water, impurities, and the like. Accordingly, hydrogen, water, impurities, and the like can be inhibited from diffusing to the oxide layer 230A through the insulating layer 250 by a later step such as formation of the conductive film to be the conductive layer 260 or posttreatment such as heat treatment.

The conductive film to be the conductive layer 260 can be formed by a sputtering method, a CVD method, an MBE method, a PLD method, a plating method, or an ALD method, for example. In this embodiment, as the conductive film to be the conductive layer 260, a conductive film having a two-layer structure is formed in the following manner: a film of titanium nitride is formed by an ALD method, and a film of tungsten is formed by a CVD method.

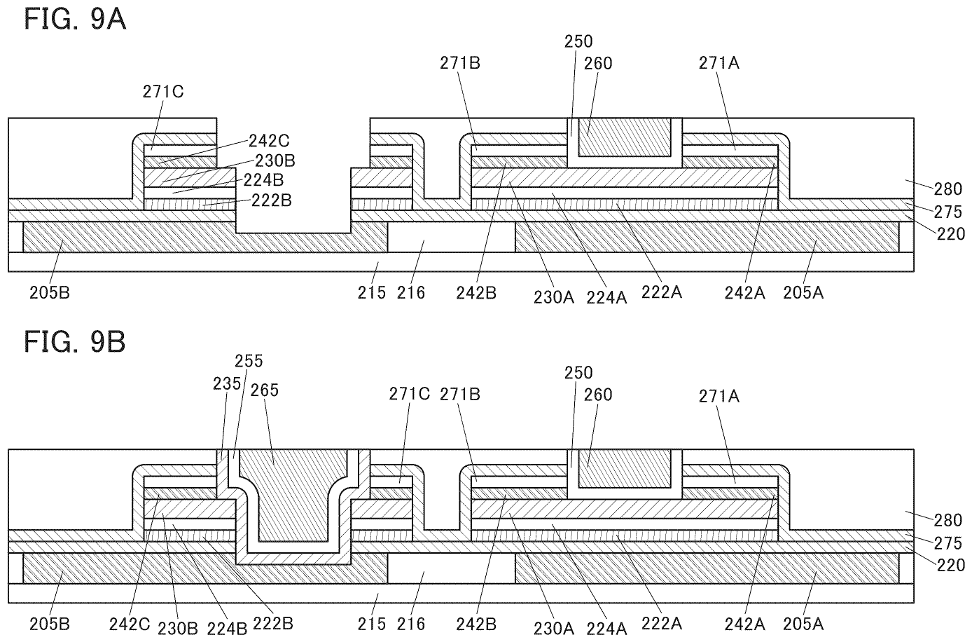

Next, the insulating layer 220, the conductive layer 242C, the insulating layer 271C, the insulating layer 275, and the insulating layer 280 are processed by a lithography method to form an opening reaching the conductive layer 205B (FIG. 9A).

The opening formed in this step overlaps with the entire opening provided in the insulating layer 222B, the insulating layer 224B, the oxide layer 230B, the conductive layer 242C, and the insulating layer 271C and is formed to have a larger size. Here, the oxide layer 230B serves as an etching stopper, so that the size of the opening provided in the conductive layer 242C and the insulating layer 271C in a plan view is larger than the size of the opening provided in the insulating layer 220, the insulating layer 222B, the insulating layer 224B, and the oxide layer 230B in a plan view.

A dry etching method or a wet etching method can be used for the processing. A dry etching method is preferable because it is suitable for fine processing. A dry etching method enables anisotropic etching and is thus suitable for forming an opening with a high aspect ratio. Note that the above description can be referred to for the conditions and an apparatus for a dry etching method.

The processing of the insulating layer 220, the processing of the conductive layer 242C, the processing of the insulating layer 271C, the processing of the insulating layer 275, and the processing of the insulating layer 280 may be performed under different conditions.

Next, a metal oxide film to be the oxide layer 235 is formed to fill the opening reaching the conductive layer 205B, an insulating film to be the insulating layer 255 is formed over the metal oxide film, a conductive film to be the conductive layer 265 is formed over the insulating film, and the metal oxide film, the insulating film, and the conductive film are polished by CMP treatment until the insulating layer 280 is exposed. That is, portions of the metal oxide film, the insulating film, and the conductive film that are exposed from the opening are removed. Thus, the oxide layer 235, the insulating layer 255, and the conductive layer 265 are formed in the opening overlapping with the conductive layer 205B (FIG. 9B). Accordingly, the oxide layer 235 is provided in contact with at least the top surface of the conductive layer 205B, the side surface of the insulating layer 222B, the side surface of the insulating layer 224B, the top surface and the side surface of the oxide layer 230B, and the side surface of the conductive layer 242C in the opening. The insulating layer 255 is provided along the oxide layer 235 over the oxide layer 235, and the conductive layer 265 is provided to fill the opening with the insulating layer 255 therebetween. In this manner, the transistor 100 is formed. Note that in the case where part of the conductive layer 205B is removed and the depressed portion is formed in the conductive layer 205B as illustrated in FIG. 9A, the oxide layer 235 is provided in contact with the bottom surface and the side surface (which can also be regarded as an inner wall) of the depressed portion of the conductive layer 205B.

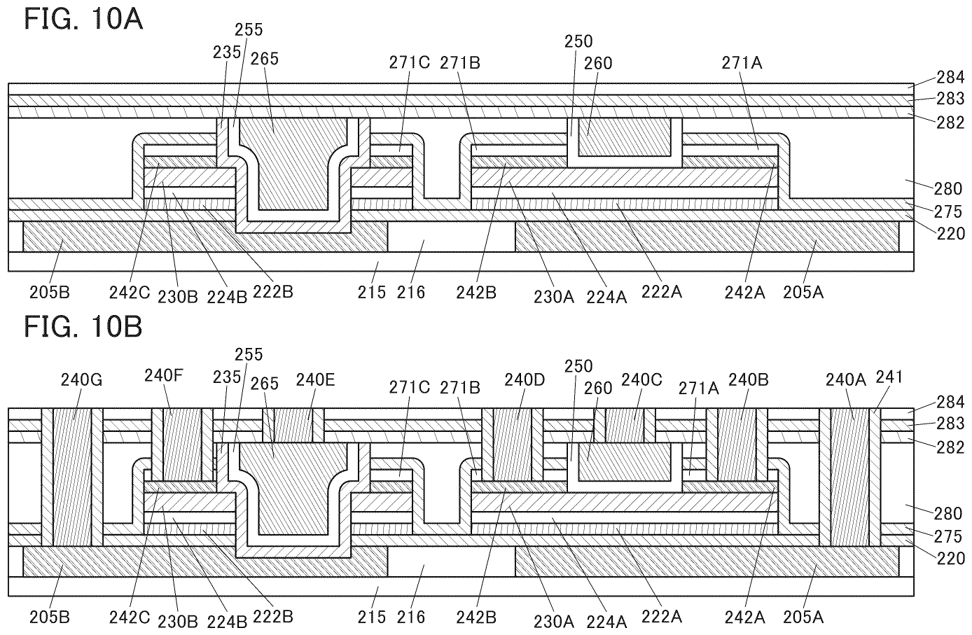

Next, the insulating layer 282 is formed over the oxide layer 235, the insulating layer 255, the conductive layer 265, the insulating layer 250, the conductive layer 260, and the insulating layer 280, the insulating layer 283 is formed over the insulating layer 282, and the insulating layer 284 is formed over the insulating layer 283 (FIG. 10A).

The insulating layer 282, the insulating layer 283, and the insulating layer 284 can each be formed by a sputtering method, a CVD method, an MBE method, a PLD method, or an ALD method, for example. The insulating layer 282, the insulating layer 283, and the insulating layer 284 are each preferably formed by a sputtering method. By using a sputtering method, which does not need to use a molecule containing hydrogen in a film formation gas, the hydrogen concentrations in the insulating layer 282, the insulating layer 283, and the insulating layer 284 can be reduced.

In this embodiment, a film of aluminum oxide is formed for the insulating layer 282 by a pulsed DC sputtering method using an aluminum target in an atmosphere containing an oxygen gas, a film of silicon nitride is formed for the insulating layer 283 by a sputtering method, and a film of silicon oxide is formed for the insulating layer 284 by a sputtering method.

When the insulating layer 282 is formed by a sputtering method in an oxygen-containing atmosphere, oxygen can be added to the insulating layer 280 during the film formation. Thus, excess oxygen can be included in the insulating layer 280. At this time, the insulating layer 282 is preferably formed while the substrate is heated.

Note that heat treatment may be performed before the formation of the insulating layer 282. The heat treatment may be performed under reduced pressure, and the insulating layer 282 may be successively formed without exposure to the air. Such treatment can remove moisture and hydrogen adsorbed onto the surface of the insulating layer 280, and further can reduce the moisture concentration and the hydrogen concentration in the insulating layer 280. The temperature of the heat treatment is preferably higher than or equal to 100° C. and lower than or equal to 400° C. In this embodiment, the temperature of the heat treatment is 250° C.

Here, it is preferable that the insulating layer 282 and the insulating layer 283 be successively formed without being exposed to the atmospheric environment. By the film formation without exposure to the air, impurities or moisture from the atmospheric environment can be prevented from being attached onto the insulating layer 282 and the insulating layer 283, so that the vicinity of the interface between the insulating layer 282 and the insulating layer 283 can be kept clean. Furthermore, the insulating layer 284 is also preferably formed successively without being exposed to the atmospheric environment.

After that, as illustrated in FIG. 10B, openings are formed in the insulating layers 220, 275, 280, 282, 283, and 284, the insulating layer 241 is formed in the openings, and the conductive layer 240A to the conductive layer 240G are formed inside the insulating layer 241. The openings where the conductive layer 240A to the conductive layer 240G are provided may be formed at a time or may be formed in a plurality of steps. Through the above steps, the semiconductor device of one embodiment of the present invention can be manufactured.

### Manufacturing Method Example 2

Next, a manufacturing method of the semiconductor device described in Structure example 2 is described.

First, as in Manufacturing method example 1, the insulating layer 216, the conductive layer 205A, the conductive layer 205B, the insulating layer 220, the insulating layer 222, the insulating layer 224, the oxide layer 230, the conductive layer 242, and the insulating layer 271 are formed over the insulating layer 215 (FIG. 6A).

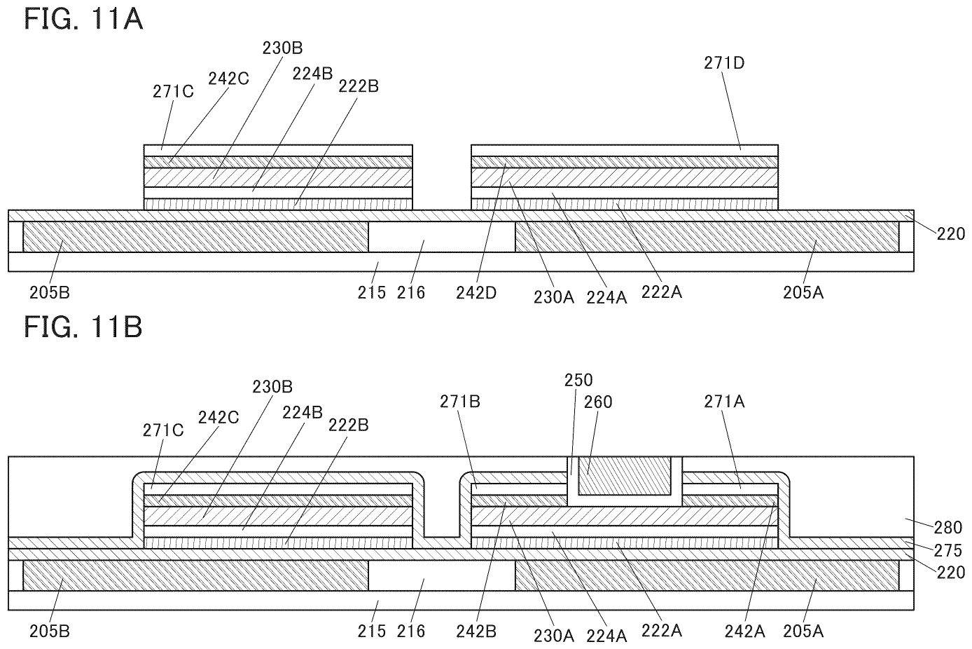

Next, as illustrated in FIG. 11A, the insulating layer 222A, the insulating layer 224A, the oxide layer 230A, the conductive layer 242D, and the insulating layer 271D are each formed into an island shape in a position overlapping with the conductive layer 205A, and the insulating layer 222B, the insulating layer 224B, the oxide layer 230B, the conductive layer 242C, and the insulating layer 271C are each formed into an island shape in a position overlapping with the conductive layer 205B.

At this time, unlike in Manufacturing method example 1 (FIG. 6B), the opening reaching the insulating layer 220 does not need to be provided in the insulating layer 222B, the insulating layer 224B, the oxide layer 230B, the conductive layer 242C, and the insulating layer 271C.

Next, as in Manufacturing method example 1 (FIG. 7A and FIG. 7B), after the insulating layer 275 and the insulating layer 280 are formed, an opening is provided in the insulating layer 275, the insulating layer 280, the conductive layer 242D, and the insulating layer 271D. This divides the conductive layer 242D into the conductive layer 242A and the conductive layer 242B, and divides the insulating layer 271D into the insulating layer 271A and the insulating layer 271B. Then, as in Manufacturing method example 1 (FIG. 8), the insulating layer 250 and the conductive layer 260 are provided to fill the opening (FIG. 11B).

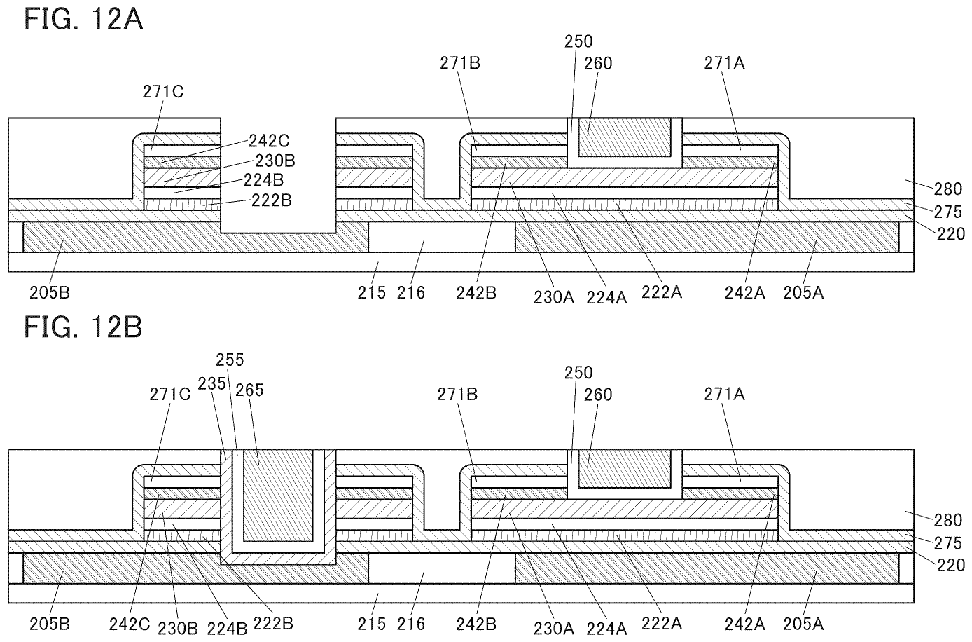

Next, as illustrated in FIG. 12A, openings are formed in the insulating layer 280, the insulating layer 275, the insulating layer 271C, the conductive layer 242C, the oxide layer 230B, the insulating layer 224B, the insulating layer 222B, and the insulating layer 220 to reach the conductive layer 205B. In Manufacturing method example 2, the openings can be formed in these layers at a time (without another step in between); thus, misalignment of the openings formed in the layers can be prevented and the manufacturing process can be simplified.

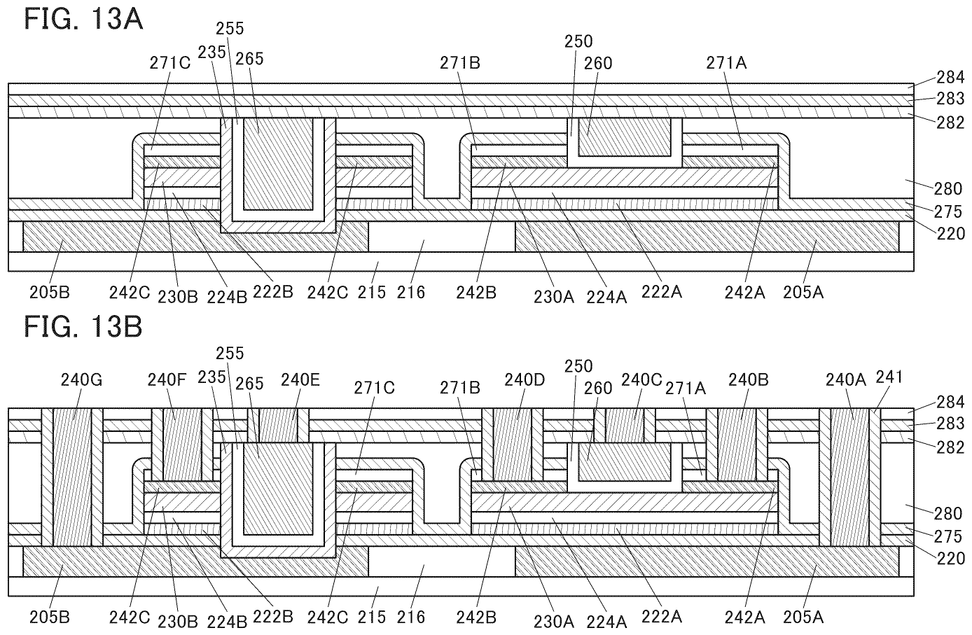

Then, as in Manufacturing method example 1 (FIG. 9B), the oxide layer 235, the insulating layer 255, and the conductive layer 265 are provided to fill the openings (FIG. 12B). Furthermore, as in Manufacturing method example 1 (FIG. 10A and FIG. 10B), the insulating layers 282, 283, and 284 are provided in this order (FIG. 13A), openings are provided in the insulating layers 282, 283, and 284 and the like, and then, the insulating layer 241 and the conductive layer 240A to the conductive layer 240G are provided, so that the semiconductor device described in Structure example 2 can be manufactured (FIG. 13B).

This embodiment can be combined with the other embodiments as appropriate.

### Embodiment 3

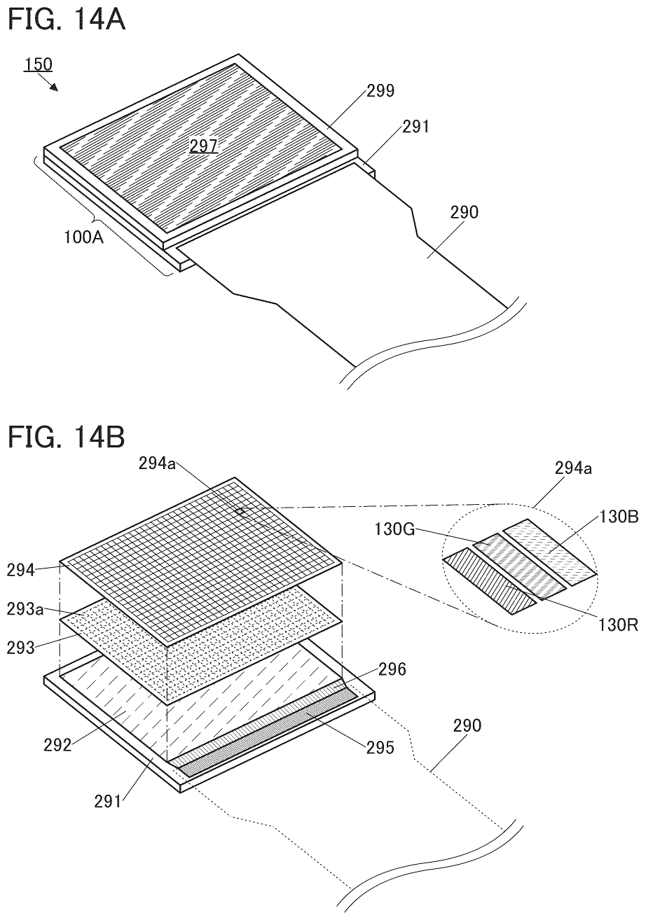

In this embodiment, a display device of one embodiment of the present invention will be described with reference to FIG. 14 to FIG. 19.

The display device of this embodiment can be a high-resolution display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

The display device of this embodiment can be a high-definition display device. Accordingly, the display device of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

The display device of this embodiment may have a function of a touch panel. The display device can employ any of a variety of sensor elements that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The mutual capacitive type is preferably used, in which case multiple points can be sensed simultaneously.

Examples of a touch panel include an out-cell touch panel, an on-cell touch panel, and an in-cell touch panel. Note that an in-cell touch panel has a structure in which an electrode included in a sensor element is provided on one or both of a substrate supporting a display element and a counter substrate.

### [Display Module]

FIG. 14A is a perspective view of a display module 150. The display module 150 includes a display device 100A and an FPC 290. Note that the display device included in the display module 150 is not limited to the display device 100A and may be any of a display device 100B to a display device 100E described later.

The display module 150 includes a substrate 291 and a substrate 299. The display module 150 includes a display portion 297. The display portion 297 is a region of the display module 150 where an image is displayed, and is a region where light from pixels provided in a pixel portion 294 described later can be seen.

FIG. 14B is a perspective view schematically illustrating a structure on the substrate 291 side. Over the substrate 291, a circuit portion 292, a pixel circuit portion 293 over the circuit portion 292, and the pixel portion 294 over the pixel circuit portion 293 are stacked. A terminal portion 295 to be connected to the FPC 290 is provided in a portion over the substrate 291 that does not overlap with the pixel portion 294. The terminal portion 295 and the circuit portion 292 are electrically connected to each other through a wiring portion 296 formed of a plurality of wirings.

The pixel portion 294 includes a plurality of pixels 294a arranged periodically. An enlarged view of one pixel 294a is illustrated on the right side of FIG. 14B. The pixel 294a can employ any of a variety of structures described in Embodiment 4. FIG. 14B illustrates an example where stripe arrangement is employed as the subpixel arrangement.

The pixel circuit portion 293 includes a plurality of pixel circuits 293a arranged periodically.

One pixel circuit 293a controls driving of a plurality of elements included in one pixel 294a. One pixel circuit 293a can be provided with three circuits each controlling light emission of one light-emitting element. For example, the pixel circuit 293a can include at least one selection transistor, one current control transistor (driving transistor), and a capacitor for one light-emitting element. In that case, a gate signal is input to a gate of the selection transistor, and a source signal is input to a source of the selection transistor. Thus, an active-matrix display device is achieved.

The circuit portion 292 includes a circuit for driving the pixel circuits 293a in the pixel circuit portion 293. For example, the circuit portion 292 preferably includes one or both of a gate line driver circuit and a source line driver circuit. In addition, at least one of an arithmetic circuit, a memory circuit, a power supply circuit, and the like may be included.

The FPC 290 functions as a wiring for supplying a video signal, a power supply potential, or the like to the circuit portion 292 from the outside. An IC may be mounted on the FPC 290.

The display module 150 can have a structure in which one or both of the pixel circuit portion 293 and the circuit portion 292 are provided to be stacked below the pixel portion 294; thus, the aperture ratio (effective display area ratio) of the display portion 297 can be significantly high. For example, the aperture ratio of the display portion 297 can be higher than or equal to 40% and lower than 100%, preferably higher than or equal to 50% and lower than or equal to 95%, further preferably higher than or equal to 60% and lower than or equal to 95%. Furthermore, the pixels 294a can be arranged extremely densely, and thus, the display portion 297 can have extremely high definition. For example, the pixels 294a are preferably arranged in the display portion 297 with definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 150 has extremely high definition, and thus can be suitably used for a VR device such as an HMD or a glasses-type AR device. For example, even with a structure in which the display portion of the display module 150 is seen through a lens, pixels of the extremely-high-definition display portion 297 included in the display module 150 are prevented from being seen when the display portion is enlarged by the lens, so that display providing a strong sense of immersion can be performed. Without being limited thereto, the display module 150 can be suitably used for electronic devices including relatively small display portions. For example, the display module 150 can be suitably used for a display portion of a wearable electronic device such as a wristwatch.

### [Display Device 100A]

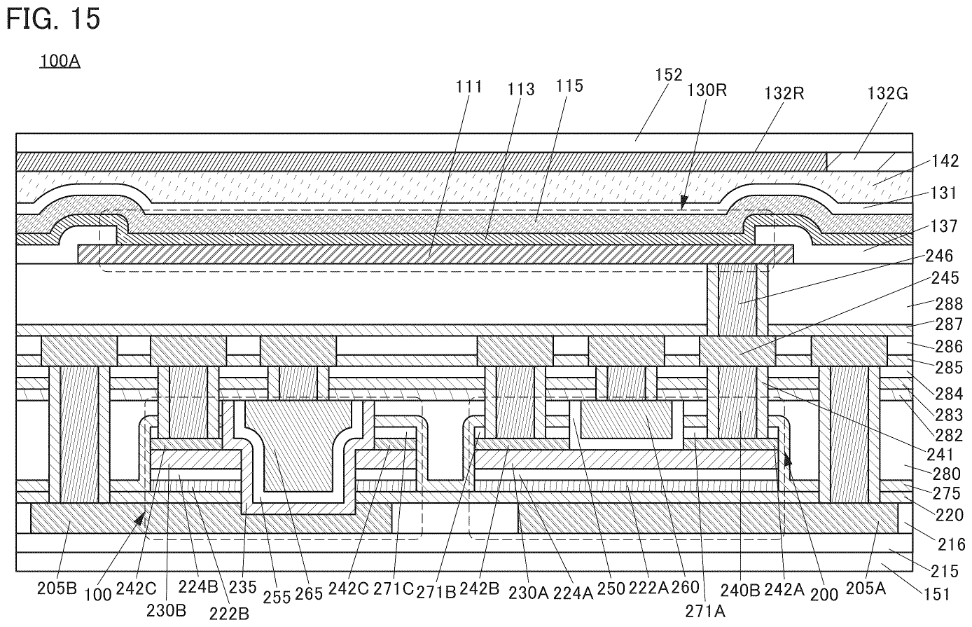

The display device 100A illustrated in FIG. 15 includes the transistor 100, the transistor 200, a light-emitting element 130R, a protective layer 131, a coloring layer 132R, a coloring layer 132G, an adhesive layer 142, a substrate 152, and the like over a substrate 151.

The light-emitting element 130R illustrated in FIG. 14B and FIG. 15 is included in a subpixel that emits red light. A light-emitting element 130G illustrated in FIG. 14B is included in a subpixel that emits green light, and a light-emitting element 130B is included in a subpixel that emits blue light. Light emitted from the light-emitting element in each subpixel is extracted to outside the display device 100A through the coloring layer. For example, light emitted from the light-emitting element 130R is extracted as red light to outside the display device 100A through the coloring layer 132R.

The substrate 151 corresponds to the substrate 291 in FIG. 14A and FIG. 14B.

Since the transistor 100 and the transistor 200 have the same structures as those described in Structure example 1 in Embodiment 1, the description thereof is omitted. That is, Embodiment 1 can be referred to for the details of the stacked-layer structure from the insulating layer 215 to the insulating layer 284.

The transistor 100 is suitable as a switching transistor required to enable charge retention. The transistor 200, which has a long channel length and includes a back gate, is suitable as a driving transistor required to have saturation characteristics. Since the transistor 100 is easier to miniaturize than the transistor 200, using the transistors 100 as all transistors other than the driving transistor in the pixel circuit allows one pixel to include a larger number of transistors. Alternatively, the area occupied by one pixel circuit can be reduced.

The conductive layer 242A functioning as the source or the drain of the transistor 200 is electrically connected to a pixel electrode 111 of the light-emitting element 130R through the conductive layer 240B, a conductive layer 245, and a conductive layer 246. Note that depending on the structure of the pixel circuit, the source or the drain of the transistor 100 is electrically connected to the pixel electrode 111 of the light-emitting element 130R in some cases.

The conductive layer 245 is formed in an opening provided in an insulating layer 285 and an insulating layer 286, and the conductive layer 246 is formed in an opening provided in an insulating layer 287 and an insulating layer 288. The pixel electrode 111 is provided over the insulating layer 288.

The light-emitting element 130R included in the display device 100A includes the pixel electrode 111, an EL layer 113, and a common electrode 115 that are stacked in this order.

In the display device 100A, the subpixels of different colors include coloring layers (e.g., color filters) and light-emitting elements sharing the EL layer 113.

The light-emitting elements included in the subpixels emitting light of different colors share the EL layer 113 and the common electrode 115. The number of manufacturing steps can be smaller in the structure in which the subpixels of different colors share the EL layer 113 than in the structure in which the subpixels of different colors are provided with the respective EL layers.

For example, the light-emitting elements included in the subpixels emitting light of different colors emit white light. When white light emitted from the light-emitting element passes through a coloring layer, light of a desired color can be obtained. The light-emitting element emitting white light preferably has a tandem structure.

Note that in the case where the light-emitting element emitting white light has a microcavity structure, light with a specific wavelength such as red light, green light, or blue light is sometimes intensified to be emitted.

Alternatively, the light-emitting elements included in the subpixels emitting light of different colors may emit blue light. When blue light emitted from the light-emitting element passes through a color conversion layer and a coloring layer, light of a desired color can be obtained.

Embodiment 5 can be referred to for the structure, the materials, and the like of the light-emitting element.

The pixel electrode 111 is formed in each light-emitting element. An end portion of the pixel electrode 111 is covered with an insulating layer 137. The insulating layer 137 functions as a partition wall. With the insulating layer 137, the pixel electrode 111 and the common electrode 115 can be electrically insulated from each other. Furthermore, with the insulating layer 137, adjacent light-emitting elements can be electrically insulated from each other.

The insulating layer 137 can be provided to have a single-layer structure or a stacked-layer structure using one or both of an inorganic insulating material and an organic insulating material.

An inorganic insulating film is preferably used for the insulating layer 137. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film.

Note that an organic insulating film may be used for the insulating layer 137. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 137 may have a stacked-layer structure of an organic insulating film and an inorganic insulating film.

The protective layer 131 is preferably provided over the light-emitting element. Providing the protective layer 131 can improve the reliability of the light-emitting elements. The protective layer 131 may have a single-layer structure or a stacked-layer structure of two or more layers.

There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

For the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of the insulating layer 137. In particular, the protective layer 131 preferably includes a nitride insulating film or a nitride oxide insulating film, and further preferably includes a nitride insulating film.

For the protective layer 131, an inorganic film including In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further include nitrogen.

In the case where light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer side.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 137.

The protective layer 131 may have a stacked structure of two layers that are formed by different film formation methods. Specifically, the first layer of the protective layer 131 may be formed by an ALD method, and the second layer of the protective layer 131 may be formed by a sputtering method.

The protective layer 131 and the substrate 152 are attached to each other with the adhesive layer 142 therebetween. The coloring layer 132R and the coloring layer 132G are provided on the substrate 152. For example, a solid sealing structure or a hollow sealing structure can be employed to seal the light-emitting elements. In FIG. 15, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting element. The space may be filled with a resin other than the frame-shaped adhesive layer 142.

The coloring layer is a colored layer that selectively transmits light in a specific wavelength range and absorbs light in the other wavelength ranges. For example, a red (R) color filter transmitting light in the red wavelength range, a green (G) color filter transmitting light in the green wavelength range, a blue (B) color filter transmitting light in the blue wavelength range, or the like can be used. For each coloring layer, one or more of a metal material, a resin material, a pigment, and a dye can be used. Each coloring layer is formed in a desired position by a printing method, an inkjet method, an etching method using a photolithography method, or the like.

A light-blocking layer such as a black matrix may be provided on the surface of the substrate 152 on the adhesive layer 142 side. Moreover, any of a variety of optical members can be provided on the outer side of the substrate 152 (the surface opposite to the adhesive layer 142 side). Examples of the optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer side of the substrate 152. For example, a glass layer or a silica layer (SiOₓ layer) is preferably provided as the surface protective layer to inhibit surface contamination and damage. For the surface protective layer, DLC (diamond-like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased. Furthermore, a polarizing plate may be used as the substrate 152.

The display device 100A has a top-emission structure. Light emitted from the light-emitting elements is emitted to the substrate 152 side. For the substrate 152, a material having a high visible-light-transmitting property is preferably used. The pixel electrode 111 includes a material that reflects visible light, and a counter electrode (the common electrode 115) includes a material that transmits visible light.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for the substrate 151 and the substrate 152.

In the case where a circularly polarizing plate overlaps with the display device, a highly optically isotropic substrate is preferably used as the substrate included in the display device. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used as the substrate and the film absorbs water, the shape of the display device might be changed, e.g., creases might be caused. Thus, as the substrate, a film with a low water absorption rate is preferably used. For example, the water absorption rate of the film is preferably lower than or equal to 1%, further preferably lower than or equal to 0.1%, still further preferably lower than or equal to 0.01%.

The adhesive layer 142 can be formed using any of a variety of curable adhesives, e.g., a reactive curable adhesive, a thermosetting curable adhesive, an anaerobic adhesive, or a photocurable adhesive such as an ultraviolet curable adhesive. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene-vinyl acetate) resin. In particular, a material with low moisture permeability, such as an epoxy resin, is preferable. A two-liquid-mixture-type resin may be used. An adhesive sheet or the like may be used.

### [Display Device 100B]

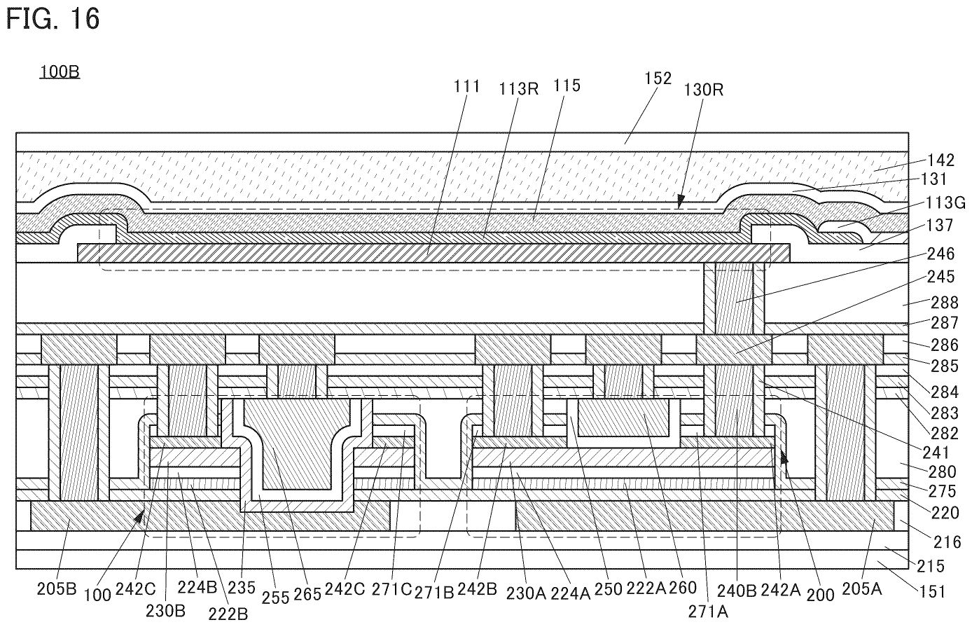

The display device 100B illustrated in FIG. 16 is different from the display device 100A mainly in that the coloring layers 132R and 132G are not provided and that the subpixels of different colors include the respective EL layers instead of sharing the EL layer 113.

The light-emitting element 130R included in the display device 100B includes the pixel electrode 111, an EL layer 113R, and the common electrode 115 that are stacked in this order. The EL layer 113R includes a light-emitting layer that emits red light. The light-emitting element 130R emits red light. Similarly, a light-emitting element that emits green light is provided in the subpixel that emits green light (an EL layer 113G includes a light-emitting layer that emits green light), and a light-emitting element that emits blue light is provided in the subpixel that emits blue light.

The EL layer 113R is provided to have an island shape. In FIG. 16, an end portion of the EL layer 113R and an end portion of the EL layer 113G that are adjacent to each other overlap with each other. When island-shaped EL layers are formed using a fine metal mask, end portions of the EL layers adjacent to each other may overlap with each other as illustrated in FIG. 16; however, the present invention is not limited thereto. That is, it is also possible that the EL layers adjacent to each other do not overlap with each other and are separated from each other. Furthermore, both a portion where the EL layers adjacent to each other overlap with each other and a portion where the EL layers adjacent to each other do not overlap with each other and are separated from each other may exist in the display device.

### [Display Device 100C]

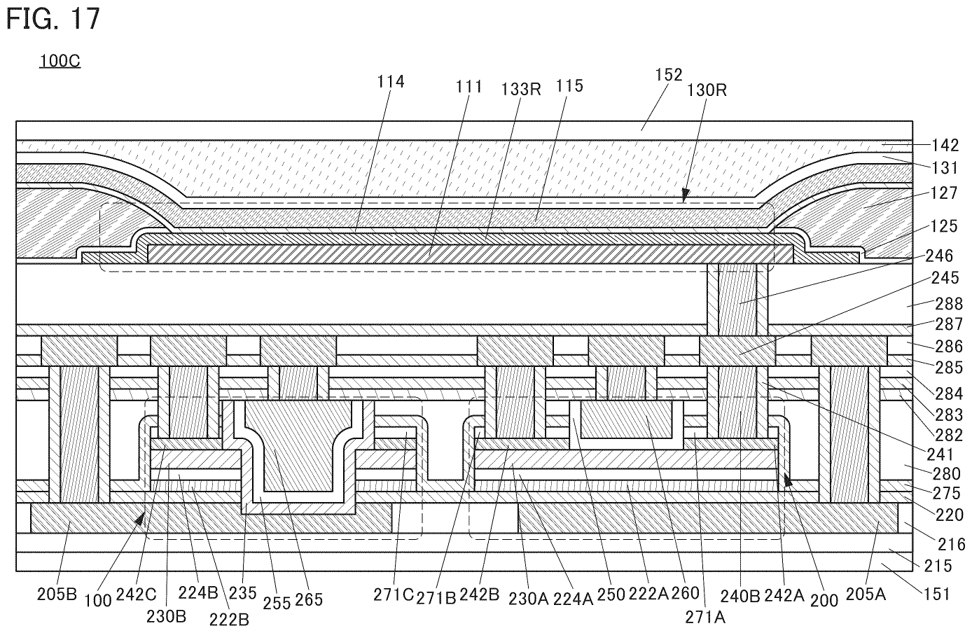

The display device 100C illustrated in FIG. 17 is an example of a display device having an MML (metal maskless) structure. In other words, the display device 100C includes a light-emitting element that is formed without using a fine metal mask.

An island-shaped light-emitting layer of the light-emitting element included in the display device having an MML structure is formed in the following manner: a light-emitting layer is formed on the entire surface, and then, the light-emitting layer is processed by a photolithography method. Accordingly, a high-definition display device or a display device with a high aperture ratio, which has been difficult to achieve, can be manufactured. Moreover, light-emitting layers can be formed separately for the respective colors, enabling the display device to perform extremely clear display with high contrast and high display quality. For example, in the case where the display device includes three types of light-emitting elements, which are a light-emitting element that emits blue light, a light-emitting element that emits green light, and a light-emitting element that emits red light, three types of island-shaped light-emitting layers can be formed by repeating formation of a light-emitting layer and processing by photolithography three times.

Note that a device having an MML structure can be manufactured without using a metal mask, and thus can break through the definition limit due to alignment accuracy of the metal mask. Furthermore, manufacturing a device without using a metal mask can eliminate the need for the manufacturing equipment of a metal mask and the cleaning step of the metal mask. Furthermore, for processing by photolithography, an apparatus that is the same as or similar to that used for manufacturing a transistor can be used; thus, there is no need to introduce a special apparatus to manufacture the device having an MML structure. An MML structure can reduce the manufacturing cost as described above, and thus is suitable for mass production of the device.

It is not necessary to conduct a pseudo improvement in definition by employing a unique pixel arrangement such as a PenTile arrangement in a display device employing an MML structure; thus, the display device can achieve high definition (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

In addition, providing a sacrificial layer over the light-emitting layer can reduce damage to the light-emitting layer in the manufacturing process of the display device, increasing the reliability of the light-emitting element.

Employing a film formation step using an area mask and a processing step using a resist mask enables the light-emitting element to be manufactured by a relatively easy process.

The stacked-layer structure from the substrate 151 to the insulating layer 288 and the stacked-layer structure from the protective layer 131 to the substrate 152 are similar to those in the display device 100A; thus, the description thereof is omitted.

In FIG. 17, the light-emitting element 130R is provided over the insulating layer 288.

The light-emitting element 130R includes the pixel electrode 111 over the insulating layer 288, a layer 133R over the pixel electrode 111, a common layer 114 over the layer 133R, and the common electrode 115 over the common layer 114. The light-emitting element 130R illustrated in FIG. 17 emits red light. The layer 133R includes a light-emitting layer that emits red light. In the light-emitting element 130R, the layer 133R and the common layer 114 can be collectively referred to as an EL layer.

In this specification and the like, in the EL layers included in the light-emitting elements, the island-shaped layer provided in each light-emitting element is referred to as the layer 133R, and the layer shared by the light-emitting elements is referred to as the common layer 114. Note that in this specification and the like, the layer 133R is sometimes referred to as an island-shaped EL layer, an EL layer formed into an island shape, or the like, in which case the common layer 114 is not included in the EL layer.

The island-shaped EL layers included in the light-emitting elements are separated from each other. When the EL layer is provided to have an island shape for each light-emitting element, a leakage current between adjacent light-emitting elements can be inhibited. This can prevent unintended light emission due to crosstalk, so that the display device can have extremely high contrast.

The top surface and a side surface of the pixel electrode 111 are covered with the layer 133R. Accordingly, a region provided with the pixel electrode 111 can be entirely used as a light-emitting region of the light-emitting element 130R, increasing the aperture ratio of the pixel.

A side surface and part of the top surface of the layer 133R are covered with insulating layers 125 and 127. The common layer 114 is provided over the layer 133R and the insulating layers 125 and 127, and the common electrode 115 is provided over the common layer 114. The common layer 114 and the common electrode 115 are each a continuous film shared by a plurality of light-emitting elements.

In FIG. 17, the insulating layer 137 illustrated in FIG. 15 or the like is not provided between the pixel electrode 111 and the layer 133R. That is, an insulating layer (also referred to as a partition wall, a bank, a spacer, or the like) being in contact with the pixel electrode and covering an end portion of the top surface of the pixel electrode is not provided in the display device 100C. Thus, the distance between adjacent light-emitting elements can be extremely narrowed. Accordingly, the display device can have high definition or high resolution. In addition, a mask for forming the insulating layer is not needed, which leads to a reduction in manufacturing cost of the display device.

As described above, the layer 133R includes a light-emitting layer. The layer 133R preferably includes a light-emitting layer and a carrier-transport layer (an electron-transport layer or a hole-transport layer) over the light-emitting layer. Alternatively, the layer 133R preferably includes a light-emitting layer and a carrier-blocking layer (a hole-blocking layer or an electron-blocking layer) over the light-emitting layer. Alternatively, the layer 133R preferably includes a light-emitting layer, a carrier-blocking layer over the light-emitting layer, and a carrier-transport layer over the carrier-blocking layer. Since the surface of the layer 133R is exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by light-emitting elements emitting light of different colors. Note that each of the EL layers included in the light-emitting elements may be provided to have an island shape, and the common layer 114 may be omitted.

The side surface of the layer 133R is covered with the insulating layer 125. The insulating layer 127 covers the side surface of the layer 133R with the insulating layer 125 therebetween.

Since the side surface (and part of the top surface) of the layer 133R is covered with at least one of the insulating layer 125 and the insulating layer 127, the common layer 114 (or the common electrode 115) can be inhibited from being in contact with the side surfaces of the pixel electrode 111 and the layer 133R, and a short circuit of the light-emitting elements can be inhibited. Thus, the reliability of the light-emitting elements can be increased.

The insulating layer 125 is preferably in contact with the side surface of the layer 133R. The insulating layer 125 in contact with the layer 133R can prevent film separation of the layer 133R, whereby the reliability of the light-emitting element can be increased.

The insulating layer 127 is provided over the insulating layer 125 to fill a depressed portion of the insulating layer 125. The insulating layer 127 preferably covers at least part of a side surface of the insulating layer 125.

The insulating layer 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 125 and the insulating layer 127, and the coverage with the common layer 114 and the common electrode 115 can be improved. Thus, connection defects caused by step disconnection can be inhibited. Alternatively, an increase in electrical resistance caused by local thinning of the common electrode 115 due to the step can be inhibited.

The top surface of the insulating layer 127 preferably has a shape with high flatness. The top surface of the insulating layer 127 may include at least one of a flat surface, a convex surface, and a concave surface. For example, the top surface of the insulating layer 127 preferably has a convex shape with a large radius of curvature.

The insulating layer 125 can include an inorganic material. For the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. In particular, aluminum oxide is preferable because it has high selectivity with respect to the EL layer in etching and has a function of protecting the EL layer in forming the insulating layer 127 to be described later. In particular, when an inorganic insulating film such as an aluminum oxide film, a hafnium oxide film, or a silicon oxide film formed by an ALD method is used for the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. In addition, the insulating layer 125 preferably has a function of capturing or fixing (also referred to as gettering) at least one of water and oxygen.

When the insulating layer 125 has a function of a barrier insulating layer, entry of impurities (typically, at least one of water and oxygen) that might diffuse to the light-emitting elements from the outside can be inhibited. With this structure, a highly reliable light-emitting element and a highly reliable display device can be provided.

The insulating layer 125 preferably has a low impurity concentration. In that case, degradation of the EL layer due to entry of impurities into the EL layer from the insulating layer 125 can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of reducing unevenness with a large level difference on the insulating layer 125, which is formed between the adjacent light-emitting elements. In other words, the insulating layer 127 has an effect of improving the flatness of the formation surface of the common electrode 115.

As the insulating layer 127, an insulating layer including an organic material can be favorably used. As the organic material, a photosensitive resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, any of precursors of these resins, or the like. For the insulating layer 127, an organic material such as polyvinyl alcohol (PVA), polyvinyl butyral, polyvinyl pyrrolidone, polyethylene glycol, polyglycerin, pullulan, water-soluble cellulose, or an alcohol-soluble polyamide resin may be used. A photoresist may be used as the photosensitive resin. As the photosensitive resin, either a positive-type material or a negative-type material may be used.

For the insulating layer 127, a material absorbing visible light may be used. When the insulating layer 127 absorbs light emitted from the light-emitting element, leakage of light (stray light) from the light-emitting element to an adjacent light-emitting element through the insulating layer 127 can be inhibited. Thus, the display quality of the display device can be improved. Since no polarizing plate is required to improve the display quality of the display device, the weight and thickness of the display device can be reduced.

Examples of the material absorbing visible light include a material containing a pigment of black or any other color, a material containing a dye, a light-absorbing resin material (e.g., polyimide), and a resin material that can be used for color filters (a color filter material). A resin material obtained by stacking or mixing color filter materials of two colors or three or more colors is particularly preferably used to enhance the effect of blocking visible light. Specifically, mixing color filter materials of three or more colors enables formation of a black or nearly black resin layer.

### [Display Device 100D and Display Device 100E]

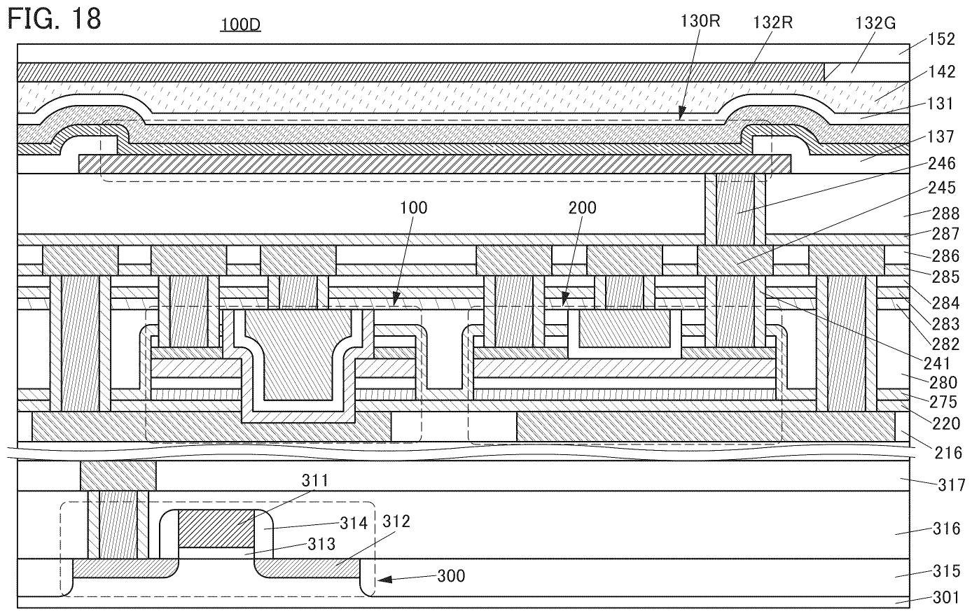

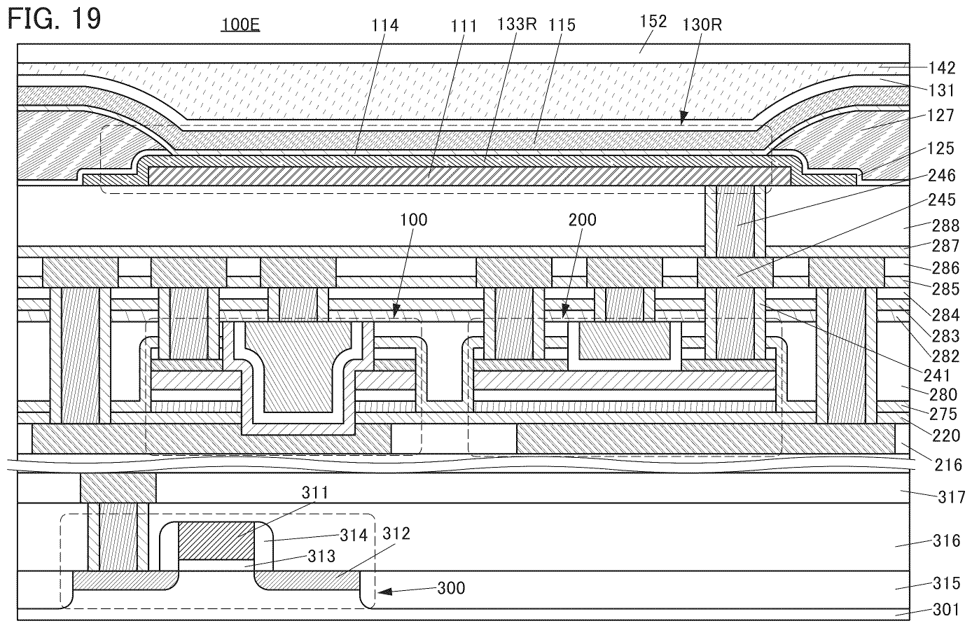

The display device 100D illustrated in FIG. 18 has a stacked-layer structure from a substrate 301 to an insulating layer 317 instead of the substrate 151 in the display device 100A. The display device 100E illustrated in FIG. 19 has a stacked-layer structure from the substrate 301 to the insulating layer 317 instead of the substrate 151 in the display device 100C.

A transistor 300 includes a channel formation region in the substrate 301. As the substrate 301, a semiconductor substrate such as a single crystal silicon substrate can be used, for example. The transistor 300 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided between two adjacent transistors 300 to be embedded in the substrate 301. The source or the drain of the transistor 300 is electrically connected to at least one of conductive layers, wirings, transistors, and the like provided above the transistor 300 through a conductive layer provided in an opening in an insulating layer 316 and the insulating layer 317.

The transistor 100 and the transistor 200 can be used as transistors included in the pixel circuit. The transistor 300 can be used as a transistor included in the pixel circuit or a transistor included in a driver circuit (a gate line driver circuit or a source line driver circuit) for driving the pixel circuit. The transistor 300 can be used as a transistor included in any of a variety of circuits such as an arithmetic circuit and a memory circuit.

With such a structure, not only the pixel circuit but also the driver circuit or the like can be formed directly under the light-emitting element; thus, the display device can be downsized as compared with the case where the driver circuit is provided around a display region.

This embodiment can be combined with the other embodiments as appropriate.

### Embodiment 4

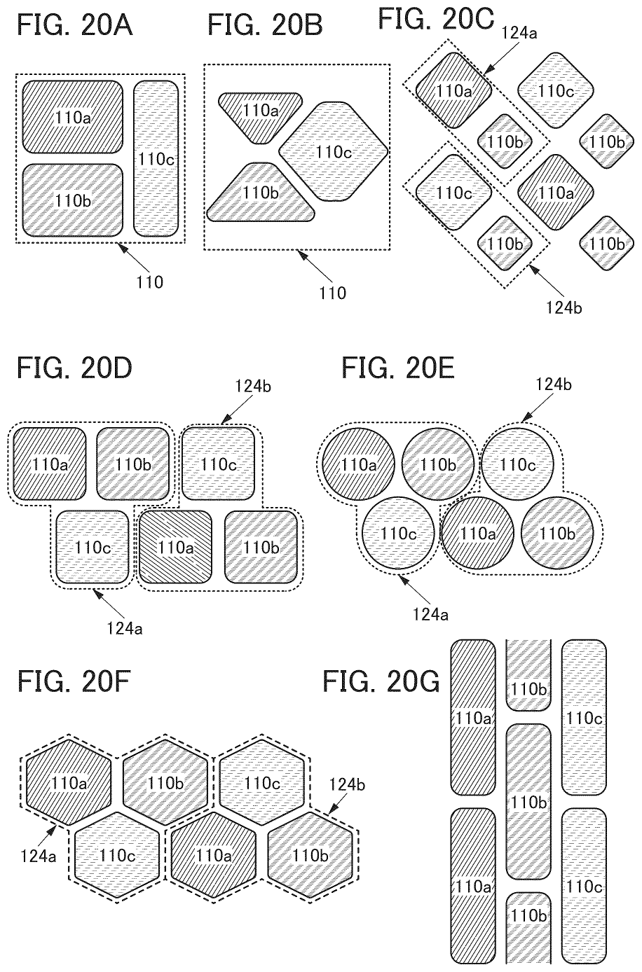

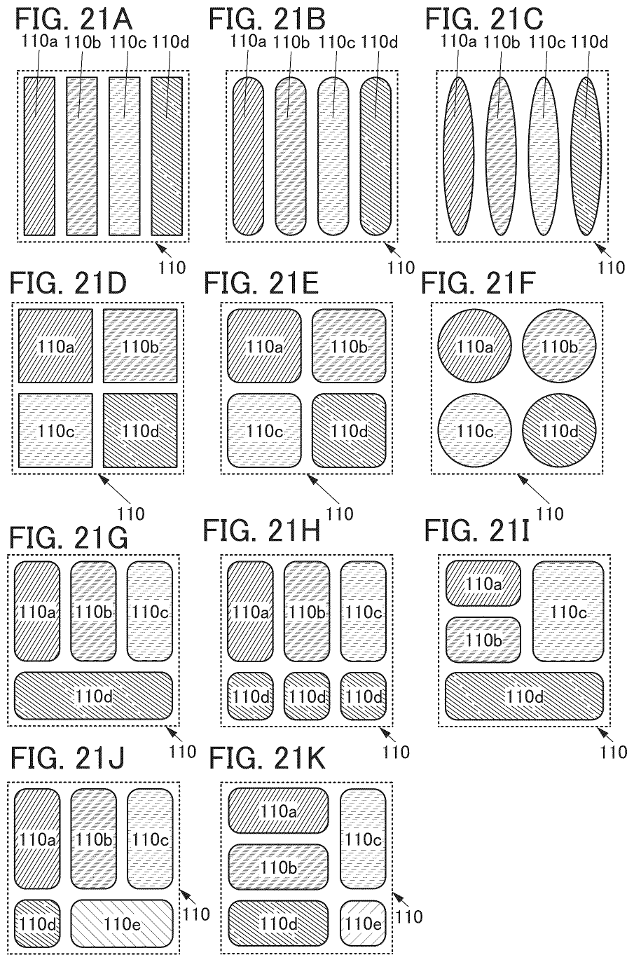

In this embodiment, display devices of embodiments of the present invention are described with reference to FIG. 20 and FIG. 21.

### [Pixel Layout]

There is no particular limitation on the arrangement of subpixels in the display device of one embodiment of the present invention, and a variety of methods can be used. Examples of the arrangement of subpixels include stripe arrangement, S-stripe arrangement, matrix arrangement, delta arrangement, Bayer arrangement, and PenTile arrangement.

The top-view shape of the subpixel illustrated in the drawings in this embodiment corresponds to the top-view shape of a light-emitting region (or a light-receiving region).

Examples of the top-view shape of the subpixel include polygons such as a triangle, a tetragon (including a rectangle and a square), and a pentagon; these polygons with rounded corners; an ellipse; and a circle.

The range of the circuit layout of the subpixels is not limited to the range of the subpixels illustrated in the drawings, and the components of the circuit may be placed outside the subpixels.

A pixel 110 illustrated in FIG. 20A employs S-stripe arrangement. The pixel 110 illustrated in FIG. 20A is composed of three subpixels: subpixels 110a, 110b, and 110c.

The pixel 110 illustrated in FIG. 20B includes the subpixel 110a whose top-view shape is a rough triangle or a rough trapezoid with rounded corners, the subpixel 110b whose top-view shape is a rough triangle or a rough trapezoid with rounded corners, and the subpixel 110c whose top-view shape is a rough tetragon or a rough hexagon with rounded corners. The subpixel 110b has a larger light-emitting area than the subpixel 110a. Thus, the shapes and sizes of the subpixels can be determined independently. For example, the size of a subpixel including a light-emitting element with higher reliability can be smaller.

Pixels 124a and 124b illustrated in FIG. 20C employ PenTile arrangement. FIG. 20C illustrates an example where the pixels 124a including the subpixel 110a and the subpixel 110b and the pixels 124b including the subpixel 110b and the subpixel 110c are alternately arranged.

The pixels 124a and 124b illustrated in FIG. 20D to FIG. 20F employ delta arrangement. The pixel 124a includes two subpixels (the subpixels 110a and 110b) in the upper row (the first row) and one subpixel (the subpixel 110c) in the lower row (the second row). The pixel 124b includes one subpixel (the subpixel 110c) in the upper row (the first row) and two subpixels (the subpixels 110a and 110b) in the lower row (the second row).

FIG. 20D is an example where the top-view shape of each subpixel is a rough tetragon with rounded corners, FIG. 20E is an example where the top-view shape of each subpixel is a circle, and FIG. 20F is an example where the top-view shape of each subpixel is a rough hexagon with rounded corners.

In FIG. 20F, each of the subpixels is placed inside one of the closest-packed hexagonal regions. Focusing on one of the subpixels, the subpixel is placed so as to be surrounded by six subpixels. The subpixels are arranged such that subpixels that emit light of the same color are not adjacent to each other. For example, focusing on the subpixel 110a, the subpixel 110a is surrounded by three of the subpixels 110b and three of the subpixels 110c that are alternately arranged.

FIG. 20G illustrates an example where subpixels of different colors are arranged in a zigzag manner. Specifically, the positions of the top sides of two subpixels arranged in the row direction (e.g., the subpixel 110a and the subpixel 110b or the subpixel 110b and the subpixel 110c) are not aligned in a plan view.

For example, in each pixel illustrated in FIG. 20A to FIG. 20G, it is preferable that the subpixel 110a be a subpixel R emitting red light, the subpixel 110b be a subpixel G emitting green light, and the subpixel 110c be a subpixel B emitting blue light. Note that the structure of the subpixels is not limited to this, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top-view shape of a subpixel is a polygon with rounded corners, an ellipse, a circle, or the like in some cases.

Furthermore, in the method for manufacturing the display device of one embodiment of the present invention, an EL layer is processed into an island shape using a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the top-view shape of the EL layer may be a polygon with rounded corners, an ellipse, a circle, or the like. For example, when a resist mask whose top-view shape is a square is intended to be formed, a resist mask whose top-view shape is a circle may be formed, and the top-view shape of the EL layer may be a circle.

Note that to obtain a desired top-view shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 21A to FIG. 21I, the pixel can include four types of subpixels.

The pixels 110 illustrated in FIG. 21A to FIG. 21C employ stripe arrangement.

FIG. 21A illustrates an example where each subpixel has a rectangular top-view shape, FIG. 21B illustrates an example where each subpixel has a top-view shape formed by combining two half circles and a rectangle, and FIG. 21C illustrates an example where each subpixel has an elliptical top-view shape.

The pixels 110 illustrated in FIG. 21D to FIG. 21F employ matrix arrangement.

FIG. 21D illustrates an example where each subpixel has a square top-view shape, FIG. 21E illustrates an example where each subpixel has a rough square top-view shape with rounded corners, and FIG. 21F illustrates an example where each subpixel has a circular top-view shape.

FIG. 21G and FIG. 21H each illustrate an example where one pixel 110 is composed of two rows and three columns.

The pixel 110 illustrated in FIG. 21G includes three subpixels (the subpixels 110a, 110b, and 110c) in the upper row (the first row) and one subpixel (a subpixel 110d) in the lower row (the second row). In other words, the pixel 110 includes the subpixel 110a in the left column (the first column), the subpixel 110b in the center column (the second column), the subpixel 110c in the right column (the third column), and the subpixel 110d across these three columns.

The pixel 110 illustrated in FIG. 21H includes three subpixels (the subpixels 110a, 110b, and 110c) in the upper row (the first row) and three of the subpixels 110d in the lower row (the second row). In other words, the pixel 110 includes the subpixel 110a and the subpixel 110d in the left column (the first column), the subpixel 110b and the subpixel 110d in the center column (the second column), and the subpixel 110c and the subpixel 110d in the right column (the third column). Matching the positions of the subpixels in the upper row and the lower row as illustrated in FIG. 21H enables efficient removal of dust and the like that would be produced in the manufacturing process. Thus, a display device with high display quality can be provided.

FIG. 21I illustrates an example where one pixel 110 is composed of three rows and two columns.

The pixel 110 illustrated in FIG. 21I includes the subpixel 110a in the upper row (the first row), the subpixel 110b in the center row (the second row), the subpixel 110c across the first and second rows, and one subpixel (the subpixel 110d) in the lower row (the third row). In other words, the pixel 110 includes the subpixels 110a and 110b in the left column (the first column), the subpixel 110c in the right column (the second column), and the subpixel 110d across these two columns.

The pixels 110 illustrated in FIG. 21A to FIG. 21I are each composed of four subpixels: the subpixels 110a, 110b, 110c, and 110d.

The subpixels 110a, 110b, 110c, and 110d can include light-emitting elements emitting light of different colors. The subpixels 110a, 110b, 110c, and 110d can be subpixels of four colors of R, G, B, and white (W), subpixels of four colors of R, G, B, and Y, or subpixels of R, G, B, and infrared light (IR), for example.

In the pixels 110 illustrated in FIG. 21A to FIG. 21I, it is preferable that the subpixel 110a be the subpixel R emitting red light, the subpixel 110b be the subpixel G emitting green light, the subpixel 110c be the subpixel B emitting blue light, and the subpixel 110d be any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIG. 21G and FIG. 21H, enabling higher display quality. In addition, what is called S-stripe arrangement is employed as the layout of R, G, and B in the pixel 110 illustrated in FIG. 21I, enabling higher display quality.

The pixel 110 may include a subpixel including a light-receiving element.

In the pixels 110 illustrated in FIG. 21A to FIG. 21I, any one of the subpixel 110a to the subpixel 110d may be a subpixel including a light-receiving element.

In the pixels 110 illustrated in FIG. 21A to FIG. 21I, for example, it is preferable that the subpixel 110a be the subpixel R emitting red light, the subpixel 110b be the subpixel G emitting green light, the subpixel 110c be the subpixel B emitting blue light, and the subpixel 110d be a subpixel S including a light-receiving element. In the case of such a structure, stripe arrangement is employed as the layout of R, G, and B in the pixels 110 illustrated in FIG. 21G and FIG. 21H, enabling higher display quality. In addition, what is called S-stripe arrangement is employed as the layout of R, G, and B in the pixel 110 illustrated in FIG. 21I, enabling higher display quality.

There is no particular limitation on the wavelength of light detected by the subpixel S including a light-receiving element. The subpixel S can be configured to detect one or both of visible light and infrared light.

As illustrated in FIG. 21J and FIG. 21K, the pixel can include five types of subpixels. FIG. 21J illustrates an example where one pixel 110 is composed of two rows and three columns.

The pixel 110 illustrated in FIG. 21J includes three subpixels (the subpixels 110a, 110b, and 110c) in the upper row (the first row) and two subpixels (the subpixels 110d and 110e) in the lower row (the second row). In other words, the pixel 110 includes the subpixels 110a and 110d in the left column (the first column), the subpixel 110b in the center column (the second column), the subpixel 110c in the right column (the third column), and the subpixel 110e across the second and third columns.

FIG. 21K illustrates an example where one pixel 110 is composed of three rows and two columns.

The pixel 110 illustrated in FIG. 21K includes the subpixel 110a in the upper row (the first row), the subpixel 110b in the center row (the second row), the subpixel 110c across the first and second rows, and two subpixels (the subpixels 110d and 110e) in the lower row (the third row). In other words, the pixel 110 includes the subpixels 110a, 110b, and 110d in the left column (the first column), and the subpixels 110c and 110e in the right column (the second column).

In the pixels 110 illustrated in FIG. 21J and FIG. 21K, for example, it is preferable that the subpixel 110a be the subpixel R emitting red light, the subpixel 110b be the subpixel G emitting green light, and the subpixel 110c be the subpixel B emitting blue light. In the case of such a structure, stripe arrangement is employed as the layout of R, G, and B in the pixel 110 illustrated in FIG. 21J, enabling higher display quality. In addition, what is called S-stripe arrangement is employed as the layout of R, G, and B in the pixel 110 illustrated in FIG. 21K, enabling higher display quality.

In the pixels 110 illustrated in FIG. 21J and FIG. 21K, for example, it is preferable to use the subpixel S including a light-receiving element as at least one of the subpixel 110d and the subpixel 110e. In the case where light-receiving elements are used in both the subpixel 110d and the subpixel 110e, the light-receiving elements may have different structures. For example, the wavelength ranges of detected light may be different at least partly. Specifically, one of the subpixel 110d and the subpixel 110e may include a light-receiving element mainly detecting visible light and the other may include a light-receiving element mainly detecting infrared light.

In the pixels 110 illustrated in FIG. 21J and FIG. 21K, for example, it is preferable that the subpixel S including a light-receiving element be used as one of the subpixel 110d and the subpixel 110e and a subpixel including a light-emitting element that can be used as a light source be used as the other. For example, it is preferable that one of the subpixel 110d and the subpixel 110e be the subpixel IR emitting infrared light and the other be the subpixel S including a light-receiving element detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, the pixel composed of the subpixels each including the light-emitting element can employ any of a variety of layouts in the display device of one embodiment of the present invention. The display device of one embodiment of the present invention can have a structure where the pixel includes both a light-emitting element and a light-receiving element. Also in this case, any of a variety of layouts can be employed.

This embodiment can be combined with the other embodiments as appropriate.

### Embodiment 5

In this embodiment, a light-emitting device that can be used in the display device of one embodiment of the present invention is described.

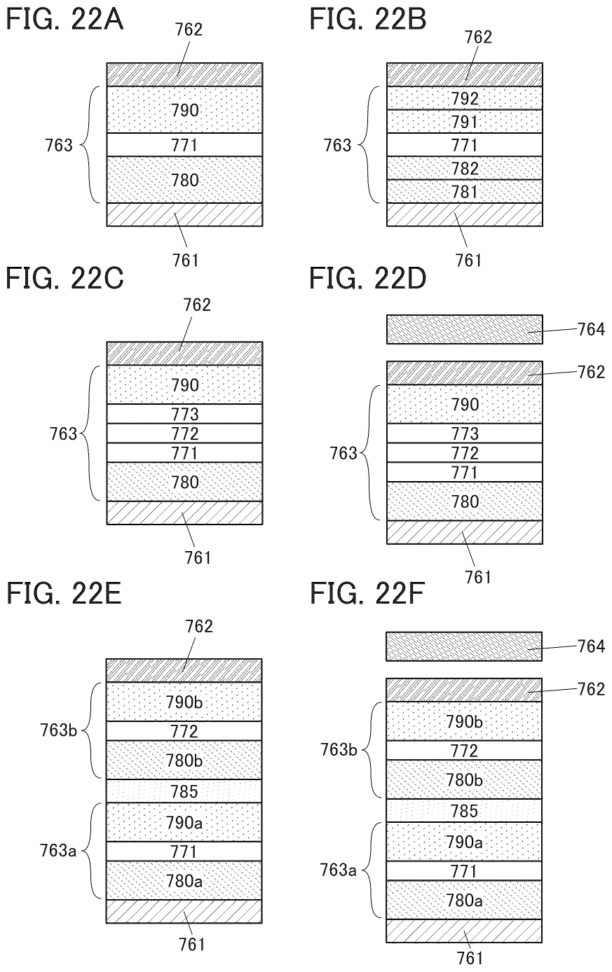

As illustrated in FIG. 22A, the light-emitting device includes an EL layer 763 between a pair of electrodes (a lower electrode 761 and an upper electrode 762). The EL layer 763 can be formed with a plurality of layers such as a layer 780, a light-emitting layer 771, and a layer 790.

The light-emitting layer 771 includes at least a light-emitting substance (also referred to as a light-emitting material).

In the case where the lower electrode 761 is an anode and the upper electrode 762 is a cathode, the layer 780 includes one or more of a layer including a substance having a high hole-injection property (hole-injection layer), a layer including a substance having a high hole-transport property (hole-transport layer), and a layer including a substance having a high electron-blocking property (electron-blocking layer). Furthermore, the layer 790 includes one or more of a layer including a substance having a high electron-injection property (electron-injection layer), a layer including a substance having a high electron-transport property (electron-transport layer), and a layer including a substance having a high hole-blocking property (hole-blocking layer). In the case where the lower electrode 761 is a cathode and the upper electrode 762 is an anode, the structures of the layer 780 and the layer 790 are interchanged.

The structure with the layer 780, the light-emitting layer 771, and the layer 790, which is provided between the pair of electrodes, can function as a single light-emitting unit, and the structure in FIG. 22A is referred to as a single structure in this specification.

FIG. 22B is a modification example of the EL layer 763 included in the light-emitting device illustrated in FIG. 22A. Specifically, the light-emitting device illustrated in FIG. 22B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (light-emitting layers 771, 772, and 773) are provided between the layer 780 and the layer 790 as illustrated in FIG. 22C and FIG. 22D are other variations of a single structure. Although FIG. 22C and FIG. 22D each illustrate an example in which three light-emitting layers are included, the number of light-emitting layers in a light-emitting device having a single structure may be two or four or more. A light-emitting device having a single structure may include a buffer layer between two light-emitting layers. The buffer layer can be formed using a material that can be used for the hole-transport layer or the electron-transport layer, for example.

A structure in which a plurality of light-emitting units (a light-emitting unit 763a and a light-emitting unit 763b) are connected in series with a charge-generation layer 785 (also referred to as an intermediate layer) therebetween as illustrated in FIG. 22E and FIG. 22F is referred to as a tandem structure in this specification. A tandem structure may be referred to as a stack structure. A tandem structure enables a light-emitting device capable of high-luminance light emission. Furthermore, the amount of current needed for obtaining a predetermined luminance can be smaller in a tandem structure than in a single structure; thus, a tandem structure enables higher reliability.

Note that FIG. 22D and FIG. 22F each illustrate an example in which the display device includes a layer 764 overlapping with the light-emitting device. FIG. 22D illustrates an example in which the layer 764 overlaps with the light-emitting device illustrated in FIG. 22C, and FIG. 22F illustrates an example in which the layer 764 overlaps with the light-emitting device illustrated in FIG. 22E. In FIG. 22D and FIG. 22F, a conductive film that transmits visible light is used for the upper electrode 762 so that light is extracted to the upper electrode 762 side.

One or both of a color conversion layer and a color filter (coloring layer) can be used as the layer 764.

In FIG. 22C and FIG. 22D, light-emitting substances that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 22D for converting blue light emitted from the light-emitting device into light with a longer wavelength, so that red or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of a desired color can be absorbed by the coloring layer, and color purity of light emitted by a subpixel can be improved.

In FIG. 22C and FIG. 22D, light-emitting substances that emit light of different colors may be used for the light-emitting layer 771, the light-emitting layer 772, and the light-emitting layer 773. When the light-emitting layer 771, the light-emitting layer 772, and the light-emitting layer 773 emit light of complementary colors, white light emission can be obtained. The light-emitting device having a single structure preferably includes a light-emitting layer including a light-emitting substance emitting blue light and a light-emitting layer including a light-emitting substance emitting visible light with a longer wavelength than blue light, for example.

A color filter is preferably provided as the layer 764 illustrated in FIG. 22D. When white light passes through a color filter, light of a desired color can be obtained.

In the case where the light-emitting device having a single structure includes three light-emitting layers, for example, a light-emitting layer including a light-emitting substance emitting red (R) light, a light-emitting layer including a light-emitting substance emitting green (G) light, and a light-emitting layer including a light-emitting substance emitting blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer including a light-emitting substance emitting blue (B) light and a light-emitting layer including a light-emitting substance emitting yellow (Y) light are preferably included. This structure may be referred to as a BY single structure.

In the light-emitting device that emits white light, two or more kinds of light-emitting substances are preferably included. To obtain white light emission by using two light-emitting layers, light-emitting substances are selected such that emission colors of the two light-emitting layers are complementary colors. For example, when emission colors of a first light-emitting layer and a second light-emitting layer are complementary colors, the light-emitting device can emit white light as a whole. To obtain white light emission by using three or more light-emitting layers, the light-emitting device is configured to emit white light as a whole by combining emission colors of the three or more light-emitting layers.

In FIG. 22C and FIG. 22D, the layer 780 and the layer 790 may each have a stacked-layer structure of two or more layers as illustrated in FIG. 22B.

In FIG. 22E and FIG. 22F, light-emitting substances that emit light of the same color, or the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In each of the subpixel that emits red light and the subpixel that emits green light, a color conversion layer is provided as the layer 764 illustrated in FIG. 22F for converting blue light emitted from the light-emitting device into light with a longer wavelength, so that red or green light can be extracted. As the layer 764, both a color conversion layer and a coloring layer are preferably used.

In FIG. 22E and FIG. 22F, light-emitting substances that emit light of different colors may be used for the light-emitting layer 771 and the light-emitting layer 772. When the light-emitting layer 771 and the light-emitting layer 772 emit light of complementary colors, white light emission can be obtained. A color filter is preferably provided as the layer 764 illustrated in FIG. 22F. When white light passes through a color filter, light of a desired color can be obtained. Although FIG. 22E and FIG. 22F each illustrate an example in which the light-emitting unit 763a includes one light-emitting layer 771 and the light-emitting unit 763b includes one light-emitting layer 772, one embodiment of the present invention is not limited to the example. Each of the light-emitting unit 763a and the light-emitting unit 763b may include two or more light-emitting layers.

Although FIG. 22E and FIG. 22F each illustrate an example of a light-emitting device including two light-emitting units, one embodiment of the present invention is not limited to the example. The light-emitting device may include three or more light-emitting units. Note that a structure including two light-emitting units and a structure including three light-emitting units may be referred to as a two-unit tandem structure and a three-unit tandem structure, respectively.

In each of FIG. 22E and FIG. 22F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. Furthermore, the layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

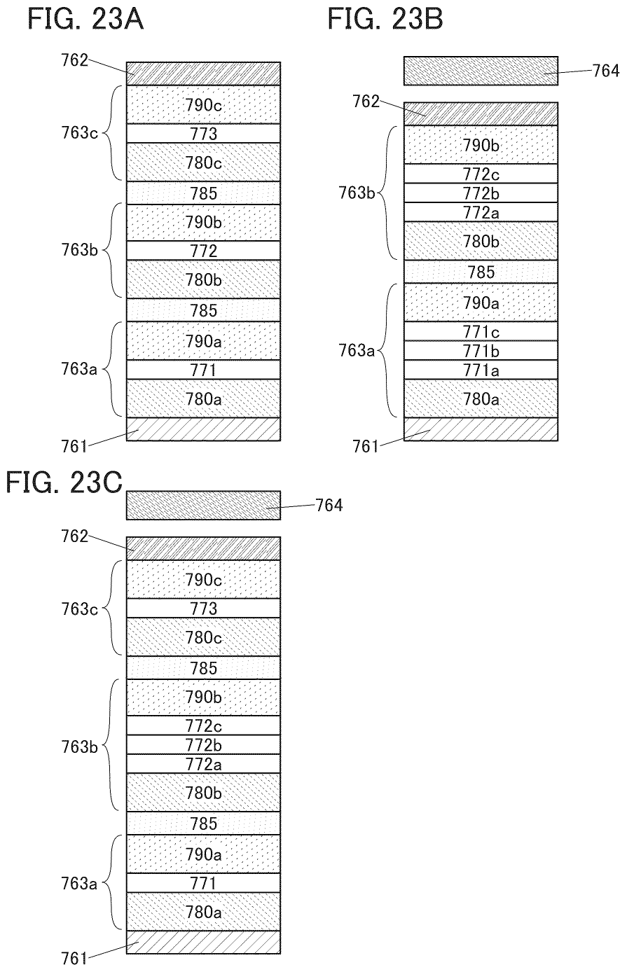

As examples of the light-emitting device with a tandem structure, structures illustrated in FIG. 23A to FIG. 23C can be given.

FIG. 23A illustrates a structure including three light-emitting units. In FIG. 23A, a plurality of light-emitting units (the light-emitting unit 763a, the light-emitting unit 763b, and a light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 23A, the light-emitting layer 771, the light-emitting layer 772, and the light-emitting layer 773 can include light-emitting substances that emit light of the same color. Specifically, a structure where the light-emitting layer 771, the light-emitting layer 772, and the light-emitting layer 773 each include a blue (B) light-emitting substance (what is called a three-unit tandem structure of B\B\B) can be employed. Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 23A, light-emitting substances that emit light of different colors can be used for some or all of the light-emitting layer 771, the light-emitting layer 772, and the light-emitting layer 773. Examples of the combination of emission colors for the light-emitting layer 771, the light-emitting layer 772, and the light-emitting layer 773 include a combination of blue (B) for two of them and yellow (Y) for the other; and a combination of red (R) for one of them, green (G) for another, and blue (B) for the other.

FIG. 23B illustrates a tandem light-emitting device in which light-emitting units each including a plurality of light-emitting layers are stacked. FIG. 23B illustrates a structure in which two light-emitting units (light-emitting unit 763a and light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 23B, the light-emitting unit 763a is configured to emit white (W) light by selecting light-emitting substances for the light-emitting layer 771a, the light-emitting layer 771b, and the light-emitting layer 771c such that their emission colors are complementary colors. Furthermore, the light-emitting unit 763b is configured to emit white (W) light by selecting light-emitting substances for the light-emitting layer 772a, the light-emitting layer 772b, and the light-emitting layer 772c such that their emission colors are complementary colors. In other words, the structure illustrated in FIG. 23B is a two-unit tandem structure of WWW. Note that there is no particular limitation on the stacking order of light-emitting substances that emit light of complementary colors, and a practitioner can select an optimum stacking order as appropriate. Although not illustrated, a three-unit tandem structure of WWW or a tandem structure with four or more units may be employed.

Other examples of the structure of a light-emitting device having a tandem structure include a BY or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) and green (G) light and a light-emitting unit that emits blue (B) light; a BIY\B three-unit tandem structure including a light-emitting unit that emits blue (B) light, a light-emitting unit that emits yellow (Y) light, and a light-emitting unit that emits blue (B) light in this order; a BYG\B three-unit tandem structure including a light-emitting unit that emits blue (B) light, a light-emitting unit that emits yellowish green (YG) light, and a light-emitting unit that emits blue (B) light in this order; and a BIG\B three-unit tandem structure including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a and a light-emitting substance that emits light of b.

Alternatively, a light-emitting unit including one light-emitting layer and a light-emitting unit including a plurality of light-emitting layers may be used in combination as illustrated in FIG. 23C.

Specifically, in the structure illustrated in FIG. 23C, a plurality of light-emitting units (light-emitting unit 763a, light-emitting unit 763b, and light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 23C can be, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display device includes a light-emitting device emitting infrared light, a conductive film transmitting visible light and infrared light is preferably used for the electrode through which light is extracted, and a conductive film reflecting visible light and infrared light is preferably used for the electrode through which light is not extracted.

A conductive film transmitting visible light may be used also for the electrode through which light is not extracted. In that case, the electrode is preferably placed between a reflective layer and the EL layer 763. In other words, light emitted from the EL layer 763 may be reflected by the reflective layer to be extracted from the display device.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing an appropriate combination of any of these metals. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a micro optical resonator (microcavity) structure. Therefore, one of the pair of electrodes of the light-emitting device preferably includes an electrode having properties of transmitting and reflecting visible light (transflective electrode), and the other preferably includes an electrode having a property of reflecting visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ω⁻² cm.

The light-emitting device includes at least a light-emitting layer. In addition to the light-emitting layer, the light-emitting device may further include a layer including any of a substance having a high hole-injection property, a substance having a high hole-transport property, a hole-blocking material, a substance having a high electron-transport property, an electron-blocking material, a substance having a high electron-injection property, a substance having a bipolar property (also referred to as a substance with a high electron-transport property and a high hole-transport property or a bipolar material), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, any of after-mentioned substances with a high hole-transport property that can be used for the hole-transport layer can be used. As the electron-transport material, it is possible to use any of after-mentioned substances with a high electron-transport property that can be used for the electron-transport layer. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of the light-emitting device can be achieved at the same time.

The hole-injection layer injects holes from the anode to the hole-transport layer and includes a substance having a high hole-injection property. Examples of the substance having a high hole-injection property include an aromatic amine compound and a composite material including a hole-transport material and an acceptor material (electron-accepting material).

As the hole-transport material, any of after-mentioned substances with a high hole-transport property that can be used for the hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferred because it is stable in the air, has a low hygroscopic property, and is easy to handle. Alternatively, an organic acceptor material containing fluorine can be used. An organic acceptor material such as a quinodimethane derivative, a chloranil derivative, or a hexaazatriphenylene derivative can be used.

As the substance having a high hole-injection property, a material containing a hole-transport material and the above-described oxide of a metal belonging to Group 4 to Group 8 of the periodic table (typically, molybdenum oxide) may be used, for example.

The hole-transport layer transports holes injected from the anode by the hole-injection layer, to the light-emitting layer. The hole-transport layer includes a hole-transport material. The hole-transport material is preferably a substance having a hole mobility higher than or equal to 1×10⁻⁶ cm²/Vs. Note that other substances can also be used as long as the substances have a hole-transport property higher than an electron-transport property. As the hole-transport material, substances having a high hole-transport property, such as a x-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer is a layer having a hole-transport property and including a material that can block an electron. Among the above-described hole-transport materials, a material having an electron-blocking property can be used for the electron-blocking layer.

Since the electron-blocking layer has a hole-transport property, the electron-blocking layer can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer includes an electron-transport material. The electron-transport material is preferably a substance having an electron mobility higher than or equal to 1×10⁻⁶ cm²/Vs. Note that other substances can also be used as long as the substances have an electron-transport property higher than a hole-transport property. As the electron-transport material, any of the following substances having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a T-electron deficient heteroaromatic compound such as a nitrogen-containing heteroaromatic compound.

The hole-blocking layer is provided in contact with the light-emitting layer. The hole-blocking layer is a layer having an electron-transport property and including a material that can block a hole. Among the above-described electron-transport materials, a material having a hole-blocking property can be used for the hole-blocking layer.

Since the hole-blocking layer has an electron-transport property, the hole-blocking layer can also be referred to as an electron-transport layer. Among electron-transport layers, a layer having a hole-blocking property can also be referred to as a hole-blocking layer.

The electron-injection layer injects electrons from the cathode to the electron-transport layer and includes a substance having a high electron-injection property. As the substance having a high electron-injection property, an alkali metal, an alkaline earth metal, or a compound thereof can be used. As the substance having a high electron-injection property, a composite material including an electron-transport material and a donor material (electron-donating material) can also be used.

The LUMO level of the substance having a high electron-injection property preferably has a small difference (specifically, less than or equal to 0.5 eV) from the work function of a material used for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato) lithium (abbreviation:Liq), 2-(2-pyridyl) phenolatolithium (abbreviation:LiPP), 2-(2-pyridyl)-3-pyridinolatolithium (abbreviation:LiPPy), 4-phenyl-2-(2-pyridyl) phenolatolithium (abbreviation:LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may include an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation:BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c] phenazine (abbreviation: HATNA), 2,4,6-tris[3′-(pyridin-3-yl) biphenyl-3-yl]-1,3,5-triazine (abbreviation:TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably includes an acceptor material. For example, the charge-generation region preferably includes the above-described hole-transport material and acceptor material that can be used for the hole-injection layer.

The charge-generation layer preferably includes a layer including a substance having a high electron-injection property. The layer can also be referred to as an electron-injection buffer layer. The electron-injection buffer layer is preferably provided between the charge-generation region and the electron-transport layer. Providing the electron-injection buffer layer can reduce an injection barrier between the charge-generation region and the electron-transport layer; thus, electrons generated in the charge-generation region can be easily injected into the electron-transport layer.

The electron-injection buffer layer preferably includes an alkali metal or an alkaline earth metal, and can include an alkali metal compound or an alkaline earth metal compound, for example. Specifically, the electron-injection buffer layer preferably includes an inorganic compound containing an alkali metal and oxygen or an inorganic compound containing an alkaline earth metal and oxygen, and further preferably includes an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer including a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) to transfer electrons smoothly.

For the electron-relay layer, a phthalocyanine-based material such as copper (II) phthalocyanine (abbreviation:CuPc), or a metal complex having a metal-oxygen bond and an aromatic ligand is preferably used.

Note that the charge-generation region, the electron-injection buffer layer, and the electron-relay layer cannot be clearly distinguished from one another on the basis of the cross-sectional shape or properties in some cases.

The charge-generation layer may include a donor material instead of an acceptor material. For example, the charge-generation layer may include a layer including the above-described electron-transport material and donor material that can be used for the electron-injection layer.

When the charge-generation layer is provided between two light-emitting units to be stacked, an increase in driving voltage can be inhibited.

This embodiment can be combined with the other embodiments as appropriate.

### Embodiment 6

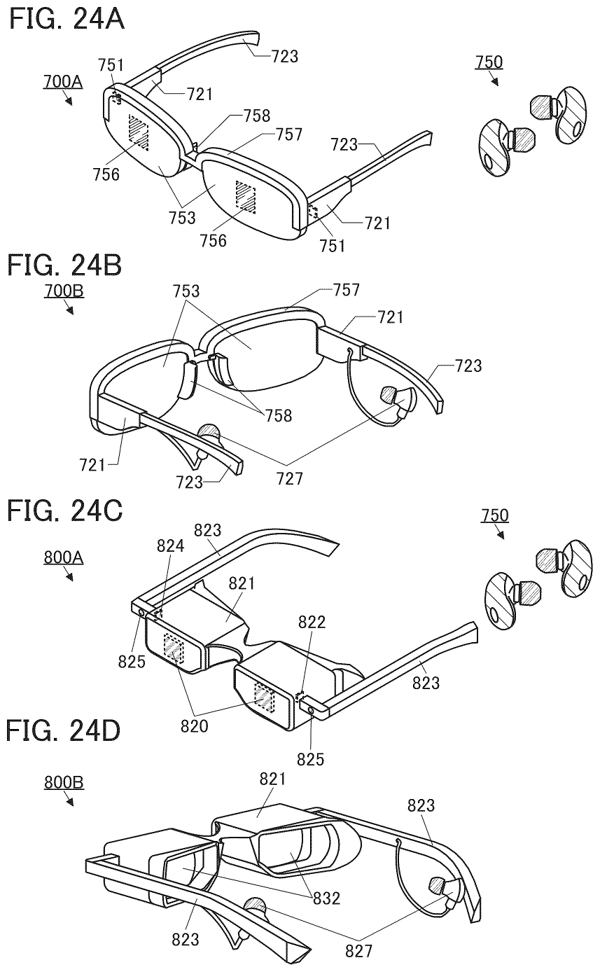

In this embodiment, electronic devices of embodiments of the present invention will be described with reference to FIG. 24 to FIG. 26.

Electronic devices of this embodiment each include the display device of one embodiment of the present invention in a display portion. The definition and resolution of the display device of one embodiment of the present invention can be easily increased. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display device of one embodiment of the present invention can have high definition, and thus can be suitably used for an electronic device including a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The resolution of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. The pixel density (definition) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such high resolution and high definition can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, or the like, a function of executing a variety of software (programs), a wireless communication function, and a function of reading out a program or data stored in a recording medium.

Examples of a wearable device that can be worn on a head are described with reference to FIG. 24A to FIG. 24D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 24A and an electronic device 700B illustrated in FIG. 24B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high definition.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and an image signal or the like can be supplied by the wireless communication device. Note that instead of the wireless communication device or in addition to the wireless communication device, a connector to which a cable for supplying an image signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 800A illustrated in FIG. 24C and an electronic device 800B illustrated in FIG. 24D each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic device can perform display with extremely high definition. This enables a user to feel high sense of immersion.

The display portions 820 are provided at a position inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be worn on the user's head with the wearing portion 823. FIG. 24C and the like illustrate non-limiting examples where the wearing portion 823 has a shape like a temple of glasses. The wearing portion 823 may have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example including the image capturing portion 825 is described here, a range sensor (hereinafter, also referred to as a sensing portion) that is capable of measuring a distance from an object may be provided. That is, the image capturing portion 825 is one mode of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, any one or more of the display portion 820, the housing 821, and the wearing portion 823 can include the vibration mechanism. In that case, without additionally using an audio device such as headphones, earphones, or a speaker, the user can enjoy images and sounds only by wearing the electronic device 800A.

The electronic device 800A and the electronic device 800B may each include an input terminal. To the input terminal, a cable for supplying an image signal from an image output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 24A has a function of transmitting information to the earphones 750 with the wireless communication function. For another example, the electronic device 800A in FIG. 24C has a function of transmitting information to the earphones 750 with the wireless communication function.

The electronic device may include an earphone portion. The electronic device 700B illustrated in FIG. 24B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 24D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This structure is preferably employed, in which case the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferred as the electronic devices of embodiments of the present invention.

The electronic device of one embodiment of the present invention can transmit information to earphones by wire or wirelessly.

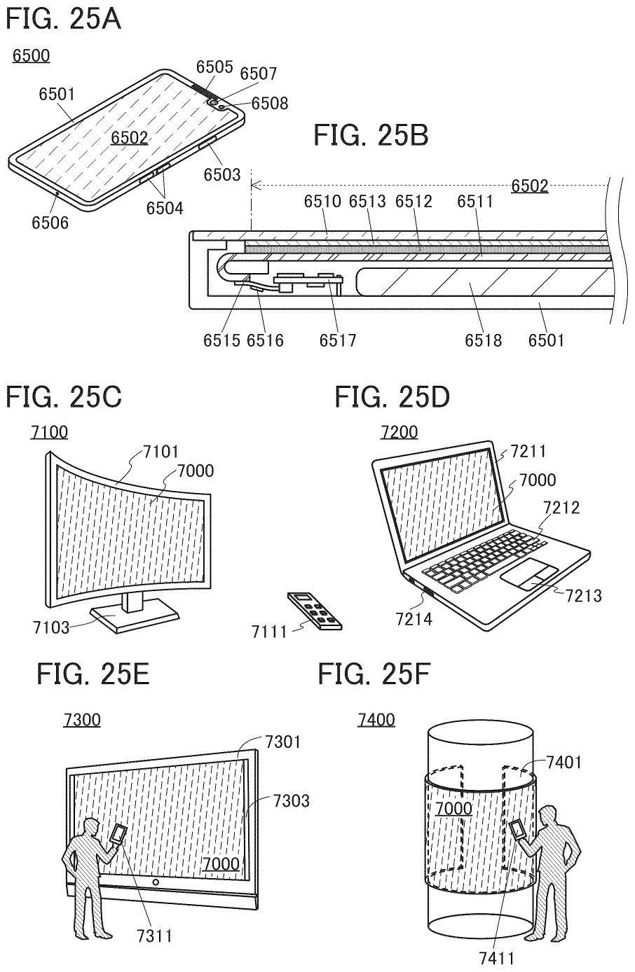

An electronic device 6500 illustrated in FIG. 25A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 25B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while an increase in thickness of the electronic device is suppressed. Moreover, part of the display panel 6511 is folded back so that a connection portion with the FPC 6515 is provided on the back side of the pixel portion, whereby an electronic device with a narrow bezel can be obtained.

FIG. 25C illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 25C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and images displayed on the display portion 7000 can be controlled.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 25D illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000.

FIG. 25E and FIG. 25F illustrate examples of digital signage.

Digital signage 7300 illustrated in FIG. 25E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 25F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in each of FIG. 25E and FIG. 25F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 25E and FIG. 25F, it is preferable that the digital signage 7300 or the digital signage 7400 can work with an information terminal 7311 or an information terminal 7411 such as a smartphone a user has through wireless communication. For example, information on an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

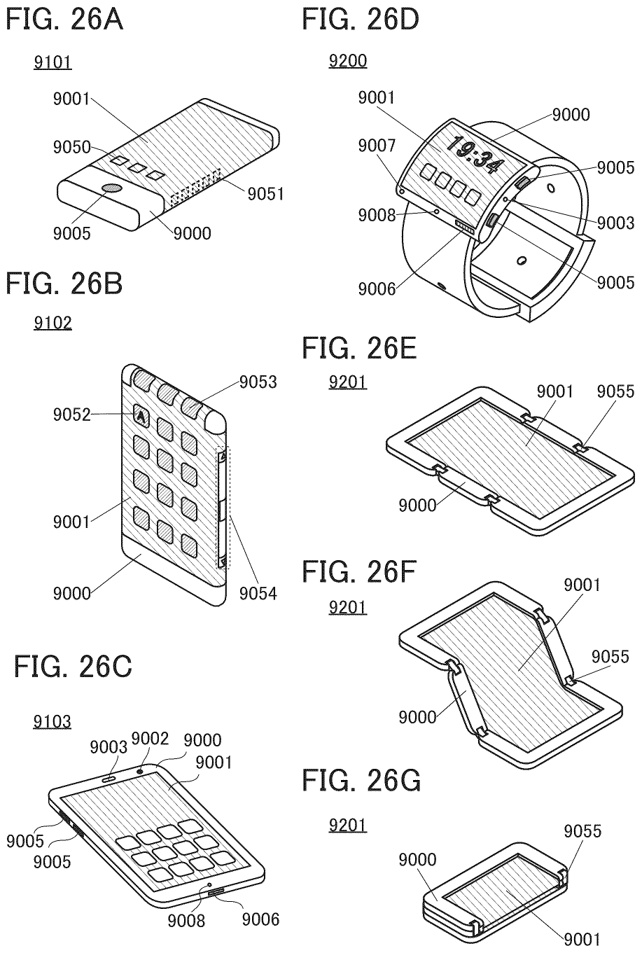

Electronic devices illustrated in FIG. 26A to FIG. 26G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portion 9001 in FIG. 26A to FIG. 26G.

The electronic devices illustrated in FIG. 26A to FIG. 26G have a variety of functions. For example, the electronic devices can have a function of displaying a variety of information (a still image, a moving image, a text image, and the like) on the display portion, a touch panel function, a function of displaying a calendar, date, time, or the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 26A to FIG. 26G are described in detail below.

FIG. 26A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 26A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 26B is a perspective view illustrating a portable information terminal 9102. The portable information terminal 9102 has a function of displaying information on three or more surfaces of the display portion 9001. An example is shown where information 9052, information 9053, and information 9054 are displayed on different surfaces. For example, a user can check the information 9053 displayed such that it can be seen from above the portable information terminal 9102, with the portable information terminal 9102 put in a breast pocket of their clothes. The user can see the display without taking out the portable information terminal 9102 from the pocket and decide whether to answer the call, for example.

FIG. 26C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 26D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 26E to FIG. 26G are perspective views illustrating a foldable portable information terminal 9201. FIG. 26E is a perspective view of an opened state of the portable information terminal 9201, FIG. 26G is a perspective view of a folded state thereof, and FIG. 26F is a perspective view of a state in the middle of change from one of FIG. 26E and FIG. 26G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

100A: display device, 100B: display device, 100C: display device, 100D: display device, 100E: display device, 100: transistor, 110a: subpixel, 110b: subpixel, 110c: subpixel, 110d: subpixel, 110e: subpixel, 110: pixel, 111: pixel electrode, 113G: EL layer, 113R: EL layer, 113: EL layer, 114: common layer, 115: common electrode, 124a: pixel, 124b: pixel, 125: insulating layer, 127: insulating layer, 130B: light-emitting element, 130G: light-emitting element, 130R: light-emitting element, 131: protective layer, 132G: coloring layer, 132R: coloring layer, 133R: layer, 137: insulating layer, 142: adhesive layer, 150: display module, 151: substrate, 152: substrate, 200: transistor, 205A: conductive layer, 205B: conductive layer, 215: insulating layer, 216: insulating layer, 220: insulating layer, 222A: insulating layer, 222B: insulating layer, 222: insulating layer, 223: insulating layer, 224A: insulating layer, 224B: insulating layer, 224: insulating layer, 230A: oxide layer, 230B: oxide layer, 230: oxide layer, 235: oxide layer, 240A: conductive layer, 240B: conductive layer, 240C: conductive layer, 240D: conductive layer, 240E: conductive layer, 240F: conductive layer, 240G: conductive layer, 241: insulating layer, 242A: conductive layer, 242B: conductive layer, 242C: conductive layer, 242D: conductive layer, 242: conductive layer, 245: conductive layer, 246: conductive layer, 250: insulating layer, 255: insulating layer, 260a: conductive layer, 260b: conductive layer, 260: conductive layer, 265: conductive layer, 271A: insulating layer, 271B: insulating layer, 271C: insulating layer, 271D: insulating layer, 271: insulating layer, 275: insulating layer, 280: insulating layer, 282: insulating layer, 283: insulating layer, 284: insulating layer, 285: insulating layer, 286: insulating layer, 287: insulating layer, 288: insulating layer, 290: FPC, 291: substrate, 292: circuit portion, 293a: pixel circuit, 293: pixel circuit portion, 294a: pixel, 294: pixel portion, 295: terminal portion, 296: wiring portion, 297: display portion, 299: substrate, 300: transistor, 301: substrate, 311: conductive layer, 312: low-resistance region, 313: insulating layer, 314: insulating layer, 315: element isolation layer, 316: insulating layer, 317: insulating layer, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first transistor and a second transistor,
wherein the first transistor comprises a first conductive layer, a second conductive layer, a third conductive layer, a first oxide layer, a second oxide layer, a first insulating layer, a second insulating layer, and a third insulating layer,
wherein the second transistor comprises a fourth conductive layer, a fifth conductive layer, a sixth conductive layer, a seventh conductive layer, a third oxide layer, the first insulating layer, a fourth insulating layer, and a fifth insulating layer,
wherein the first insulating layer is positioned over the first conductive layer and over the fourth conductive layer,
wherein the second insulating layer is positioned over the first insulating layer,
wherein the first oxide layer is positioned over the second insulating layer,
wherein the second conductive layer is positioned over the first oxide layer,
wherein the first insulating layer, the second insulating layer, the first oxide layer, and the second conductive layer comprise an opening reaching the first conductive layer,
wherein in the opening, the second oxide layer is in contact with at least a top surface of the first conductive layer, a side surface of the first insulating layer, a side surface of the second insulating layer, a side surface of the first oxide layer, and a side surface of the second conductive layer,
wherein in the opening, the third insulating layer is positioned over the second oxide layer,
wherein in the opening, the third conductive layer overlaps with the second oxide layer with the third insulating layer therebetween,
wherein the fourth insulating layer is positioned over the first insulating layer,
wherein the third oxide layer is positioned over the fourth insulating layer,
wherein the fifth conductive layer and the sixth conductive layer are positioned over the third oxide layer to be separated from each other,
wherein the fifth insulating layer is positioned over the third oxide layer and is positioned between the fifth conductive layer and the sixth conductive layer, and
wherein the seventh conductive layer comprises a portion positioned over the fifth insulating layer and overlapping with the fourth conductive layer with the third oxide layer between the portion and the fourth conductive layer.

2. The semiconductor device according to claim 1,
wherein a size of the opening provided in the second conductive layer in a plan view is the same or substantially the same as a size of the opening provided in the first oxide layer in the plan view.

3. The semiconductor device according to claim 1,
wherein a size of the opening provided in the second conductive layer in a plan view is larger than a size of the opening provided in the first oxide layer in the plan view, and
wherein the second oxide layer is in contact with part of a top surface of the first oxide layer.

4. The semiconductor device according to claim 1,
wherein the first conductive layer comprises a depressed portion,
wherein the opening overlaps with the depressed portion, and
wherein the second oxide layer is further in contact with an inner wall of the depressed portion of the first conductive layer.

5. The semiconductor device according to claim 4,
wherein the third conductive layer overlaps with the side surface of the first insulating layer and the side surface of the second insulating layer with the third insulating layer and the second oxide layer between the third conductive layer and each of the side surface of the first insulating layer and the side surface of the second insulating layer.

6. A display device comprising:
the semiconductor device according to claim 1; and
a light-emitting element,
wherein the light-emitting element comprises a first electrode, a light-emitting layer, and a second electrode stacked in this order, and
wherein the first electrode is electrically connected to at least one of the first conductive layer, the second conductive layer, the fifth conductive layer, and the sixth conductive layer.

7. The display device according to claim 6, further comprising:
a first layer, a second layer, and a third layer stacked in this order,
wherein the first layer comprises a third transistor comprising silicon in a channel formation region,
wherein the second layer comprises the first transistor and the second transistor, and wherein the third layer comprises the light-emitting element.

8. A display module comprising:
the display device according to claim 6; and
at least one of a connector and an integrated circuit.

9. An electronic device comprising:
the display module according to claim 8; and
at least one of a housing, a battery, a camera, a speaker, and a microphone.
